(19) United States
(12) Patent Application Publication
(10) Pub. No.: US 2009/0029125 A1
(43) Pub. Date: Jan. 29, 2009

(54) PHOTOSENSITIVE MATERIAL FOR FORMING CONDUCTIVE FILM, CONDUCTIVE FILM, LIGHT TRANSMITTING ELECTROMAGNETIC WAVE SHIELDING FILM AND METHOD FOR MANUFACTURING THE SAME

(75) Inventor: Shinichi Nakahira, Kanagawa (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 11/816,319

(22) PCT Filed: Feb. 14, 2006
(86) PCT No.: PCT/JP2006/302552

§ 371 Date: Nov. 8, 2007

(30) Foreign Application Priority Data
Feb. 15, 2005 (JP) 2005-038188

(51) Int. Cl. B32B 3/10; G03C 1/32; G03F 7/20; G03C 1/43

(52) U.S. Cl. 428/209; 430/270.1; 430/319

(57) ABSTRACT

To provide a conductive film forming photosensitive material from which a conductive film having high electromagnetic wave shielding properties and high transparency simultaneously can be manufactured and which is reduced with respect to pressure properties.

A conductive film forming photosensitive material including a support having thereon an emulsion layer containing a silver salt emulsion and capable of manufacturing a conductive film by exposing the emulsion layer, performing a development treatment and further performing physical development and/or plating treatment, wherein the emulsion layer is disposed substantially in an uppermost layer; and the emulsion layer contains an antioxidant.

### TECHNICAL FIELD

The present invention relates to a silver salt photosensitive material for forming a conductive film such as electromagnetic wave shielding films capable of shielding electromagnetic waves emitted from the front of a display inclusive of CRT (cathode ray tube), PDP (plasma display panel), liquid crystal, EL (electroluminescence) and FED (field emission display), microwave ovens, electronic appliances, printed wiring boards, and the like and having light transmission properties and to a method for manufacturing a conductive film.

Also, the invention relates to a light transmitting conductive film which is used in imaging devices and the like in addition to these image display devices and to a method for manufacturing the same.

### BACKGROUND ART

In recent years, following an increase of utilization of various electric equipment and electronic application equipment, electromagnetic interference (EMI) increases rapidly. It is pointed out that EMI not only causes a malfunction of electric appliances and interference but also gives health hazards to operators of these apparatus. For that reason, in electronic or electric appliances, it is required that the intensity of release of electromagnetic waves is suppressed within standards or regulations.

As a countermeasure to the foregoing EMI, it is necessary that electromagnetic waves are shielded. In order to achieve this, it is self-explanatory that properties of a metal which does not penetrate electromagnetic waves therethrough are utilized. For example, there are employed a method of forming a casing into a metal body or highly conductive body, a method of inserting a metal plate between a circuit board and a circuit board, a method of covering a cable by a metal foil, and the like. But, since an operator must recognize letters or the like displayed on a screen in CRT, PDP, etc., transparency in a display is required. For that reason, all of the foregoing methods were improper as a shielding method of electromagnetic waves because the front of a display becomes often opaque.

In particular, since PDP emits a large amount of electromagnetic waves as compared with CRT or the like, it is required to have a stronger electromagnetic wave shielding ability. The electromagnetic wave shielding ability can be simply expressed by a surface resistivity value. In a light transmitting electromagnetic wave shielding material for CRT, the surface resistivity value is required to be not more than about 300 Ω/sq; and on the other hand, in a light transmitting electromagnetic wave shielding material for PDP, the surface resistivity value is required to be not more than 2.5 Ω/sq; and in a plasma television set for general use using PDP, the necessity that the surface resistivity value be not more than 1.5 Ω/sq is high, and more desirably, extremely high conductivity that the surface resistivity value be not more than 0.1 Ω/sq is required.

Also, with respect to the level required for the transparency, a visible light transmittance is required to be about 70% or more for CRT and 80% or more for PDP, respectively, and higher transparency is desirable.

In order to solve the foregoing problems, various materials and methods capable of making both electromagnetic wave shielding properties and transparency compatible with each other by utilizing a metal mesh having openings as shown below have hitherto been proposed.

### (1) Conductive Fiber:

For example, Patent Document 1 discloses an electromagnetic shielding material composed of a conductive fiber. But, this shielding material involved a drawback that a mesh line width is so thick that when a display screen is shielded, the screen becomes dark, whereby letters displayed on the display are hardly viewed.

### (2) Electroless Plating Worked Mesh:

There is proposed a method in which an electroless plating catalyst is printed as a lattice-like pattern by a printing method and electroless plating is performed (for example, Patent Documents 2 and 3, etc.). But, a line width of the printed catalyst is thick as about 60 μm, and this method was improper as a use for displays which are required to have a comparatively small line width and minute pattern.

Furthermore, there is proposed a method in which a photoresist containing an electroless plating catalyst is coated and exposure and development are performed to form an electroless plating catalyst pattern, followed by performing electroless plating (for example, Patent Document 4). But, a visible light transmittance of the conductive film is 72% so that the transparency was insufficient. Moreover, since extremely expensive palladium must be used as the electroless plating catalyst for removing a large proportion after the exposure, a problem was also involved in view of the manufacturing costs.

### (3) Etching Worked Mesh Utilizing Photolithography Method:

There is proposed a method of forming a mesh of a metal thin film on a transparent substrate by etching working utilizing a photolithography method (for example, Patent Documents 5, 6, 7 and 8, etc.). Since micro working is possible, this method has advantages that a mesh with a high opening ratio (high transmittance) can be prepared and that release of strong electromagnetic waves can be shielded. But, there were involved problems that the manufacturing steps are complicated and complex; and that the production costs are expensive. Also, since this method relies upon the etching method, it is known that there is involved a problem that an intersection point part of a lattice pattern is thicker than a line width of a straight line portion. A problem of moiré is also pointed out, and improvements were desired.

### (4) Method of Forming Conductive Metallic Silver Pattern Using Silver Salt:

A photosensitive material utilizing a silver salt has hitherto been utilized mainly as a material for recording and transmitting an image or a picture image. Examples thereof include photographic films such as color negative films, black-and-white negative films, motion picture films mid color reversal films and photographic printing papers such as color papers and black-and-white printing papers; and also, emulsion masks (photomasks) utilizing the matter that metallic silver can be formed according to an exposure pattern and the like are used for general purposes. In all of them, an image per se which is obtained by exposing a silver salt and developing it is of value, and the image itself is utilized.

However, since developed silver obtained from the silver salt is metallic silver, it is thought to be possible to utilize conductivity of the metallic silver according to the production method. Such proposals have been found here and there from old to recent years; and as an example of disclosing a concrete formation method of a conductive silver thin film, a method in which a metallic silver thin film pattern is formed by a silver salt diffusion transfer method for depositing silver on a physical development nucleus is disclosed in the 1960s in Patent Document 9. Also, it is disclosed in Patent Document 10 that a uniform silver thin film not having light transmittance as obtained by utilizing a similar silver salt diffusion transfer method has a microwave attenuating function. Also, a method in which a conductive pattern is formed simply though exposure and development by employing this principle as it is and using an instant black-and-white slide film is described in Non-Patent Document 1 and Patent Document 11. Also, a method of forming a conductive silver film which can be utilized as a display electrode for plasma display by a principle of a silver salt diffusion transfer method is described in Patent Document 12.

But, the conductive metallic silver films obtained by these methods are insufficient in light transmission properties for image display or image forming device; and a measure for shielding electromagnetic waves emitting from an image display surface of a display such as CRT and PDP without disturbing image displaying has not been known at all.

In the methods described in the foregoing documents, a physical development nucleus prepared specially in a layer on which a conductive metal pattern is formed is uniformly provided irrespective of exposed areas or unexposed areas. For that reason, there was involved a drawback that the opaque physical development nucleus remains in unexposed areas where a metallic silver film is not formed, whereby light transmittance is impaired. In particular, in the case of utilizing a metal pattern material as a light transmitting electromagnetic wave shielding material of a display such as CRT and PDP, the foregoing drawback is serious.

Also, it is difficult to obtain high conductivity, and when it is intended to obtain a thick silver film for the purpose of obtaining high conductivity, there was involved a problem that the transparency is impaired. Accordingly, even by employing the foregoing silver salt diffusion transfer method as it is, a light transmitting electromagnetic wave shielding material with excellent light transmittance and conductivity, which is suitable for shielding electromagnetic waves from an image display surface of an electronic display appliance, could not be obtained.

Also, in the case of imparting conductivity by utilizing a usually commercially available negative film through development, physical development and plating steps without employing a silver salt diffusion transfer method, it was not sufficient to utilize the resulting material as a light transmitting electromagnetic wave shielding material of CRT or PDP in view of conductivity and transparency.

In view of the foregoing, as a measure for shielding electromagnetic waves emitted from electronic display appliances, a method of manufacturing a light transmitting electromagnetic wave shielding material by using a silver salt photosensitive material is disclosed in Patent Document 13.

Patent Document 1: JP-A-5-327274

Patent Document 2: JP-A-11-170420

Patent Document 3: JP-A-5-283889

Patent Document 4: JP-A-11-170421

Patent Document 5: JP-A-2003-46293

Patent Document 6: JP-A-2003-23290

Patent Document 7: JP-A-5-16281

Patent Document 8: JP-A-10-338848

Patent Document 9: JP-B-42-23746

Patent Document 10: JP-B-43-12862

Patent Document 11: WO 01/51276

Patent Document 12: JP-A-2000-149773

Patent Document 13: JP-A-2004-221564

Non-Patent Document 1: Analytical Chemistry, 2000, Vol. 72, page 645

### DISCLOSURE OF THE INVENTION

### Problems that the Invention is to Solve

In a silver salt photosensitive material for manufacturing the foregoing light transmitting electromagnetic wave shielding material, in order that the foregoing physical development and/or plating treatment may be rapidly performed, it is extremely advantageous that a protective layer is not provided on an emulsion layer. However, a silver salt photosensitive material not provided with a protective layer involves problems that it is easily influenced by an external pressure and that fog is easy to occur.

In view of such circumstances, the invention has been made, and an object of the invention is to provide a conductive film forming photosensitive material from which a conductive film having high electromagnetic wave shielding properties and high transparency simultaneously can be manufactured and which is reduced with respect to influences by an external pressure (which is improved with respect to pressure properties).

### Means for Solving the Problems

The object of the invention is achieved by the following inventions.

(1) A conductive film forming photosensitive material, which comprises a support having thereon an emulsion layer containing a silver salt emulsion and is capable of manufacturing a conductive film by exposing the emulsion layer, performing a development treatment and further performing physical development and/or plating treatment,

wherein the emulsion layer is disposed substantially in an uppermost layer; and the emulsion layer contains an antioxidant.

(2) A conductive film forming photosensitive material, which comprises a support having thereon an emulsion layer containing a silver salt emulsion and is capable of manufacturing a conductive film by exposing the emulsion layer, performing a development treatment and further performing physical development and/or plating treatment,

wherein the emulsion layer is disposed substantially in an uppermost layer; and the emulsion layer contains an oxidizing agent.

(3) A conductive film forming photosensitive material, which comprises a support having thereon an emulsion layer containing a silver salt emulsion and is capable of manufacturing a conductive film by exposing the emulsion layer, performing a development treatment and further performing physical development and/or plating treatment,

wherein the emulsion layer is disposed substantially in an uppermost layer; and the silver salt emulsion is a substantially chemically unsensitized emulsion.

(4) A conductive film forming photosensitive material, which comprises a support having thereon an emulsion layer containing a silver salt emulsion and is capable of manufacturing a conductive film by exposing the emulsion layer, performing a development treatment and further performing physical development and/or plating treatment,

wherein the emulsion layer is disposed substantially in an uppermost layer; and the silver salt emulsion is a silver halide emulsion having a silver iodide content of not more than 1.5% by mole.

(5) A conductive film forming photosensitive material, which comprises a support having thereon an emulsion layer containing a silver salt emulsion and is capable of manufacturing a conductive film by exposing the emulsion layer, performing a development treatment and further performing physical development and/or plating treatment,

wherein the emulsion layer is disposed substantially in an uppermost layer; and a coating amount of the silver salt emulsion is not more than 4 g/m² as converted to a silver amount.

(6) The conductive film forming photosensitive material as described in (5) above,

wherein a weight ratio of Ag/binder in the emulsion layer is 1.5 or more.

(7) The conductive film forming photosensitive material as described in (5) or (6) above,

wherein a binder layer is provided in a lower layer of the emulsion layer.

(8) A conductive film forming photosensitive material, which comprises a support having thereon an emulsion layer containing a silver salt emulsion and is capable of manufacturing a conductive film by exposing the emulsion layer, performing a development treatment and further performing physical development and/or plating treatment,

wherein the emulsion layer is disposed substantially in an uppermost layer; and the emulsion layer contains at least one of a matting agent, a slipping agent, colloidal silica and an antistatic agent.

(9) A conductive film forming photosensitive material, which is a combination of the conductive film forming photosensitive materials as described in any of (1) to (8) above.

(10) A method for manufacturing a conductive film, which comprises:

exposing the conductive film forming photosensitive material as described in any of (1) to (9) above;

subsequently developing the exposed conductive film forming photosensitive material; and

further performing physical development and/or plating treatment.

(11) The method for manufacturing a conductive film as described in (10) above,

wherein the conductive film has electromagnetic wave shielding properties.

(12) The method for manufacturing a conductive film as described in (10) or (11) above,

wherein the conductive film forming photosensitive material is partially exposed to form partially a conductive metal part, thereby forming a conductive metal pattern corresponding to an exposure pattern.

(13) The method for manufacturing a conductive film as described in (12) above,

wherein the conductive metal part is formed only in an exposed area.

(14) The method for manufacturing a conductive film as described in (13) above,

wherein a portion other than the conductive metal part is light transmitting.

(15) A light transmitting electromagnetic wave shielding film, which is manufactured by the method as described in (14) above.

(16) A light transmitting electromagnetic wave shielding film for plasma display panel, which comprises the light transmitting electromagnetic wave shielding film as described in (15) above.

(17) The light transmitting electromagnetic wave shielding film as described in (15) or (16) above, which has an adhesive layer.

(18) The light transmitting electromagnetic wave shielding film as described in any of (15) to (17) above, which has a peelable protective film.

(19) The light transmitting electromagnetic wave shielding film as described in any of (15) to (18) above,

wherein 20% or more of a surface of the conductive pattern in terms of a surface area is black.

(20) The light transmitting electromagnetic wave shielding film as described in any of (15) to (19) above, which has a functional transparent layer having at least one function selected from the group consisting of infrared ray shielding properties, hard coat properties, antireflection properties, antiglare properties, antistatic properties, antifouling properties, ultraviolet ray cutting properties, gas barrier properties and display panel failure-proof properties.

(21) The light transmitting electromagnetic wave shielding film as described in any of (15) to (20) above, which has infrared ray shielding properties.

(22) An optical filter, which comprises the light transmitting electromagnetic wave shielding film as described in any of (15) to (21) above.

### ADVANTAGES OF THE INVENTION

According to the invention, a light transmitting electromagnetic wave shielding film having high electromagnetic wave shielding properties and high transparency is obtainable; and a conductive film forming photosensitive material with excellent pressure properties is obtainable.

### BRIEF DESCRIPTION OF THE DRAWINGS

FIG. 1 is a schematic view to show an example of an electroplating tank which is suitably used in a plating treatment method of the invention.

FIG. 2A is an enlarged outline longitudinal cross-sectional view of a cathode roller part of a plating apparatus according to an embodiment in the invention.

FIG. 2B is an enlarged outline longitudinal cross-sectional view of a cathode roller part of a plating apparatus according to another embodiment in the invention.

FIG. 2C is an outline longitudinal cross-sectional view to show an example of the whole of a plating apparatus in the invention.

FIG. 2D is an outline configuration view to show an example of an electric power supply method by a partially enlarged view of an apparatus of FIG. 3.

FIG. 3A is an outline configuration view to show a manufacturing apparatus of a light transmitting electromagnetic shielding material according to an embodiment.

FIG. 3B is an outline configuration view to show a plating apparatus according to an embodiment.

FIG. 3C is a partial cross-sectional view to show a gas-liquid mixer in a plating apparatus according to an embodiment.

FIG. 3D is an outline configuration view to show other example of a plating apparatus according to an embodiment.

FIG. 4A is an outline configuration view to show a manufacturing apparatus of a light transmitting electromagnetic shielding material according to an embodiment.

FIG. 4B is an outline configuration view to show an electroplating apparatus according to an embodiment.

FIG. 4C is an outline cross-sectional view to show a carrying and supporting roller arranged within a second tank (plating bath tank) in an electroplating apparatus according to an embodiment.

FIG. 4D is a partial cross-sectional view to show a gas-liquid mixer in an electroplating apparatus according to an embodiment.

### DESCRIPTION OF REFERENCE NUMERALS AND SIGNS

210: Electroplating tank
212a, 212b: Electric power supply roller
213; Anode plate
216: Film
1: Cathode roller
1A, 1B, 1C: Cathode roller
2: Anode
3, 3A, 3B: Direct current source
4: Film
5: Conductive surface of film
6: Plating tank
7: Plating liquid
8: Liquid film gap
9: Liquid in saucer
10: Saucer
10A: Nozzle
11: Tank of electrolyte
12: Electrolyte
13: Conduit
14: Pump
16: Conduit
17: Conduit for discharging liquid in saucer
25, 28, 30: Liquid
31: Saucer
32: Liquid in saucer
33: Conduit for discharging liquid in saucer
101A, 101B: Film carrying roller in liquid
102A, 102B, 102C, 102D, 102E: Metal of anode
106A, 106B, 106C: Shielding plate
301. Unwinding section
302: Pre-treatment section
303: Electroplating section
304: Post-treatment section
305: Winding section
306: Roller-shaped film before plating
307: Accumulator
308: Balance roller section
309: Speed control section
310: Acids degreasing treatment section
311: Acid, degreasing treatment liquid
312: Water washing section
313: Water washing liquid
314: Water washing section
315: Water washing liquid
316: Rustproof treatment section
317: Rustproof liquid
318: Water washing section
319: Water washing liquid
320: Drying step section
321: Speed adjusting section
322: Balance roller section
323: Accumulator
324: Plated film-provided roller-shaped film
325: Tension detecting roller
330A, 330B, 330C, 330D: Air agitating nozzle
331A, 331B, 331C, 331D: Agitating air
510: Manufacturing apparatus of electromagnetic wave shielding material
512: Exposure apparatus
514: Development apparatus
516: Plating apparatus
518: Light transmitting photosensitive web
520: Carrying roller pair
522: Magazine
522A: Withdrawal roller
524: Exposure unit
526: Development tank
528: Bleach fixing tank
530: Water washing tank
530L: Washing liquid
532: Carrying roller pair
534: Plating bath tank
534A: Plating bath liquid
536: Non-contact carrying member
536A: Cylindrical hollow tube
536B: Injection section
542: Gas-liquid mixing and supply mechanism
544: Heat exchanger
546: Circulating pump
548: Filter
550: Gas-liquid mixer
552: Valve
554: Air knife
538, 540: Carrying support roller
710: Manufacturing apparatus of electromagnetic wave shielding material
712: Exposure apparatus
714: Development apparatus
716: Electroplating apparatus
718: Light transmitting photosensitive web
720: Carrying roller pair
722: Magazine
724: Exposure unit
726: Development tank
728: Bleach fixing tank
730: Water washing tank
732: Carrying roller pair
734: First tank
736: Second tank
738: Third tank
746: First plating power source
746A: Cathode plate
746B: First anode plate
748: Second plating power source
748A: Electric power supply roller on cathode side
748B: Second anode plate
750: Gas-liquid mixing and supply mechanism
754: Circulating pump
756: Filter
758: Gas-liquid mixer
760: Valve
762: Rotating roller
764: Electrolyte solution circulating mechanism
766: Air knife
768: Water absorbing roller

### BEST MODES FOR CARRYING OUT THE INVENTION

The conductive film forming photosensitive material of the invention and the light transmitting electromagnetic wave shielding film formed by using this photosensitive material are hereunder described in detail.

Incidentally, the term “˜” as referred to in the present description is used so as to mean that numerical values designated before and after the same are included as a lower limit value and an upper limit value, respectively.

### (Conductive Film Forming Photosensitive Material)

### [Support]

As the support of the photosensitive material which is used in the manufacturing method of the invention, plastic films, plastic plates, glass plates, and the like can be used.

Examples of raw materials of the foregoing plastic films and plastic plates which can be used include polyesters, for example, polyethylene terephthalate (PET) and polyethylene naphthalate; polyolefins, for example, polyethylene (PE), polypropylene (PP), polystyrene, and EVA; vinyl based resins, for example, polyvinyl chloride and polyvinylidene chloride; and besides, polyetheretherketone (PEEK), polysulfone (PSF), polyethersulfone (PES), polycarbonate (PC), polyamides, polyimides, acrylic resins, and triacetyl cellulose (TAC).

In the invention, the foregoing plastic film is preferably a polyethylene terephthalate film or triacetyl cellulose (TACO) from the standpoints of transparency, heat resistance, easiness of handling and costs.

In the case where the conductive film of the invention is used as an electromagnetic wave shielding material for display, it is preferable that the support is a transparent substrate such as transparent plastics. In that case, a total visible light transmittance of the plastic film or plastic plate is preferably 70˜100%, more preferably 85˜100%, and especially preferably 90˜100%. In the invention, as the foregoing plastic film or plastic plate, it is also possible to use a plastic film or a plastic plate which is colored to a degree such that the object of the invention is not hindered.

Though the plastic film or plastic plate in the invention can be used as a single layer, it can be used as a multilayered film composed of a combination of two or more layers, too.

In the invention, though in the case where a glass plate is used as the support, its kind is not particularly limited, in the case where the glass plate is used as an application of an electromagnetic wave shielding film for display, it is preferred to use a reinforced glass having a reinforced layer provided on a surface thereof. The reinforced glass has a high possibility to prevent breakage as compared with a non-reinforced glass. Furthermore, in a reinforced glass obtained by a forced air cooling method, even when it is broken by any chance, its shattered fragments are small and its end faces do not become sharp, and therefore, such a reinforced glass is preferable in view of safety.

### [Emulsion Layer]

The photosensitive material which is used in the manufacturing method of the invention has an emulsion containing silver salt emulsion (silver salt-containing layer) as an optical sensor on the support. The emulsion layer is disposed substantially in an uppermost layer. It is meant by the terms “the emulsion layer is disposed substantially in an uppermost layer” as referred to herein that not only the case where the emulsion layer is disposed actually in an uppermost layer is included, but also a total film thickness of layers provided on the emulsion layer is not more than 0.5 μm. The total film thickness of layers provided on the emulsion layer is preferably not more than 0.2 μm.

The emulsion layer can contain a dye, a binder, a solvent, and the like in addition to the silver salt as the need arises. Respective components which are contained in the emulsion layer are hereunder described.

### <Dye>

In the photosensitive material, a dye may be contained in at least the emulsion layer. The subject dye is contained as a filter dye or for the purpose of preventing irradiation or various other purposes. A solid disperse dye may be contained as the foregoing dye. Examples of the dye which is preferably used in the invention include dyes represented by the formulae (FA), (FA1), (FA2) and (FA3) described in JP-A-9-179243, and concretely, Compounds F1˜F34 described in this patent document are preferable. (II-2)˜(II-24) described in JP-A-7-152112, (III-5)˜(III-18) described in JP-A-7-152112, (IV-2)˜(IV-7) described in JP-A-7-152112, and the like are also preferably used.

Besides, as the dye which can be used in the invention, examples of a dye in a solid fine particle dispersion state which is decolored at the development or fixation treatment include cyanine dyes, pyrylium dyes and aminium dyes described in JP-A-3-138640. Also, examples of a dye which is not decolored at the treatment include cyanine dyes containing a carboxyl group described in JP-A-9-96891; cyanine dyes not containing an acid group described in JP-A-8-245902; lake type cyanine dyes described in JP-A-8-333519; cyanine dyes described in JP-A-1-266536; holopolar type cyanine dyes described in JP-A-3-136038; pyrylium dyes described in JP-A-62-299959; polymer type cyanine dyes described in JP-A-7-253639; solid fine particle dispersions of an oxonol dye described in JP-A-2-282244; light scattering particles described in JP-A-63-131135; Yb3+compounds described in JP-A-9-5913; and ITO powders described in JP-A-7-113072. Dyes represented by the formulae (F1) and (F2) described in JP-A-9-179243, and concretely, Compounds F35˜F112 described in this patent document can also be used.

Also, a water-soluble dye can be contained as the foregoing dye. Examples of such a water-soluble dye include oxonol dyes, benzylidene dyes, merocyanine dyes, cyanine dyes, and azo dyes. Of these, oxonol dyes, hemioxonol dyes, and benzylidene dyes are useful in the invention. Specific examples of the water-soluble dye which can be used in the invention include those described in U.K. Patents Nos. 584,609 and 1,177,429, JP-A-48-85130, JP-A-49-99620, JP-A-49-114420, JP-A-52-20822, JP-A-59-154439 and JP-A-59-208548, and U.S. Pat. Nos. 2,274,782, 2,533,472, 2,956,879, 3,148,187, 3,177,078, 3,247,127, 3,540,887, 3,575,704, 3,653,905 and 3,718,427.

From the viewpoints of an effect for preventing irradiation or the like and a lowering in sensitivity due to an increase of the addition amount, the content of the dye in the foregoing emulsion layer is preferably 0.01˜10% by weight, and more preferably 0.1˜5% by weight based on the whole solids.

### <Silver Salt>

Examples of the silver salt which is used in the invention include inorganic silver salts such as silver halides and organic silver salts such as silver acetate. In the invention, it is preferred to use a silver halide having excellent characteristics as an optical sensor.

The silver halide which is preferably used in the invention is described.

In the invention, it is preferred to use a silver halide having excellent characteristics as an optical sensor, and technologies which are employed in silver salt photographic films or printing papers, printing plate making films, emulsion masks for photomask, and the like regarding a silver halide can also be employed in the invention.

The halogen element which is contained in the foregoing silver halide may be any of chlorine, bromine, iodine, or fluorine or may be a combination thereof. A silver halide containing, for example, AgCl, AgBr or AgI as a major component is preferably used; and a silver halide containing AgBr or AgCl as a major component is more preferably used. Silver chlorobromide, silver iodochlorobromide and silver iodobromide are also preferably used. Silver chloropromide, silver bromide, silver iodochlorobromide, and silver iodobromide are more preferable; and silver chlorobromide and silver iodochlorobromide each containing 50% by mole or more of silver chloride are most preferably used.

Incidentally, the “silver halide containing AgBr (silver bromide) as a major component” as referred to herein refers to a silver halide having a molar fraction of a bromide ion in the silver halide composition of 50% or more. This silver halide grain containing AgBr as a major component may contain an iodide ion and a chloride ion in addition to the bromide ion.

Incidentally, the silver iodide content in the silver halide emulsion is preferably not more than 1.5% by mole per mole of the silver halide emulsion. By regulating the silver iodide content at not more than 1.5% by mole, it is possible to prevent fog and to improve pressure properties. The silver iodide content is more preferably not more than 1% by mole per mole of the silver halide emulsion.

The silver halide is in a solid grain state; and from the viewpoint of image quality of the pattern-like metallic silver layer formed after the exposure and development, an average grain size of the silver halide is preferably 0.1˜1,000 nm (1 μm), more preferably 0.1˜100 nm, and further preferably 1˜50 nm in terms of a sphere-corresponding diameter.

Incidentally, the “sphere-corresponding diameter of silver halide grain” as referred to herein means a diameter of a grain having a spherical grain shape and having the same volume.

The shape of the silver halide grain is not particularly limited, and examples thereof include various shapes such as a spherical shape, a cubic shape, a tabular shape (for example, a hexagonal tabular shape, a triangular tabular shape, and a square tabular shape), an octahedral shape, and a tetradecahedral shape. Of these, a cubic shape and a tetradecahedral shape are preferable.

With respect to the silver halide grain, the inside and the surface layer may be made of the same phase or may be made of a different phase from each other. Also, a localized layer having a different halogen composition may be present in the inside or surface of the grain.

The silver halide emulsion which is a coating solution for emulsion layer to be used in the invention can be prepared by methods described in P. Glafkides, Chimie et Physique Photogtraphique (published by Paul Montel, 1967), G. F. Duffin, Photographic Emulsion Chemistry (published by The Focal Press, 1966), and V. L. Zelikman, et al., Making and Coating Photographic Emulsion (published by The Focal Press, 1964).

That is, as a preparation method of the foregoing silver halide emulsion, any of an acidic method or a neutral method may be employed; and as a method of allowing a soluble silver salt and a soluble halogen salt to react with each other, any of a single-jet mixing method, a double-jet mixing method, or a combination thereof may be employed.

As a method of forming a silver grain, a method of forming a grain in the presence of an excess of a silver ion (so-called reverse mixing method) can also be employed. Furthermore, a method of keeping a pAg in a liquid phase where the silver halide is formed constant, namely a so-called controlled double-jet mixing method can be employed as one mode of the double-jet mixing method.

It is also preferred to form a grain by using a so-called silver halide solvent such as ammonia, a thioether, and a tetra-substituted thiourea. As such a method, a method of using a tetra-substituted thiourea compound is more preferable and is described in, for example, JP-A-53-82408 and JP-A-55-77737. Preferred examples of the thiourea compound include tetramethylthiourea and 1,3-dimethyl-2-imidazolidinethione. Though the addition amount of the silver halide solvent varies with the kind of a compound to be used, the desired grain size and the halogen composition, it is preferably 10⁻⁵˜10⁻² moles per mole of the silver halide.

The foregoing controlled double-jet method and the method of forming a grain by using a silver halide solvent are easy for preparing a silver halide emulsion having a regular crystal type and having a narrow grain size distribution and can be preferably employed.

Also, for the purpose of making the grain size uniform, it is preferred to rapidly grow silver within a range not exceeding a critical degree of saturation by using a method of altering the addition rate of silver nitrate or a halogenated alkali corresponding to the grain growth rate as described in U.K. Patent No. 1,535,016, JP-B-48-36890 and JP-B-52-16364, or a method of altering the concentration of an aqueous solution as described in U.S. Pat. No. 4,242,445 and JP-A-55-158124. The silver halide emulsion which is used for the formation of an emulsion layer in the invention is preferably a monodispersed emulsion, and its coefficient of fluctuation expressed by {[(standard deviation of grain size)/(average grain size)]×100} is preferably not more than 20%, more preferably not more than 15%, and most preferably not more than 10%.

The silver halide emulsion which is used in the invention may be a mixture of plural kinds of silver halide emulsions having a different grain size from each other.

The silver halide emulsion which is used in the invention may contain a metal belonging to the group VIII or the group VIIB. In particular, for the purpose of achieving high contrast and low fog, it is preferable that the silver halide emulsion contains a rhodium compound, an iridium compound, a ruthenium compound, an iron compound, an osmium compound, or the like. Such a compound may be a compound containing a ligand of every kind. Examples of the ligand include an cyanide ion, a halogen ion, a thiocyanate ion, a nitrosyl ion, water, a hydroxide ion, pseudo-halogens thereof, and ammonia; and besides, organic molecules such as amines (for example, methylamine and ethylenediamine), heterocyclic compounds (for example, imidazole, thiazole, 5-methylthiazole, and mercapto-imidazole), ureas, and thioureas.

Also, for the purpose of achieving high sensitivity, doping with a metal hexacyano complex such as K₄[Fe(CN)₆], K₄[Ru(CN)₆], and K₃[Cr(CN)₆] is advantageously carried out.

As the foregoing rhodium compound, a water-soluble rhodium compound can be used. Examples of the water-soluble rhodium compound include rhodium(III) halide compounds, hexachlororhodate(III) complex salts, pentachloroaquorhodate complex salts, tetrachlorodiaquorhodate complex salts, hexabromorhodate(III) complex salts, hexamminerhodate(III) complex salts, trioxalatorhodate(III) complex salts, and K₃Rh₂Br₉.

While such a rhodium compound is used upon being dissolved in water or an appropriate solvent, a method which is often employed for the purpose of stabilizing a solution of a rhodium compound, namely a method of adding a hydrogen halide aqueous solution (for example, hydrochloric acid, hydrobromic acid, and hydrofluoric acid) or a halogenated alkali (for example, KCl, NaCl, KBr, and NaBr) can be employed. Instead of using the water-soluble rhodium compound, it is also possible to add another silver halide grain which has been doped with rhodium in advance and to dissolve it at the time of preparation of a silver halide.

Examples of the foregoing iridium compound include hexachloroiridate complex salts (for example, K₂IrCl₆ and K₃IrCl₆), hexabromoiridate complex salts, a hexaammineiridate complex salts, and pentachloronitrosyliridate complex salts.

Examples of the foregoing ruthenium compound include hexachlororuthenium, pentachloronitrosylruthenium, and K₄[Ru(CN)₆].

Examples of the foregoing iron compound include potassium hexacyanoferrate(II) and ferric thiocyanate.

The foregoing ruthenium or osmium is added in a form of a water-soluble complex salt described in, for example, JP-A-63-2042, JP-A-1-285941, JP-A-2-20852, and JP-A-2-20855; and a hexacoordinated complex represented by the following formula is especially preferable.

[ML₆]⁻ⁿ

### (Here, M Represents Ru or Os; and N Represents 0, 1, 2, 3 or 4.)

In that case, a counter ion is not important, and for example, an ammonium or alkali metal ion is useful. Preferred examples of the ligand include a halide ligand, a cyanide ligand, a cyanate ligand, a nitrosyl ligand, and a thionitrosyl ligand. Specific examples of the complex which is used in the invention are given below, but it should not be construed that the invention is limited thereto.

[RuCl₆]⁻³, [RuCl₄(H₂O)₂]⁻¹, [RuCl₅(NO)]⁻², [RuBr₅(NS)]⁻², [Ru(CO)₃Cl₃]⁻², [Ru(CO)Cl₅]⁻², [Ru(CO)Br₅]⁻², [OsCl₆]⁻³, [OsCl₅(NO)]⁻², [Os(NO)(CN)₅]⁻², [Os(NS)Br₅]⁻², [Os(CN)₆]⁻⁴, and [Os(O)₂(CN)₅]⁻⁴.

The addition amount of such a compound is preferably 10⁻¹⁰˜10⁻² moles/mole of Ag, and more preferably 10⁻⁹˜10⁻³ moles/mole of Ag based on one mole of the silver halide.

Besides, in the invention, a silver halide containing a Pb(II) ion and/or a Pd metal can also be preferably used. Though Pd may be uniformly distributed in the silver halide grain, it is preferable that Pd is contained in the vicinity of the surface layer of the silver halide grain. It is meant by the terms “Pd is contained in the vicinity of the surface layer of the silver halide grain” as referred to herein that a layer having a higher content of palladium than other layers is made present within 50 nm in a depth direction from the surface of the silver halide grain.

Such a silver halide grain can be prepared by adding Pd on the way of the formation of a silver halide grain. It is preferred to add Pd after adding a silver ion and a halogen ion in an amount of 50% or more of the total addition amount, respectively. It is also preferable that Pd is made present in the surface layer of the silver halide by a method of adding a Pd(II) ion at the post ripening or other method.

This Pd-containing silver halide grain increases the speed of physical development or electroless plating, increases the production efficiency of a desired electromagnetic shielding material and contributes to a lowering of the production costs. Though Pd is well known and used as an electroless plating catalyst, since in the invention, Pd can be localized on the surface of the silver halide grain, it is possible to save extremely expensive Pd.

In the invention, the content of the Pd ion and/or the Pd metal contained in the silver halide is preferably 10⁻⁴˜0.5 moles/mole of Ag, and more preferably 0.01˜0.3 moles/mole of Ag based on the molar number of silver of the silver halide.

Examples of the Pd compound which is used include PdCl₄ and Na₂PdCl₄.

A chemically unsensitized emulsion according to the invention is described. In the silver halide photographic material, it is usual that the silver halide emulsion is subjected to chemical sensitization. The chemical sensitization can be carried out by adding a chemical sensitizer made of a chalcogenite compound or a noble metal compound having a sensitizing function of photographic photosensitive material referred to in, for example, paragraphs 0078, et seq. of JP-A-2000-275770 in a silver halide emulsion. As the silver salt emulsion which is used in the photosensitive material of the invention, an emulsion which has not been subjected to such chemical sensitization, namely a chemically unsensitized emulsion can be preferably used. The preparation of the chemically unsensitized emulsion can be easily carried out by not adding such a chemical sensitizer in the emulsion. Also, even when a chalcogenite or noble metal-containing compound is added in the emulsion, in the case where an increase in sensitivity is small against the case where this is not added, this emulsion is considered to be chemically unsensitized in the invention. In the invention, as a preferred preparation method of the chemically unsensitized emulsion, it is preferable that the addition amount of a chemical sensitizer made of a chalcogenite or noble metal compound is controlled in an amount of not more than the amount at which the increase in sensitivity due to the addition of such a compound is within 0.1. Though a specific amount regarding the addition amount of the chalcogenite or noble metal compound is not limited, as a preferred preparation method of the chemically unsensitized emulsion in the invention, it is preferable that the total addition amount of such chemical sensitizing compounds is not more than 5×10⁻⁷ moles per mole of the silver halide; and it is more preferable that such compounds are not added at all.

In the invention, for the purpose of enhancing the sensitivity as a photosensor, chemical sensitization which is carried out in a photographic emulsion can be further applied. Examples of the chemical sensitization method include chalcogen sensitization, for example, sulfur sensitization, selenium sensitization, and tellurium sensitization; noble metal sensitization, for example, gold sensitization; and reduction sensitization. Such sensitization is employed singly or in combination thereof. In the case of using a combination of the foregoing chemical sensitization methods, for example, a combination of a sulfur sensitization method and a gold sensitization method, a combination of a sulfur sensitization method, a selenium sensitization method and a gold sensitization method, and a combination of a sulfur sensitization method, a tellurium sensitization method and a gold sensitization method are preferable.

The foregoing sulfur sensitization is in general carried out by adding a sulfur sensitizer and stirring an emulsion at a high temperature of 40° C. or higher for a fixed time. Known compounds can be used as the foregoing sulfur sensitizer. For example, in addition to a sulfur compound which is contained in gelatin, various sulfur compounds, for example, thiosulfates, thioureas, thiazoles, and rhodanines can be used. Thiosulfates and thiourea compounds are preferable as the sulfur compound. The addition amount of the sulfur sensitizer varies under various conditions such as pH and temperature at the chemical ripening and a size of the silver halide grain and is preferably 10⁷˜10⁻² moles, and more preferably 10⁻⁵˜10⁻³ moles per mole of the silver halide.

As a selenium sensitizer which is used in the foregoing selenium sensitization, known selenium compounds can be used. That is, the foregoing selenium sensitization is in general carried out by adding an unstable type and/or non-unstable type selenium compound and stirring an emulsion at a high temperature of 40° C. or higher for a fixed time. As the foregoing unstable type selenium compound, compounds described in JP-B-44-15748, JP-B-43-13489, JP-A-4-109240, JP-A-4-324855, and the like can be used. In particular, it is preferred to use compounds represented by the formulae (VIII) and (IX) in JP-A-4-324855.

A tellurium sensitizer which is used in the foregoing tellurium sensitization is a compound capable of forming silver telluride which is estimated to become a sensitization nucleus on the surface or in the inside of the silver halide grain. A formation rate of silver telluride in the silver halide emulsion can be tested by a method described in JP-A-5-313284. Concretely, compounds described in U.S. Pat. Nos. 1,623,499, 3,320,069 and 3,772,031, U.K. Patents 235,211, 1,121,496, 1,295,462 and 1,396,696, Canadian Patent No. 800,958, JP-A-4-204640, JP-A-4-271341, JP-A-4-333043, JP-A-5-303157, J. Chem. Soc. Chem. Commun., page 635 (1980), ibid., page 1102 (1979), ibid., page 645 (1979), J. Chem. Soc. Perkin. Trans., Vol. 1, page 2191 (1980), S. Patai ed., The Chemistry of Organic Selenium and Tellurium Compounds, Vol. 1 (1986), and ibid., Vol. 2 (1987) can be used. Compounds represented by the formulae (II), (II) and (IV) described in JP-A-5-313284 are especially preferable.

The use amount of each of the selenium sensitizer and the tellurium sensitizer which can be used in the invention varies with the silver halide grain to be used, the chemical ripening condition, and the like and is in general about 10⁻⁸˜10⁻² moles, and preferably about 10⁻⁷˜10⁻³ moles per mole of the silver halide. In the invention, while the condition of the chemical sensitization is not particularly limited, the pH is 5˜8; the pAg is 6˜11, and preferably 7˜10; and the temperature is 40˜95° C., and preferably 45˜85° C.

Also, examples of the foregoing noble metal sensitizer include gold, platinum, palladium, and iridium; and gold sensitization is especially preferable. Specific examples of the gold sensitizer which is used in the gold sensitization include chloroauric acid, potassium chloroaurate, potassium aurithiocyanate, gold sulfide, gold(I) thioglucose, and gold(I) thiomannose. The gold sensitizer can be used in an amount of about 10⁻⁷˜10⁻² moles per mole of the silver halide. In the silver halide emulsion which is used in the invention, a cadmium salt, a sulfurous acid salt, a lead salt, a thallium salt, or the like may be copresent during the course of formation or physical ripening of a silver halide grain.

Also, reduction sensitization can be used in the invention. As a reduction sensitizer, stannous salts, amines, formamidinesulfinic acid, silane compounds, and the like can be used. In the foregoing silver halide emulsion, a thiosulfonic acid compound may be added by a method described in EP-A-293917. The silver halide emulsion which is used for the preparation of the photosensitive material used in the invention may be a single emulsion or a combination of two or more emulsions (for example, a combination of emulsions having a different average grain size from each other, a combination of emulsions having a different halogen composition from each other, a combination of emulsions having a different crystal habit from each other, a combination of emulsions having a different condition of chemical sensitization from each other, and a combination of emulsions having a different sensitivity from each other). Above all, in order to obtain high contrast, it is preferred to coat an emulsion with high sensitivity in a part closer to the support as described in JP-A-6-324426.

Incidentally, a coating amount of the silver salt emulsion is preferably not more than 4 g/m², and more preferably not more than 2 g/m² as converted to a silver amount. By regulating the coating amount of the silver salt emulsion at not more than 4 g/m², fog is hardly generated, and pressure properties can be improved.

### <Binder>

For the purposes of uniformly dispersing the silver salt grain and assisting the adhesion between the emulsion layer and the support, a binder can be used. In the invention, while all of water-insoluble polymers and water-soluble polymers can be used as the foregoing binder, water-soluble polymers are preferably used.

Examples of the foregoing binder include gelatin, polyvinyl alcohol (PVA), polyvinylpyrrolidone (PVP), polysaccharides such as starch, cellulose and derivatives thereof, polyethylene oxide, polysaccharides, polyvinylamine, chitosan, polylysin, polyacrylic acid, polyalginic acid, polyhyaluronic acid, and carboxycellulose. Such a binder has neutral, anionic or cationic properties depending upon the ionicity of a functional group.

The content of the binder to be contained in the emulsion layer is not particularly limited and can be properly determined within a range where the binder can exhibit dispersibility and adhesion. The content of the binder in the emulsion layer is preferably 1.5 or more, and more preferably 2.5 or more in terms of an Ag/binder weight ratio. By regulating the Ag/binder weight ratio at 1.5 or more, it is possible to shorten a required time for the plating treatment. Also, it is preferable that the Ag/binder weight ratio is not more than 20.

### <Solvent>

A solvent which is used for the formation of the foregoing emulsion layer is not particularly limited, and examples thereof include water, organic solvents (for example, alcohols such as methanol, ketones such as acetone, amides such as formamide, sulfoxides such as dimethyl sulfoxide, esters such as ethyl acetate, and ethers), ionic liquids, and mixed solvents thereof.

The content of the solvent to be used in the emulsion layer is preferably in the range of 30˜90% by weight, and more preferably in the range of 50˜80% by weight based on the weight of the total sum of the silver salt, the binder, and the like which are contained in the emulsion layer.

### <Antioxidant>

It is preferable that an antioxidant is contained in the emulsion layer according to the invention. By adding the antioxidant in the emulsion layer, fog is hardly generated, and pressure properties can be improved.

As the antioxidant which is used in the invention, those having a molecular weight of not more than 330 are preferable. Though a lower limit of the molecular weight is not particularly limitative, it is preferably 40 or more. The molecular weight is especially preferably 200˜330.

Furthermore, the antioxidant which is used in the invention is preferably a compound having an oxidation potential Eox of Eox≦1.5 (V), more preferably Eox≦1.2 (V), and further preferably 0.3≦Eox≦0.8 (V). The oxidation potential Eox of the antioxidant can be easily measured by those skilled in the art. A method thereof is described in, for example, A. Stanienda, Naturwissenschaften, Vol. 47, pages 353 and 512 (1960); P. Dekahay, New Instrumental Methods in Electrochemistry (1954), published by Interscience Publishers; and L. Mites, Polarographic Techniques, Second Edition (1965), published by Interscience Publishers. The foregoing Eox value means a potential at which an electron of the compound is extracted at an anode in voltammetry and is primarily related to a lowest unoccupied electronic level in the ground state of the compound.

In the invention, Eox is a value determined from a half-wave potential of polarogram under the following condition. That is, the measure was carried out at 25° C. in a concentration of the antioxidant of 10⁻³ ˜10⁻⁴ moles/liter by using acetonitrile as a solvent of the antioxidant and 0.1 N sodium perchlorate as a supporting electrolyte, using an Ag/AgCl electrode as a reference electrode and using a rotatory platinum plate electrode for the measurement of Eox.

Though it is the most desirable that this antioxidant is added and contained directly in the silver halide emulsion layer of the photosensitive material according to the invention, the antioxidant may be added in a non-photosensitive layer containing, as a binder, a hydrophilic colloid, such as an interlayer, a protective layer, a yellow filter layer, and an antihalation layer. Also, it is effective that the antioxidant is added in both the photosensitive emulsion layer and the foregoing non-photosensitive layer. With respect to the timing of addition of this antioxidant, when it is added in the photosensitive emulsion layer, though the antioxidant may be added at an arbitrary timing until coating working, it may be added preferably at a timing of from chemical ripening to coating working, and more preferably after completion of the chemical ripening. Also, the antioxidant may be added in the non-photosensitive layer and diffused over the whole of the configuration layers at the coating.

The antioxidant may be added after being dissolved in water or a lower alcohol, an ester or a ketone, each of which is compatible with water, or a mixed solvent thereof. Also, the antioxidant may be dispersed and added after being dissolved in a high boiling solvent or the like. An addition amount thereof is preferably in the range of 10⁻²˜10⁻⁸ moles, and especially preferably in the range of 10⁻³˜10⁻⁵ moles per mole of the silver halide, but the addition amount may be properly chosen depending upon the kind of the silver halide, the kind of the antioxidant, and the like. Also, when the antioxidant is contained in the non-photosensitive layer, a satisfactory result can be obtained by coating an aqueous solution of a hydrophilic colloid containing the antioxidant in the range of 0.01˜50 g, and more preferably in the range of 0.05˜10 g per gram of the hydrophilic colloid. Also, the antioxidant may be used singly or in combination.

Specific examples of the antioxidant include the following example, but it should not be construed that the invention is limited thereto.

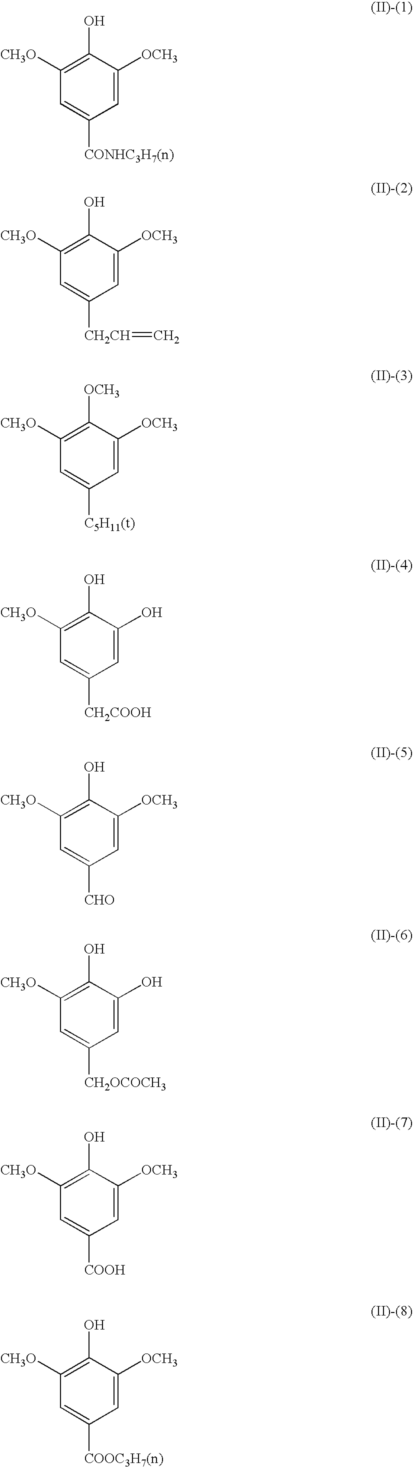

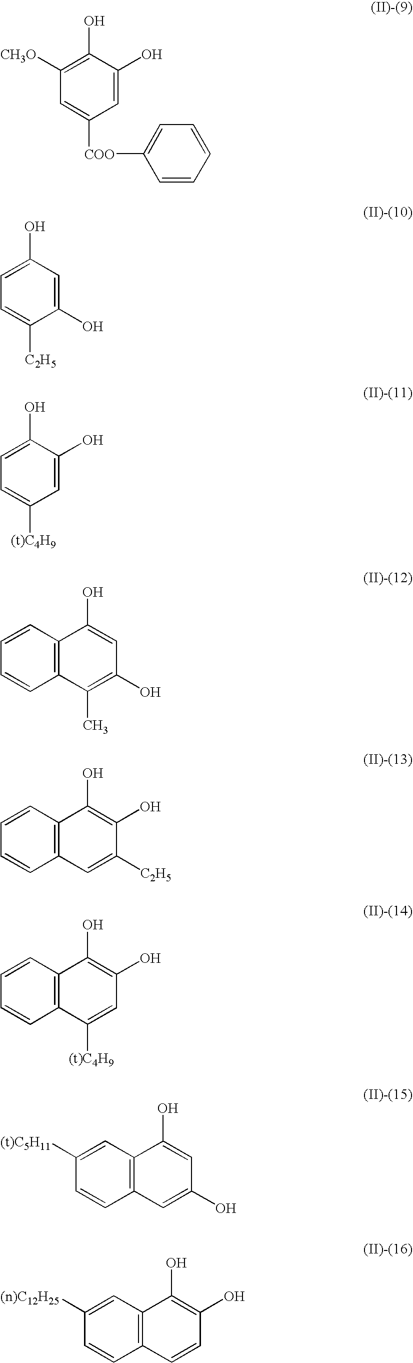

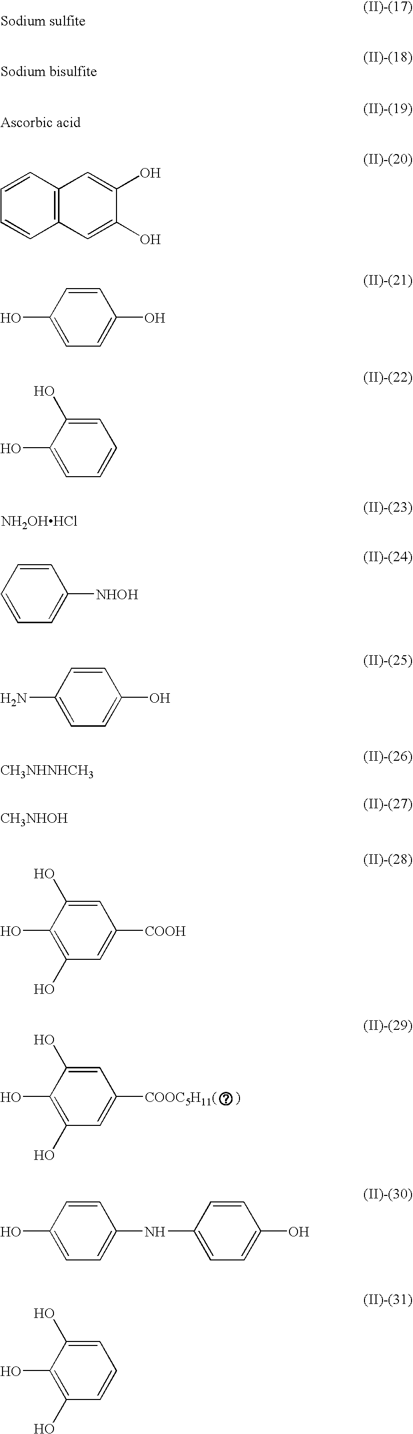

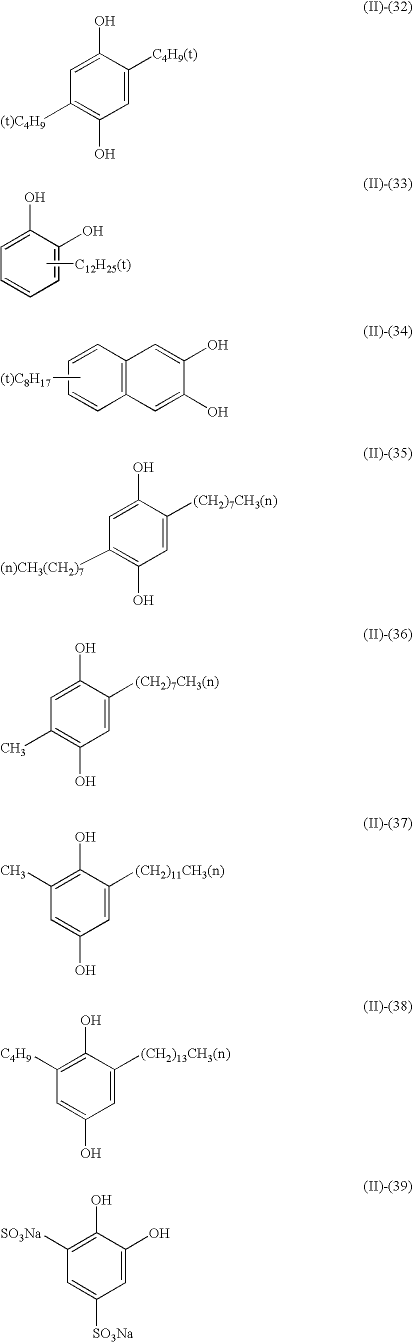

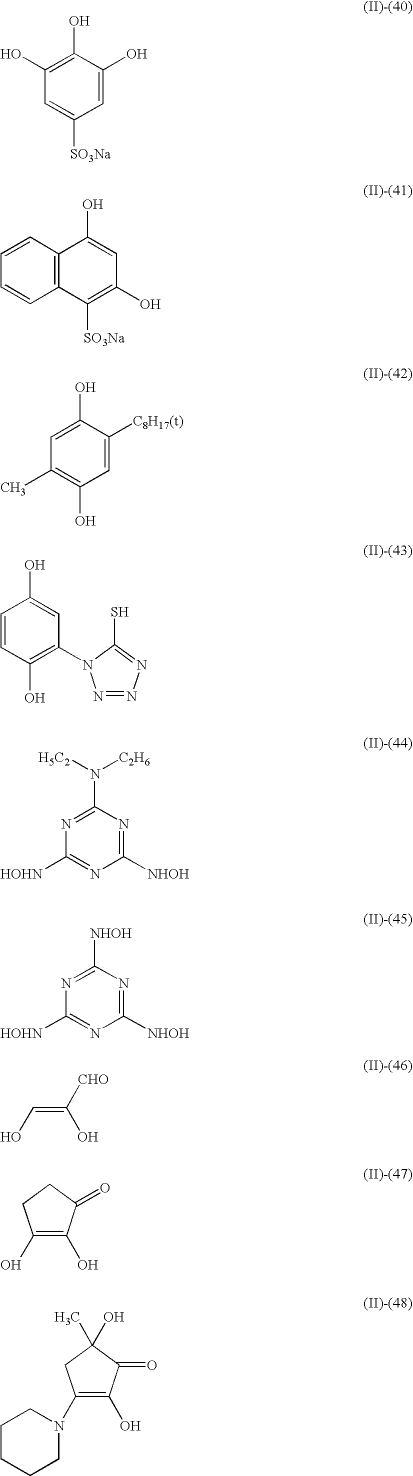

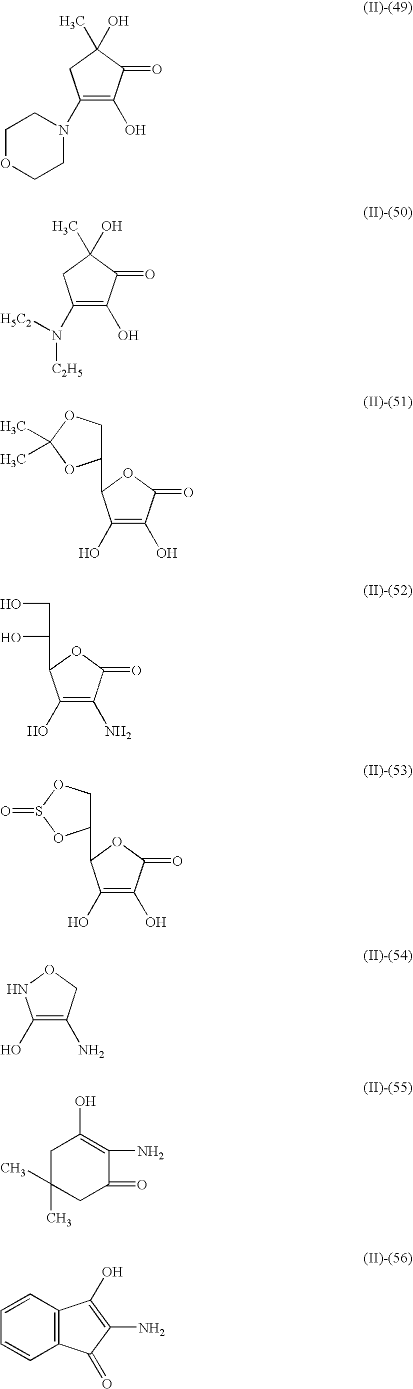

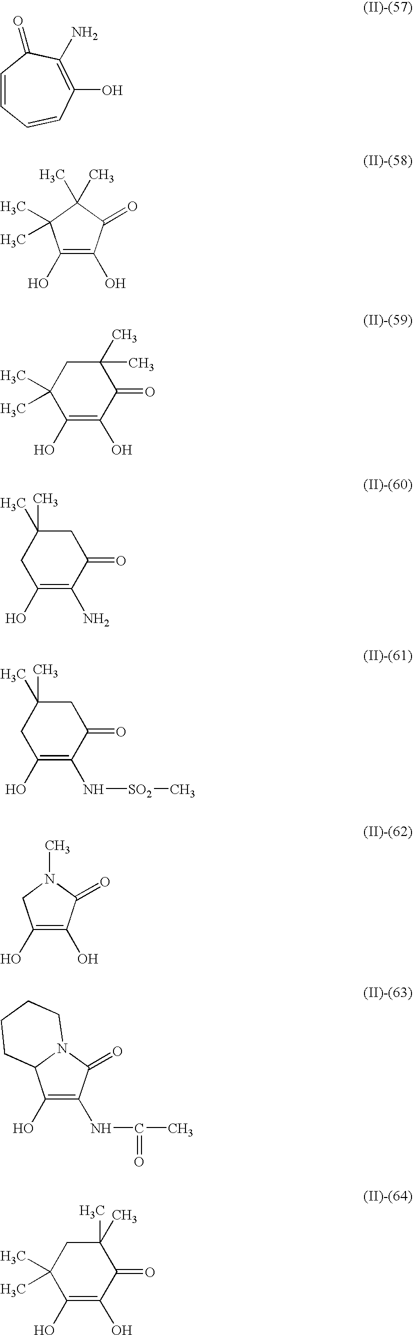

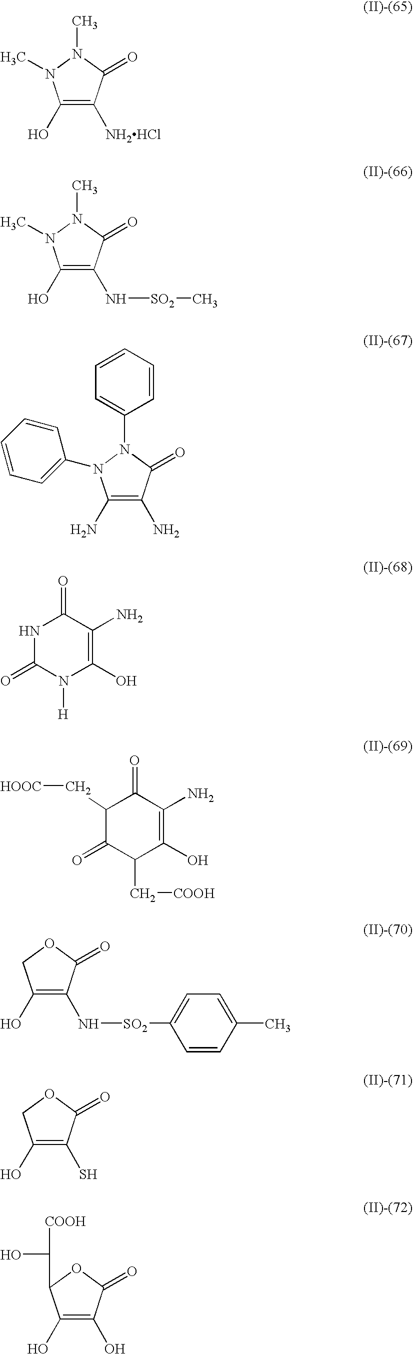

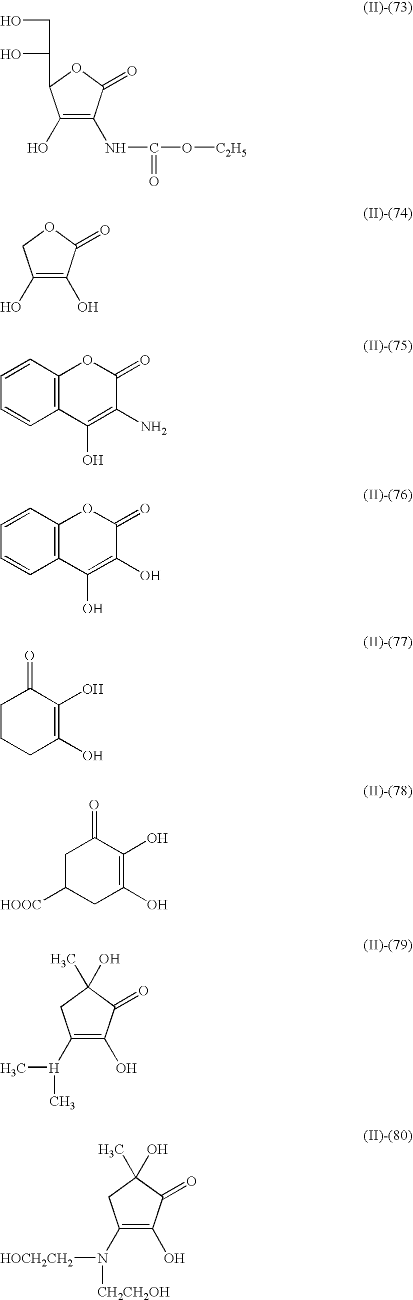

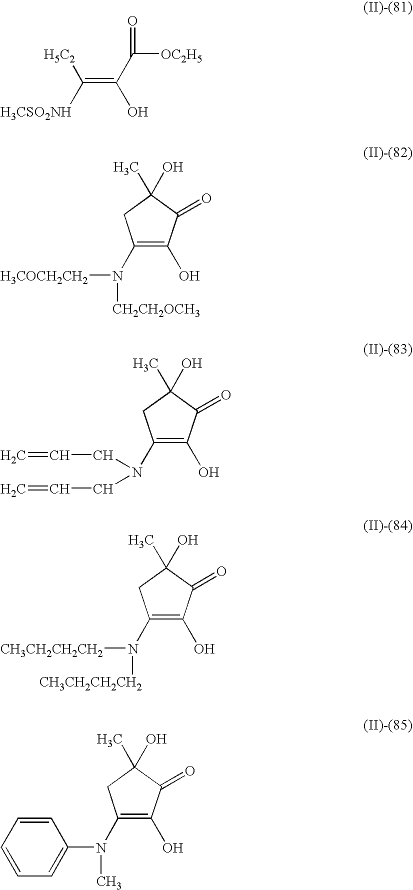

A preferred antioxidant is represented by the following formula (II).

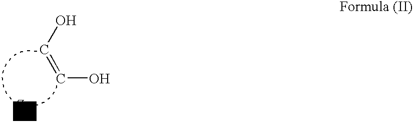

In the formula, Z₁₁ represents an atomic group necessary for forming a carbon ring or a hetero cyclic; preferred specific examples of the carbon ring include a benzene ring and a naphthalene ring; and preferred specific examples of the hetero ring include a 7-membered ring containing an oxygen atom as a hetero atom. Specific examples of a substitutent which can be substituted on such a ring include an alkyl group, an alkoxy group, an alkoxycarbonyl group, a hydroxyl group, and a sulfonic group.

Of the compounds represented by the formula (II), a compound containing at least one sulfonic group (sulfonate) on an aromatic carbon ring is especially preferable. Especially preferred specific examples of the antioxidant include the foregoing specific examples II-(19), II-(22) and II-(39). Besides the compounds represented by the formula (II), the following antioxidants (1) and (2) are also preferable as an antioxidant having a molecular weight of not more than 330.

(1) A 2-cyclopenten-1-one derivative in which one of substituents at the 2-position is a group selected from a hydroxyl group, an amino group and a substituted amino group, with the other being a hydrogen atom, and one of substituents at the 3-position is a group selected from a hydroxyl group, an amino group and a substituted amino group, with the other being a hydrogen atom.
(2) A 2-cyclohexen-1-one derivative in which one of substituents at the 2-position is group selected from a hydroxyl group, all amino group and a substituted amino group, with the other being a hydrogen atom, and one of substituents at the 3-position is a group selected from a hydroxyl group, an amino group and a substituted amino group, with the other being a hydrogen atom. In (1) and (2), compounds containing a hydroxyl group at the 2-position and an amino group or a substituted amino group at the 3-position are more preferable. Of (1) and (2), (1) is preferable; and compounds containing pyrrolidin-1-yl, piperidin-1-yl or morpholin-1-yl at the 3-position and a hydroxyl group at the 2-position are the most preferable. Concretely, Illustrative Compounds (II)-(48) and (II)-(49) are enumerated.

### <Oxidizing Agent>

It is preferable that an oxidizing agent is contained in the emulsion layer according to the invention. By adding the oxidizing agent in the emulsion layer, fog is hardly generated, and pressure properties can be improved.

Though the addition amount is preferably in the range of 1×10⁻⁸˜1×10⁻² moles/mole-Ag, and more preferably 1×10⁻⁶˜5×10⁻³ moles/mole-Ag, the addition amount can be properly chosen depending upon the kind of the silver halide, the kind of the oxidizing agent, and the like.

The oxidizing agent as referred to herein is a compound having an action to act on metallic silver and convert it into a silver ion. In particular, a compound capable of converting an extremely fine silver part produced as a by-product in the formation step of a silver halide grain and chemical sensitization step into a silver ion is effective. The silver ion formed herein may form a silver salt which is sparingly soluble in water, such as silver halides, silver sulfide, and silver selenium or may form a silver salt which is easily soluble in water, such as silver nitrate. The oxidizing agent for silver may be an inorganic material or an organic compound. Examples of the inorganic oxidizing agent include ozone, hydrogen peroxide and adducts thereof (for example, NaBO₂.H₁₂O₂.3H₂O, 2NaCO₃.3H₂O₂, Na₄P₂O₇.2H₂O₂, and 2Na₂SO₄.H₂O₂.2H₂O), oxyacid salts such as peroxy acids (for example, K₂S₂O₈, K₂C₂O₆, and K₂P₂O₈), peroxy complex compounds (for example, K₂[Ti(O₂)C₂O₄].3H₂O, 4K₂SO₄.Ti(O₂)OH.SO₄.2H₂O, and Na₃[VO(O₂)(C₂H₄)₂.6H₂O]), permanganic acid salts (for example, KMnO₄), and chromic acid salts (for example, K₂Cr₂O₇), halogen elements such as iodine and bromine, perhalogenic acid salts (for example, potassium periodate), and salts of a metal of a high valence (for example, potassium hexacyanoferrate(III)). Also, examples of the organic oxidizing agent include quinones such as p-quinone, organic peroxides such as peracetic acid and perbenzoic acid, and compounds capable of releasing an active halogen (for example, N-bromosuccimide, chloramine T, and chloramine B).

Thiosulfonic acid salt compounds represented by the following formulae (XX), (XXI) and (XXII) are especially preferable as the oxidizing agent which is used in the invention, with a compound represented by the formula (XX) being the most preferable.

R—SO₂S-M Formula (XX)

R—SO₂S—R¹ Formula (XXI)

R—SO₂S-Lₘ-—SSO₂—R² Formula (XXII)

In the formulae (XX), (XXI) and (XXII), R, R¹ and R² may be the same or different and each represents an aliphatic group, an aromatic group or a heterocyclic group; M represents a cation; L represents a divalent connecting group; and m is 0 or 1. The compounds of the formulae (XX) to (XXII) may be a polymer containing, as a repeating unit, a divalent group derived from a structure represented by (XX) to (XXII). Also, R, R¹, R² and L may be taken together to form a ring.

It is reported in S. Gahler, Verffwiss. Photo lab Wolfen X, 63 (1965) that when silver is present, a thiosulfonic acid oxidizes silver to form silver sulfide according to the following reaction formula.

RSO₂SM+2Ag→RSO₂M+Ag₂S

It is experimentally confirmed that such oxidization takes place. The thiosulfonic acid salt compound is hereunder described.

The aliphatic group represented by R, R¹ and R² is a saturated or unsaturated, linear, branched or cyclic aliphatic hydrocarbon group, and preferably an alkyl group having 1 to 22 carbon atoms or an alkenyl group or alkynyl group having from 2 to 22 carbon atoms, each of which may contain a substituent. Examples of the alkyl group include methyl ethyl, propyl, butyl, pentyl, hexyl, octyl, 2-ethylhexyl, decyl, dodecyl, hexadecyl, octadecyl, cyclohexyl, isopropyl, and t-butyl. Examples of the alkenyl group include allyl and butenyl. Examples of the alkynyl group include propargyl and butynyl.

The aromatic group represented by R, R¹ and R² includes a monocyclic or fused ring aromatic group and is preferably one having from 6 to 20 carbon atoms, for example, phenyl and naphthyl. These may be substituted.

The heterocyclic group represented by R, R¹ and R² is a 3- to 15-membered ring containing at least one element selected from nitrogen, oxygen, oxygen, sulfur, selenium and tellurium and containing at least one carbon atom, and preferably a 3- to 6-membered ring, for example, pyrrolidine, piperidine, pyridine, tetrahydrofuran, thiophene, oxazole, thiazole, imidazole, benzothiazole, benzoxazole, benzimidazole, selenazole, benzoselenazole, tetrazole, triazole, benzotriazole, tetrazole, oxadiazole, and thiadiazole rings.

Examples of the substituent of R, R¹ and R² include an alkyl group (for example, methyl, ethyl, and hexyl), an alkoxy group (for example, methoxy, ethoxy, and octyloxy), an aryl group (for example, phenyl, naphthyl, and tolyl), a hydroxyl group, a halogen atom (for example, fluorine, chlorine, bromine, and iodine), an aryloxy group (for example, phenoxy), an alkylthio group (for example, methylthio and butylthio), an arylthio group (for example, phenylthio), an acyl group (for example, acetyl, propionyl, butyryl, and valeryl), a sulfonyl group (for example, methylsulfonyl and phenylsulfonyl), an acylamino group (for example, acetylamino and benzoylamino), a sulfonylamino group (for example, methanesulfonylamino and benzenesulfonylamino), an acyloxy group (for example, acetoxy and benzoxy), a carboxyl group, a cyano group, a sulfo group, an amino group, an SO₂SM group (M represents a monovalent cation), and an —SO₂R¹ group.

The divalent connecting group represented by L is an atom or an atomic group containing at least one of C, N, S and O. Concretely, a single group such as an alkylene group, an alkenylene group, an alkynylene group, an arylene group, —O—, —S—, —NH—, —CO—, and —SO₂—; and a combination thereof are enumerated.

L is preferably a divalent aliphatic group or a divalent aromatic group. Examples of the divalent aliphatic group represented by L include —(C₂H₂)ₙ— (n=1˜12), —CH₂—CH═CH—CH₂—,

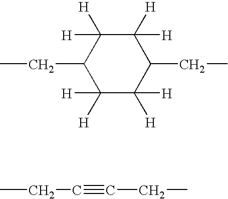

and a xylene group. Examples of the divalent aromatic group include a phenylene group and a naphthylene group.

These substituents may be further substituted with the foregoing substituents.

M is preferably a metal ion or an organic cation. Examples of the metal ion include a lithium ion, a sodium ion, and a potassium ion. Examples of the organic cation include an ammonium ion (for example, ammonium, tetramethylammonium, and tetrabutylammonium), a phosphonium ion (for example, a tetraphenylphosphonium), and a quanidyl group.

Specific examples of the compound represented by the formula (XX), (XXI) or (XXII) are given below, but it should not be construed that the invention is limited thereto.

The compounds represented by the formulae (XX), (XXI) and (XXII) can be synthesized by a method described in JP-A-54-1019, U.K. Patent No. 972,211, or Journal of Organic Chemistry, Vol. 53, page 396 (1988).

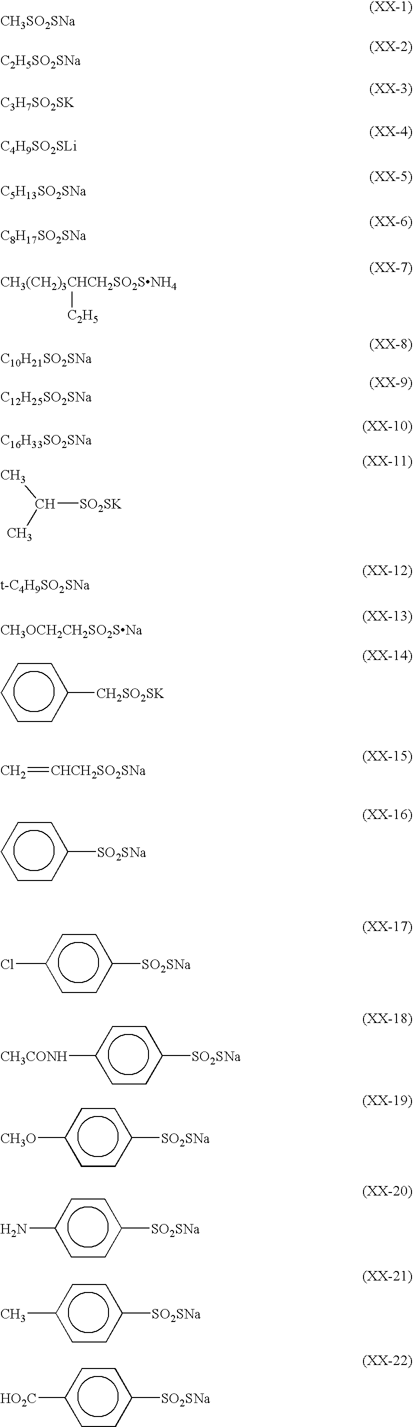

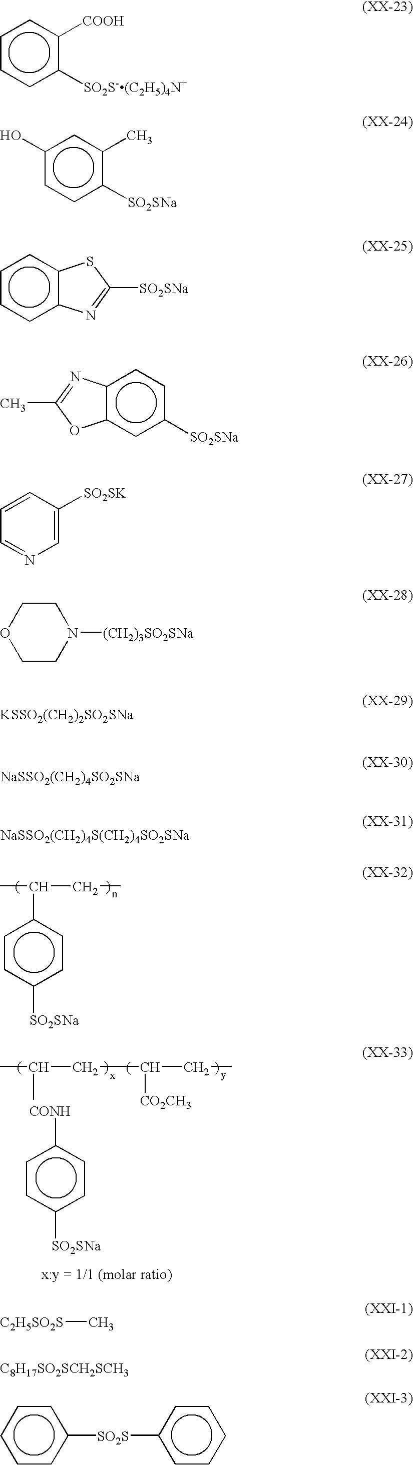

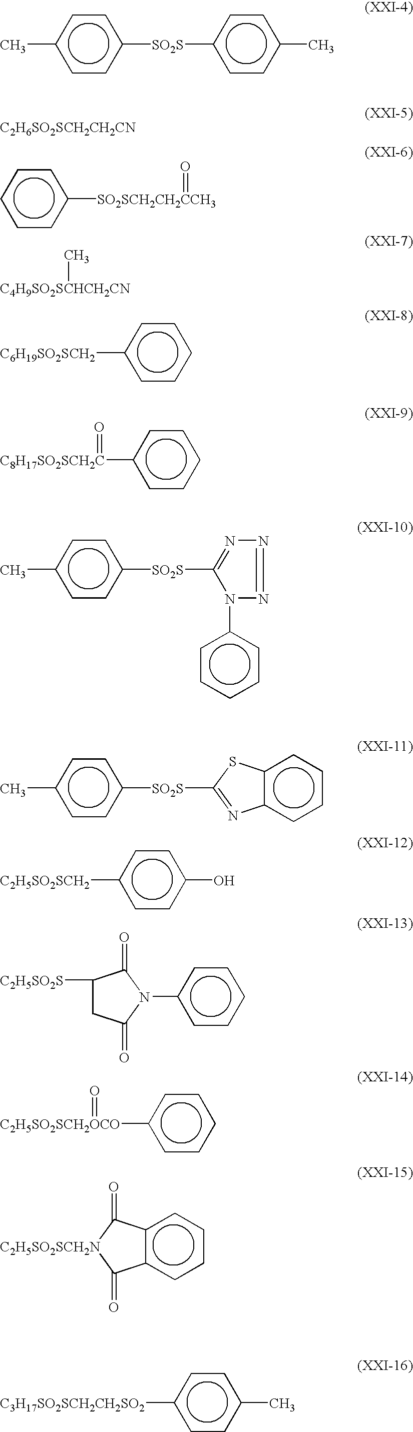

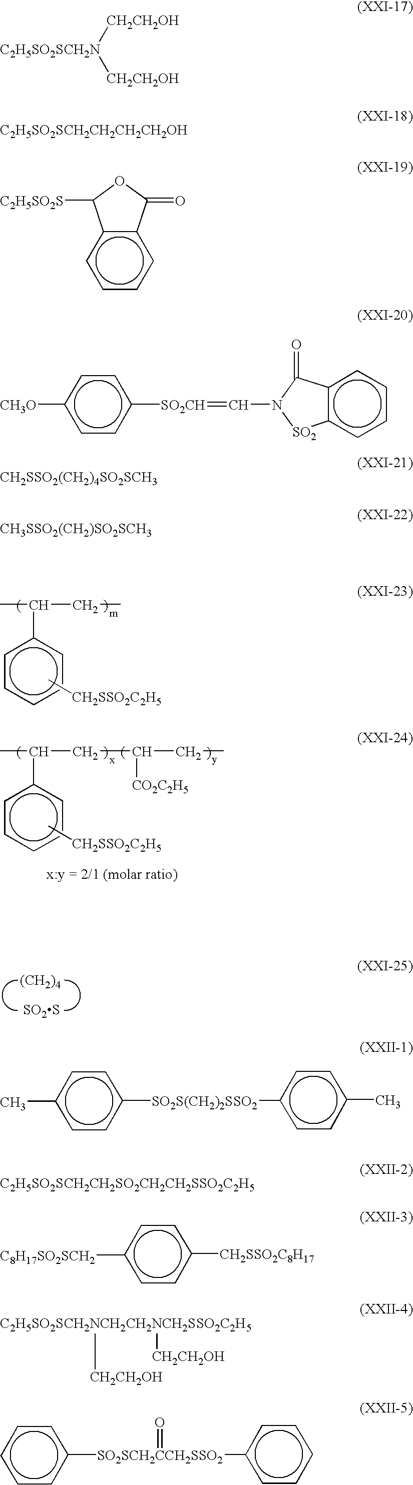

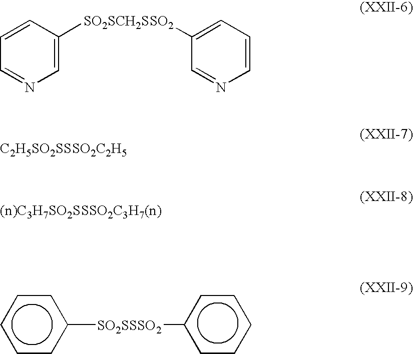

The compound represented by the formula (XX), (XXI) or (XXII) is preferably added in an amount of from 10⁻⁷ to 10⁻¹ moles per mole of the silver salt. The addition amount is more preferably from 10⁻⁶ to 10⁻², and especially preferably from 10⁻⁵ to 10⁻³ moles/mole-Ag.

For adding the compound represented by the formula (XX), (XXI) or (XXII) during the grain formation, a method which is usually employed in the case of adding an additive in an emulsion can be applied. For example, a compound which is soluble in water can be added as an aqueous solution having a suitable concentration; and a compound which is insoluble or sparingly soluble in water can be added as a solution obtained through dissolution in a solvent which does not adversely affect a photographic characteristic among suitable solvents compatible with water, for example, alcohols, glycols, ketones, esters, and amides.

The compound represented by the compound (XX), (XXI) or (XXII) may be added at any stage of manufacture during the grain formation of the silver halide emulsion or before or after the chemical sensitization.

Though any of the compounds (XX) to (XII) may be previously added in a reactor, it may be previously added in an aqueous solution of a water-soluble silver salt or a water-soluble alkali halide to prepare an aqueous solution, which is then subjected to grain formation. A method in which the solution of any of the compounds (XX) to (XXII) is dividedly added or continuously added over a long period of time during the manufacturing step of a grain is preferable, too.

### <Matting Agent>

It is preferable that a matting agent is contained in the emulsion layer according to the invention. By adding the matting agent in the emulsion layer, fog is hardly generated, and pressure properties can be improved. Though the addition amount is preferably in the range of 5˜400 mg/m², and more preferably in the range of 10˜200 mg/m², the addition mount can be properly chosen depending upon the kind of the matting agent or the like.

Examples of the matting agent include compounds described in page 19, left-hand upper column, line 15 to page 19, right-hand upper column, line 15 of JP-A-2-103536.

### <Slipping Agent>

It is preferable that a slipping agent is contained in the emulsion layer according to the invention. By adding the slipping agent in the emulsion layer, fog is hardly generated, and pressure properties can be improved.

Examples of the useful slipping agent include silicon based slipping agents described in U.K. Patents Nos. 955,061 and 1,143,118, U.S. Pat. Nos. 3,042,522, 3,080,317, 4,004,927, 4,047,958 and 3,489,576, and JP-A-60-140341; higher fatty acid based, higher aliphatic alcohol based and higher fatty acid amide based slipping agents described in U.S. Pat. Nos. 2,454,043, 2,732,305, 2,976,148 and 3,206,311, and German Patents Nos. 1,284,295 and 1,284,294; metallic soaps described in U.K. Patent No. 1,263,722 and U.S. Pat. No. 3,933,516; higher fatty acid ester based and higher aliphatic alcohol ether based slipping agents described in U.S. Pat. Nos. 2,588,765 and 3,121,060 and U.K. Patent No. 1,198,387; and taurine based slipping agents described in U.S. Pat. Nos. 3,502,437 and 3,042,222. Specific examples thereof are given below, but it should not be construed that the slipping agent which can be used in the invention is limited thereto.

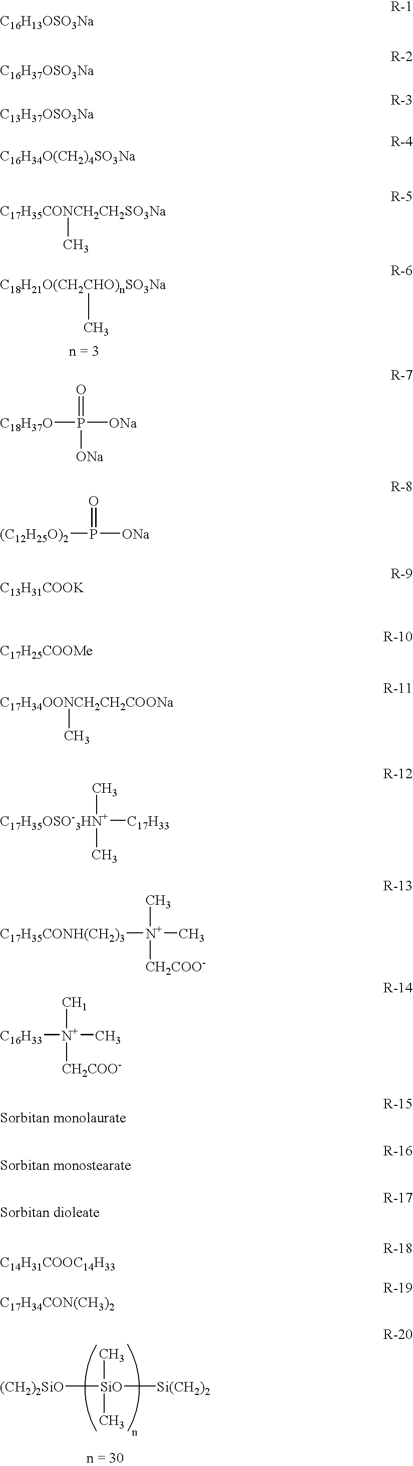

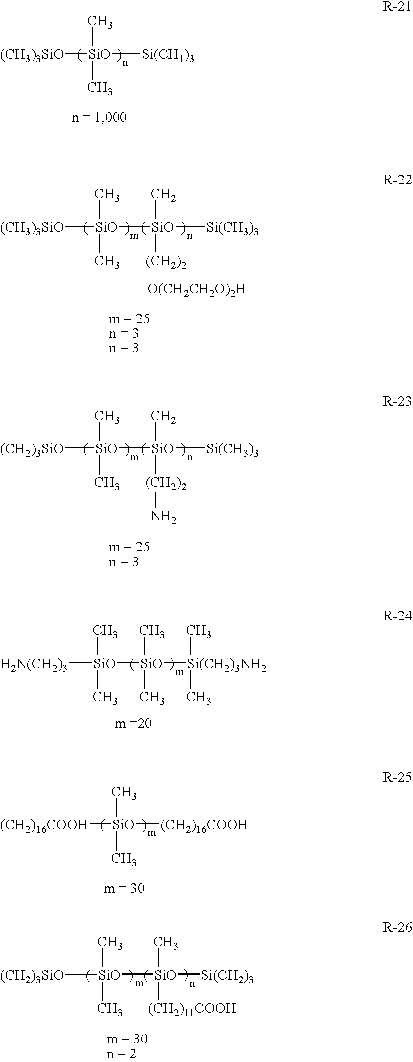

With respect to the use amount of the slipping agent, though its optimum amount varies with the deposition amount of gelatin in an outermost layer, the kind of the matting agent, and the like, it is 5˜200 mg, and preferably 15˜150 mg per m² of one surface.

### <Colloidal Silica>

It is preferable that colloidal silica is contained in the emulsion layer according to the invention. By adding colloidal silica in the emulsion layer, fog is hardly generated, and pressure properties can be improved. Though the addition amount is preferably in the range of 0.01˜2.0 and more preferably in the range of 0.1˜0.6 in terms of a dry weight ratio based on a binder (for example, gelatin) of the addition layer, the addition amount can be properly chosen.

The colloid-like silica (colloidal silica) which is preferably used in the invention refers to a colloid of a fine particle of silicic anhydride having an average particle size of 1 nm or more and not more than 1 μm, and those described in JP-A-53-112732, JP-B-57-009051 and JP-B-57-51653 can be made hereof by reference. Such colloidal silica can be prepared by a sol-gel method and used, and commercially available products can be utilized. In the case where colloidal silica is prepared by a sol-gel method, it can be synthesized by referring to Werner Stober, et al., J. Colloid and Interface Sci., 26, 62-69 (1968), Ricky D. Badley et al., Langmuir, 6, 792-801 (1990), and Skikizai Kyokaishi (Journal of the Japan Society of Colour Material), 61[9], 488-493 (1988). Also, in the case where a commercially available product is used, SNOWTEX-XL (average particle size: 40˜60 nm), SNOWTEX-YL (average particle size: 50˜80 nm), SNOWTEX-ZL (average particle size: 70˜100 nm), PST-2 (average particle size: 210 nm), MP-3020 (average particle size: 328 nm), SNOWTEX 20 (average particle size: 10˜20 mm, SiO₂/Na₂O>57), SNOWTEX 30 (average particle size: 10˜20 mm, SiO₂/Na₂O>50), SNOWTEX C (average particle size: 10˜20 nm, SiO₂/Na₂O>100), and SNOWTEX O (average particle size: 10˜20 nm, SiO₂Na₂O>500), all of which are manufactured by Nissan Chemical Industries, Ltd., and the like can be preferably used (the term “SiO₂/Na₂O” as referred to herein is a content weight ratio of silicon dioxide to sodium hydroxide as expressed by converting sodium hydroxide to Na₂O and is described in a brochure). In the case where a commercially available product is utilized, SNOWTEX-YL, SNOWTEX-ZL, PST-2, MP-3020 and SNOWTEX C are especially preferable. Though a major component of colloidal silica is silicon dioxide, alumina or sodium aluminate or the like may be contained as a minor component; and an inorganic base such as sodium hydroxide, potassium hydroxide, lithium hydroxide, and ammonia or an organic base such as tetramethylammonium may be further contained as a stabilizer.

As the colloidal silica of the invention, colloidal silica having a long and narrow shape of 1˜50 nm in thickness and 10˜1,000 nm in length as described in JP-A-10-268464; and a composite particle of colloidal silica and an organic polymer as described in JP-A-9-218488 or JP-A-10-111544 can also be preferably used.

### <Antistatic Agent>

It is preferable that an antistatic agent is contained in the emulsion layer according to the invention. By adding the antistatic agent in the emulsion layer, fog is hardly generated, and pressure properties can be improved.

As an antistatic layer, a conductive substance-containing layer having a surface resistive of not more than 10¹²Ω in an atmosphere at 25° C. and 25% RH can be preferably used. In the invention, as the preferred antistatic agent, the following conductive substances can be preferably used.

Conductive substances described in page 2, left-hand lower part, line 13 to page 3, right-hand upper part, line 7 of JP-A-2-18542. Concretely, metal oxides described in page 2, right-hand lower part, lines 2 to 10 of ibid.; and conductive high molecular weight compounds P-1 to P-7 of ibid. Acicular metal oxides described in U.S. Pat. No. 5,575,957, paragraphs 0045 to 0043 of JP-A-10-142738, and paragraphs 0013 to 0019 of JP-A-11-223901 and the like can be used.

Examples of the conductive metal oxide particle which is used in the invention include particles of ZnO, TiO₂, SnO₂, Al₂O₃, In₂O₃, MgO, BaO and MoO₃ and composite oxides thereof and metal oxides of such a metal oxide further containing a different kind of atom. As the metal oxide, SnO₂, ZnO, Al₂O₃, TiO₂, In₂O₃ and MgO are preferable; SnO₂, ZnO, In₂O₃ and TiO₂ are more preferable; and SnO₂ is especially preferable. Examples of the metal oxide containing a small amount of a different kind of atom include materials doped with 0.01˜30% by mole (preferably 0.1˜10% by mole) of a different kind of atom, for example, ZnO doped with Al or In, TiO₂ doped with Nb or Ta, In₂O₃ doped with Sn, and SnO₂ doped with Sb, Nb or a halogen element. When the addition amount of the different kind of atom is less than 0.01% by mole, sufficient conductivity is hardly imparted to the oxide or composite oxide, whereas when it exceeds 30% by mole, since a degree of blackening of the particle increases and the antistatic layer becomes black, such is not suitable. Accordingly, in the invention, as a material of the conductive metal oxide particle, those containing a small amount of a different kind of atom in a metal oxide or composite oxide are preferable. Those containing an oxygen defect in a crystal structure are also preferable.

As the foregoing conductive metal oxide fine particle containing a small amount of a different kind of atom, an SnO₂ particle doped with antimony is preferable; and an SnO₂ particle doped with 0.2˜2.0% by mole of antimony is especially preferable.

The shape of the conductive metal oxide which is used in the invention is not particularly limited, and examples thereof include granular and acicular shapes. Also, its side is 0.5˜25 μm in terms of an average particle size as converted to a sphere.

For the purpose of obtaining conductivity, it is also possible to use, for example, a soluble salt (for example, chlorides and nitrates), a metal vapor deposited layer, an ionic polymer described in U.S. Pat. Nos. 2,861,056 and 3,206,312, or an insoluble inorganic salt described in U.S. Pat. No. 3,428,451.

It is preferable that the antistatic layer containing such a conductive metal oxide particle is provided as an undercoat layer on a back surface, an undercoat layer of the emulsion layer, or the like. Its addition amount is preferably 0.01˜1.0 g/m² in terms of a total sum on the both surfaces.

Also, it is preferable that an internal resistivity of the photosensitive material is 1.0×10⁷˜1.0×10¹²Ω in an atmosphere at 25° C. and 25% RH.

In the invention, in addition to the foregoing conductive substance, by using jointly a fluorine-containing surfactant described in page 4, right-hand upper part, line 2 to page 4, right-hand lower part, line 3 from the bottom of JP-A-2-18542 and page 12, left-hand lower part, line 6 to page 13, right-hand lower part, line 5 of JP-A-3-39948, more satisfactory antistatic characteristics can be obtained.

### <Other Additives>

Various additives which are used in the photosensitive material of the invention are not particularly limited, and for example, those described in the following patent documents can be preferably used.

### 1) Nucleation Promoter:

Examples of the foregoing nucleation promoter include compounds of the formulae (I), (II), (III), (IV), (V) and (VI) described in JP-A-6-82943; compounds of the formulae (II-m) to (II-p) and Compounds II-1 to II-22 described in page 9, right-hand upper column, line 13 to page 16, left-hand upper column, line 10 of JP-A-2-103536; and compounds described in JP-A-1-179939.

### 2) Spectral Sensitizing Coloring Matter:

Examples of the foregoing spectral sensitizing coloring matter include spectral sensitizing coloring matters described in page 8, left-hand lower column, line 13 to right-hand lower column, line 4 of JP-A-2-12236; page 16, right-hand lower column, line 3 to page 17, left-hand lower column, line 20 of JP-A-2-103536; JP-A-1-112235; JP-A-2-124560; JP-A-3-7928; and JP-A-5-11389.

### 3) Surfactant:

Examples of the foregoing surfactant include surfactants described in page 9, right-hand upper column, line 7 to right-hand lower column, line 7 of JP-A-2-12236; and page 2, left-hand lower column, line 13 to page 4, right-hand lower column, line 18 of JP-A-2-18542.

### 4) Antifoggant:

Examples of the foregoing antifoggant include thiosulfinic acid compounds described in page 17, right-hand lower column 19 to page 18, right-hand upper column, line 4 and right-hand lower column, lines 1 to 5 of JP-A-2-103536; and JP-A-1-237538.

### 5) Polymer Latex:

Examples of the foregoing polymer latex include those described in page 18, left-hand lower column, lines 12 to 20 of JP-A-2-103536.

### 6) Acid Group-Containing Compound:

Examples of the foregoing acid group-containing compound include compounds described in page 18, right-hand lower column, line 6 to page 19, left-hand upper column, line 1 of JP-A-2-103536.

### 7) Hardener:

Examples of the foregoing hardener include compounds described in page 18, right-hand column, lines 5 to 17 of JP-A-2-103536.

### 8) Black Spot Preventing Agent:

The foregoing black spot preventing agent is a compound capable of retraining the generation of spot-like developed silver in an unexposed area, and examples thereof include compounds described in U.S. Pat. No. 4,956,257 and JP-A-1-118832.

### 9) Redox Compound:

Examples of the redox compound include compounds represented by the formula (I) (especially Compounds 1 to 50) of JP-A-2-301743; compounds of the formulae (R-1), (R-2) and (R-3) and Compounds 1 to 75 described in pages 3 to 20 of JP-A-3-174143; and compounds described in JP-A-5-257239 and JP-A-4-278939.

### 10) Monomethine Compound:

Examples of the foregoing monomethine compound compounds of the formula (II) (especially Compounds II-1 to II-26) of JP-A-2-287532.

### 11) Dihydroxybenzene:

Examples of the dihydroxybenzene include compounds described in page 11, left-hand upper column to page 12, left-hand lower column of JP-A-3-39948; and European Patent No. 452,772A.

### [Binder Layer]

It is preferable that the photosensitive material according to the invention has a binder layer in a lower layer of the emulsion layer. The “lower layer” as referred to herein means that it is closer from the support and is located on the same surface. In the invention, a binder layer composed of a hydrophilic colloid layer can be preferably set up in a lower layer than the silver salt emulsion layer.

Though it is advantageous to use gelatin as the binder, hydrophilic colloids other than this can also be used. Examples thereof include various synthetic hydrophilic high molecular weight substances, for example, gelatin derivatives; graft polymers of gelatin and other high molecular weight material; proteins such as albumin and casein; cellulose derivatives such as hydroxyethyl cellulose, carboxymethyl cellulose, and cellulose sulfuric acid esters; sugar derivatives such as sodium alginate and starch derivatives; and homo- or copolymers such as polyvinyl alcohol, polyvinyl alcohol partial acetal, poly-N-vinylpyrrolidone, polyacrylic acid, polymethacrylic acid, polyacrylamide, polyvinyl imidazole, and polyvinylpyrazole. As gelatin, in addition to lime-processed gelatin, acid-processed gelatin may be used; and gelatin hydrolyzates and gelatin enzymatic hydrolyzates can also be used.

In the photosensitive material of the invention, when the binder layer is provided in a lower layer than the silver salt emulsion layer, a thickness of the binder layer is preferably in the range of from 0.2 μm to 2 μm, and more preferably in the range of from 0.5 μm to 1 μm.

### (Manufacturing Method of Conductive Film)

A manufacturing method of a suitable conductive film as the light transmitting electromagnetic wave shielding film by using the foregoing photosensitive material is described.

The manufacturing method of the conductive film of the invention is characterized by exposing a photosensitive material having an emulsion layer containing a photosensitive silver halide salt on a support and developing it to form a metallic silver part and a light transmitting part in an exposed area and an unexposed area, respectively and further applying physical development and/or plating treatment to the foregoing metallic silver part, thereby supporting a conductive metal on the foregoing metallic silver part.

Incidentally, the conductive film obtained by the invention includes not only one in which the metal is formed on the support by pattern exposure but also one in which the metal is formed by surface exposure.

The manufacturing method of the conductive film of the invention includes the following three embodiments depending upon the photosensitive material and the mode of development treatment.

(1) An embodiment in which a physical development nucleus-free photosensitive silver halide black-and-white material is subjected to chemical development or thermal development to form a metallic silver part on the photosensitive material.
(2) An embodiment in which a photosensitive silver halide black-and-white material containing a physical development nucleus in a silver halide emulsion layer is subjected to dissolution physical development to form a metallic silver part on the photosensitive material.
(3) An embodiment in which a physical development nucleus-free photosensitive silver halide black-and-white material and an image receiving sheet having a physical development nucleus-containing non-photosensitive layer are superimposed and subjected to diffusion transfer development to form a metallic silver part on the non-photosensitive image receiving sheet.

The foregoing embodiment (1) is of an integrated black-and-white development type, and a light transmitting conductive film such as a light transmitting electromagnetic wave shielding film is formed on the photosensitive material. In view of the matter that the resulting developed silver is chemically developed silver or thermally developed silver and is a filament with a high specific surface, it has high activity in a plating or physical development step to be carried out subsequently.

In the foregoing embodiment (2), a silver halide grain in the vicinity of the physical development nucleus is dissolved and deposited on the physical nucleus in the exposed area, whereby a light transmitting conductive film such as a light transmitting electromagnetic wave shielding film and a light transmitting conductive film is formed on the photosensitive material. This is of an integrated black-and-white development type, too. Since the development action is deposition on the physical development nucleus, though the developed silver has high activity, it is a sphere with a small specific surface.

In the foregoing embodiment (3), a silver halide grain is dissolved, diffused and deposited on the development nucleus on the image receiving sheet in the unexposed area, whereby a light transmitting conductive film such as a light transmitting electromagnetic wave shielding film and a light transmitting conductive film is formed on the image receiving sheet. This is of a so-called separate type and is concerned with an embodiment in which the image receiving sheet is striped from the photosensitive material and used.

In all of the embodiments, any development of a negative working development treatment or a reversal development treatment can be chosen (in the case of a diffusion transfer system, by using an auto-positive working photosensitive material as the photosensitive material, a negative working development treatment becomes possible).

The “chemical development”, “thermal development”, “dissolution physical development” and “diffusion transfer development” as referred to herein have the same meanings as in terminologies which are usually used in the art and are explained in general textbooks in the photochemistry, for example, Shin-ichi Kikuchi, Shashinkagaku (Photochemistry) (published by Kyoritsu Shuppan Co., Ltd.) and C. E. K. Mees, The Theory of Photographic Process, 4th ed. Though the present case is concerned with a liquid treatment, with respect to other applications, a thermal development system is also applicable as the development system. For example, JP-A-2004-184693, JP-A-2004-334077, JP-A-2005-010752, and Japanese Patent Applications Nos. 2004-244080 and 2004-085655 are applicable.

### [Exposure]

In the invention, the silver salt-containing layer provided on the support is exposed. The exposure can be carried out by using electromagnetic waves. Examples of the electromagnetic waves include light such as visible light and ultraviolet ray and radiations such as X-ray. Furthermore, a light source having wavelength distribution may be utilized for the exposure, and a light source having a specified wavelength may be used.

Examples of the foregoing light source include scanning exposure using a cathode ray (CRT) exposure unit. The cathode ray tube exposure unit is simple and easy, compact in size and low in costs as compared with a unit using a laser. Also, the cathode ray tube exposure unit is easy for the adjustment of optical axis and color. For the cathode ray tube to be used in image exposure, an illuminant of every kind exhibiting light emission in a spectral region is used as the need arises. For example, any one of a red illuminant, a green illuminant and a blue illuminant or a mixture of two or more kinds thereof is used. The spectral region is not limited to the foregoing red, green or blue spectral region, and a phosphor capable of emitting light in a yellow, orange, violet or infrared region is also useful. In particular, a cathode ray tube capable of emitting light white upon mixing these illuminants is often used. An ultraviolet ray lamp is also preferable; and a g-line of mercury vapor lamp, an i-line of mercury vapor lamp, and the like are utilized, too.

Also, in the invention, it is preferable that the exposure is carried out by using various laser beams. For example, a scanning exposure system using, as a laser, monochromatic high-density light, for example, a gas laser, a light emitting diode, a semiconductor laser, and a second harmonic generation (SHG) light source which is a combination of a semiconductor laser or a solid laser using a semiconductor laser as an excitation light source and a non-linear optical crystal can be preferably employed for the exposure in the invention. In addition, a KrF excimer laser, an ArF excimer laser, an F2 laser, and the like can be used. In order to make the system compact and inexpensive, it is preferable that the exposure is carried out by using a semiconductor laser or a second harmonic generation (SHG) light source which is a combination of a semiconductor laser or a solid laser and a non-linear optical crystal. In order to design a unit which is compact in size, inexpensive in costs, long in life and high in safety, it is especially preferable that the exposure is carried out by using a semiconductor laser.

In the case of using a silver halide, the exposure energy is preferably not more than 1 mJ/cm², more preferably not more than 100 uJ/cm², and further preferably not more than 50 μJ/cm². It is most preferably not more than 40 μJ/cm² and 4 μJ/cm² or more.

Concretely, a blue semiconductor laser having a wavelength of 390˜460 nm (announced by Nichia Corporation in The 48th Annual Meeting of JSAP held in March 2001), a green laser of about 530 nm obtained by wavelength converting a semiconductor laser (oscillation wavelength: about 1,060 nm) by an SHG crystal of LiNbO₃ having an inverted domain structure in a waveguide state and extracting it, a red semiconductor laser having a wavelength of about 685 nm (Hitachi Type No. HL6738 MG), a red semiconductor laser having a wavelength of about 650 nm (Hitachi Type No. HL6501MG), and the like can be preferably employed. In the case of aiming to achieve fine line drawing with higher definition, a laser light source of not more than 420 nm is preferable; and in the case of aiming to achieve a cheap and stable fine line drawing system, a laser light source of 600 nm or more is preferable

As a method of exposing the silver salt-containing layer in a pattern-like form, scanning exposure by leaser beams is preferable. A laser exposure unit described in JP-A-2000-39677 is preferable; and it is also preferable that DMD described in JP-A-2004-1224 is used in a light beam scanning system in place of the beam scanning due to the rotation of a polygon mirror in the subject exposure unit. A DMD (digital mirror device) exposure head described in JP-A-2004-1244 intersects against a support carrying direction. This exposure head is provided with an exposure unit for exposing light beams; a spatial light modulation device in which many pixel parts whose light modulation state varies with each control signal are two-dimensionally arranged on a substrate and which modulates light beams irradiated from the foregoing exposure unit; a control unit for controlling each of plural pixel parts, the number of which is less than the total number of the pixel parts arranged on the foregoing substrate, by a control signal generated corresponding to exposure information; and an optical system for image forming light beams modulated in each pixel part on an exposed surface.

As the support carrying system, a capstan system and a support drive system by suction rollers as seen in a coating apparatus and a slit roller apparatus are preferable. In particular, in the case where the support length reaches several hundreds meters, it is preferred to employ a meandering control mechanism jointly.

As a method of exposing the emulsion layer in a pattern-like form, the pattern exposure may be achieved by surface exposure utilizing a photomask or may be achieved by scanning exposure by laser beams. On that occasion, exposure systems such as refraction type exposure using a lens, reflection type exposure using a reflecting mirror, contact exposure, proximity exposure, reduction projection exposure, and reflection projection exposure can be employed.

In the invention, what the mesh has a pattern in which substantially parallel straight line-like fine lines intersect means a so-called lattice-like pattern and refers to the case where the adjacent straight lines configuring a lattice are in parallel or within (parallel±2°).

It is preferable that the exposure is carried out by scanning light beams while carrying the foregoing photosensitive material.

It is preferable that the direction of principal scanning of light beams is vertical to the carrying direction of the photosensitive material. Also, a light intensity thereof may be one taking two or more values including a state that it is substantially 0 during the scanning exposure or may be one taking only one value.

As the scanning method of light beams, a method in which the exposure is achieved by light sources in a line-like form arranged in a substantially vertical direction to the carrying direction or a rotatory polygon mirror is preferable. In that case, it is required that the light beams are subjected to intensity modulation with two or more values, and the straight line is subjected to patterning in a continuous manner of dots. Since the dots are continuous, though an edge of the fine line of one dot is in a stepwise state, it is meant that the thickness of the fine line is the narrowest length of a constricted portion.

As another system of the scanning method of light beams, it is also preferable that beams, the scanning direction of which is inclined against the carrying direction in accordance with an inclination of the lattice pattern, is scanned. In that ease, it is preferable that two scanning light beams are arranged orthogonally. The light beams take an intensity of substantially one value on an exposed surface.

In the capstan system, an exposure system in which laser exposure is carried out via a photomask having a desired pattern is a preferred embodiment, too. In that case, it is characterized that a size of the laser beam is thicker than a mesh line width which is intended to be ultimately obtained. Also, in that case, even when a fine pattern is obtained, there is an advantage that the fine pattern is obtainable without bringing the photomask into intimate contact with the photosensitive material, and it is possible to reduce the running costs of an expensive photomask. Also, for the purpose of forming a mesh of an electromagnetic wave shielding film for plasma display, it is enough that the size of the photomask is smaller than the display size different from a photomask for surface exposure as utilized in the art.

In the invention, the mesh pattern is preferably inclined at from 30° to 60°, more preferably from 40° to 50°, and most preferably from 43° to 47° against the carrying direction. This is because the preparation of a mask in which the mesh pattern is inclined at about 45° against the frame is generally difficult, thereby causing problems that unevenness is easily generated and that the costs are high; and on the other hand, in the present system, since unevenness is rather hardly generated at around 45°, there is brought an advantage that the effect of the invention is more remarkable against photolithography of a mask contact exposure system or patterning by screen printing.

### [Development Treatment]

In the invention, after exposing the emulsion layer, a development treatment is further carried out. For the development treatment, usual technologies of development treatment which are employed in silver salt films or printing papers, films for printing plate, emulsion masks for photomask, and the like can be employed. Though a developing solution is not particularly limited, PQ developing solutions, MQ developing solutions, MAA developing solutions, and the like can be used; and as commercially available products, developing solutions such as CN-16, CR-56, CP45X, FD-3 and PAPITOL, all of which are manufactured by FUJIFILM Corporation, and C-41, E-6, RA-4, D-19 and D-72, all of which are manufactured by Kodak Corporation, and developing solutions contained in those kits can be used. Also, lith developing solutions can be used.

As the lith developing solution, Kodak's D85 or the like can be used. In the invention, by performing the foregoing exposure and development treatment, not only a metallic silver part, preferably a pattern-like metallic silver part is formed in an exposed area, but also a light transmitting part as described later is formed in an unexposed area.

In the manufacturing method of the invention, a dihydroxybenzene based developing agent can be used as the foregoing developing solution. Examples of the dihydroxybenzene based developing agent include hydroquinone, chlorohydroquinone, isopropylhydroquinone, methylhydroquinone, and hydroquinone monosulfonate, with hydroquinone being especially preferable. Examples of an auxiliary developing agent exhibiting super additivity with the foregoing dihydroxybenzene based developing agent include 1-phenyl-3-pyrazolidones and p-aminophenols. As the developing solution which is used in the manufacturing method of the invention, a combination of a dihydroxybenzene based developing agent and a 1-phenyl-3-pyrazolidone or a combination of a dihydroxybenzene based developing agent and a p-aminophenol is preferably used.

Specific examples of the developing agent to be combined with 1-phenyl-3-pyrazolidone or its derivative which is used as the auxiliary developing agent include 1-phenyl-3-pyrazolidone, 1-phenyl-4,4-dimethyl-3-pyrazolidone, and 1-phenyl-4-methyl-4-hydroxymethyl-3-pyrazolidone.

Examples of the foregoing p-aminophenol based auxiliary developing agent include N-methyl-p-aminophenol, p-aminophenol, N-(β-hydroxyethyl)-p-aminophenol, and N-(4-hydroxyphenyl)glycine, with N-methyl-p-aminophenol being preferable. Though it is preferred to use the dihydroxybenzene based developing agent usually in an amount of 0.05˜0.8 moles/liter, it is especially preferred to use it in an amount of 0.23 moles/liter or more in the invention. More preferably, it is in the range of 0.23˜0.6 moles/liter. Also, in the case of using a combination of a dihydroxybenzene and a 1-phenyl-3-pyrazolidone or a p-aminophenol, the former is preferably used in an amount of 0.23˜0.6 moles/liter, and more preferably 0.23˜0.5 moles/liter, whereas the latter is preferably used in an amount of not more than 0.06 moles/liter, and more preferably 0.03 moles/liter 0.003 moles/liter.

In the invention, it is preferable that both a development initiator and a development replenisher have properties that “when 0.1 moles of sodium hydroxide is added in one liter of the solution, an increase in pH is not more than 0.5”. As a method of confirming that the development initiator or development replenisher has such properties, the pH of the development initiator or development replenisher which is a subject to the test is fixed at 10.5; 0.1 moles of sodium hydroxide is then added in one liter of this solution; on that occasion, a pH value of the solution is measured; and when an increase of the pH value is not more than 0.5, the solution is judged to have the foregoing regulated properties. In particular, it is preferred to use a development initiator and a development replenisher in which when the foregoing test is performed, an increase of the pH value is not more than 0.4.

As a method of imparting the foregoing properties to the development initiator and the development replenisher, a method of using a buffer is preferable. As the foregoing buffer, carbonates, boric acid described in JP-A-62-186259, sugars described in JP-A-60-93433 (for example, saccharose), oximes (for example, acetoxime), phenols (for example, 5-sulfosalicylic acid), tertiary phosphates (for example, sodium salts and potassium salts), and the like can be used; and carbonates and boric acid are preferably used. A use amount of the foregoing buffer (in particular, a carbonate) is preferably 0.25 moles/liter, and especially preferably 0.25˜1.5 moles/liter.

In the invention, a pH of the foregoing development initiator is preferably in the range of 9.0˜11.0, and especially preferably 9.5˜10.7. A pH of the foregoing development replenisher and a pH of the developing solution within a development tank at the continuous treatment are also in this range. As an alkaline agent used for setting up the pH, usual water-soluble inorganic alkali metal salts (for example, sodium hydroxide, potassium hydroxide, sodium carbonate, and potassium carbonate) can be used.

In the manufacturing method of the invention, in treating one square meter of the photosensitive material, the content of the development replenisher in the developing solution is not more than 323 mL, preferably 323˜30 mL, and especially preferably 225˜50 mL. The development replenisher may have the same composition as the development initiator and may have a higher concentration than the initiator with respect to components to be consumed by the development.

In the invention, the developing solution in developing the photosensitive material (both the development initiator and the development replenisher will be hereinafter sometimes summarized and referred to simply as “developing solution”) can contain usually used additives (for example, a preservative and a chelating agent). Examples of the foregoing preservative include sulfites such as sodium sulfite, potassium sulfite, lithium sulfite, ammonium sulfite, sodium bisulfite, potassium metabisulfite, and formaldehyde sodium bisulfite. Though the sulfite is preferably used in an mount of 0.20 moles/liter or more, and more preferably 0.3 moles/liter or more, when it is added in an excess amount, staining of silver is caused in the developing solution, its upper limit is desirably 1.2 moles/liter. The addition amount is especially preferably 0.35˜0.7 moles/liter. As a preservative for the dihydroxybenzene based developing agent, a small amount of an ascorbic acid derivative may be used together with the sulfite. The ascorbic acid derivative as referred to herein includes ascorbic acid, erythorbic acid which is a stereo isomer thereof, and alkali metal salts thereof (for example, sodium and potassium salts). It is preferable in view of material costs that sodium erythorbate is used as the foregoing ascorbic acid derivative. The addition amount of the foregoing ascorbic acid derivative is preferably in the range of 0.03˜0.12, and especially preferably in the range of 0.05˜0.10 in terms of a molar ratio against the dihydroxybenzene based developing agent. In the case of using an ascorbic acid derivative as the foregoing preservative, it is preferable that the developing solution does not contain a boron compound.

Besides the foregoing, development restrainers such as sodium bromide and potassium bromide; organic solvents such as ethylene glycol, diethylene glycol, triethylene glycol, and dimethylformamide; development promoters such as alkanolamines, for example, diethanolamine and triethanolamine and imidazoles and derivatives thereof; and antifoggants or black spot preventing agents such as mercapto based compounds, imidazole based compounds, benzotriazole based compound, and benzimidazole based compounds may be contained as additives which can be used in the development material. Specific examples of the foregoing benzimidazole based compound include 5-nitroindazole, 5-p-nitrobenzoylaminoindazole, 1-methyl-5-nitroindazole, 6-nitroindazole, 3-methyl-5-nitroindazole, 5-nitrobenzimidazole, 2-isopropyl-5-nitrobenzimidazole, 5-nitro-benztriazole, sodium 4-[(2-mercapto-1,3,4-thiadiazol-2-yl)thio]butanesulfonate, 5-amino-1,3,4-thiazole-2-thiol, methylbenzotriazole, 5-methylbenzotriazole, and 2-mercaptobenzotriazole. The content of such a benzoimidazole based compound is usually 0.01˜10 mmoles, and more preferably 0.1˜12 mmoles per liter of the developing solution.

Furthermore, various organic or inorganic chelating agents can be used jointly in the foregoing developing solution. As the foregoing inorganic chelating agent, sodium tetrapolyphosphate, sodium hexametaphosphate, and the like can be used. On the other hand, as the foregoing organic chelating agent, organic carboxylic acids, aminopolycarboxylic acids, organic phosphonic acids, aminophosphonic acids, and organic phosphonocarboxylic acids can be mainly used.

Examples of the foregoing organic carboxylic acid include acrylic acid, oxalic acid, malonic acid, succinic acid, glutaric acid, adipic acid, pimelic acid, azelaic acid, sebacic acid, nonanedicarboxylic acid, succinic acid, decanedicarboxylic acid, undecanedicarboxylic acid, maleic acid, itaconic acid, malic acid, citric acid, and tartaric acid, but it should not be construed that the invention is limited thereto.

Examples of the foregoing aminopolycarboxylic acid include iminodiacetic acid, nitrilotriacetic acid, nitrileotripropionic acid, ethylenediaminemonohydroxyethyltriacetic acid, ethylenediaminetetraacetic acid, glycol ether tetraacetic acid, 1,2-diaminopropanetetraacetic acid, diethylenetriaminetetraacetic acid, triethylenetetraminehexaacetic acid, 1,3-diamino-2-propanoltetraacetic acid, and glycol ether diaminepentaacetic acid; and besides, compounds described in JP-A-52-25632, JP-A-55-67747, JP-A-57-102624, and JP-B-53-40900.

Examples of the organic phosphonic acid include hydroxyalkylidene-diphosphonic acids described in U.S. Pat. Nos. 3,214,454 and 3,794,591 and West German OLS No. 2,227,639 and compounds described in Research Disclosure, Vol. 181, Item 18170 (May 1979).

Examples of the foregoing aminophosphonic acid include aminotris(methylenephosphonic acid), ethylenediaminetetramethylenephosphonic acid, and aminotrimethylenephosphonic acid; and besides, compounds described in the foregoing Research Disclosure, 18170, JP-A-57-208554, JP-A-54-61125, JP-A-55-29883, and JP-A-56-97347.

Examples of the foregoing organic phosphonocarboxylic acid described in JP-A-52-102726, JP-A-53-42730, JP-A-54-121127, JP-A-55-4024, JP-A-55-4025, JP-A-55-126241, JP-A-55-65955, JP-A-55-65956, and we foregoing Research Disclosure, 18170. These chelating agents may be used in a form of an alkali metal salt or an ammonium salt.

The addition amount of such a chelating agent is preferably 1×10⁻⁴˜1×10⁻¹ moles, and more preferably 1×10⁻³˜1×10⁻² moles per liter of the developing solution.

Furthermore, compounds described in JP-A-56-24347, JP-B-56-46585, JP-B-62-2849, and JP-A-4-362942 can be used as a silver staining-preventing agent in the developing solution. Also, compounds described in JP-A-61-267759 can be used as a dissolution aid. Moreover, the developing solution may contain a toning agent, a surfactant, an antifoaming agent, a hardener, and the like as the need arises. Though the development treatment temperature and time are mutually related to each other and are determined in relations with the entire treatment time, the development temperature is in general preferably about 20° C.˜about 50° C., and more preferably 25˜45° C. Also, the development time is preferably 5 seconds˜2 minutes, and more preferably 7 seconds˜one minute 30 seconds.

In view of carrying costs of the developing solution, packaging material costs, space saving, and the like, an embodiment in which the developing solution is concentrated and used upon being diluted at the use is preferable, too. For the purpose of concentrating the developing solution, it is effective to convert a salt component contained in the developing solution into a potassium salt.

The development treatment in the invention can include a fixation treatment for the purpose of stabilization upon removal of the silver salt in an unexposed area. For the fixation treatment in the invention, technologies which are employed in silver salt photographic films or printing papers, printing plate making films, emulsion masks for photomask, and the like regarding a silver halide can be employed.

The following are enumerated as preferred components of a fixing solution which is used in the foregoing fixation step.

That is, it is preferable that the fixing solution contains sodium thiosulfate, ammonium thiosulfate, and optionally, tartaric acid, citric acid, gluconic acid, boric acid, iminodiacetic acid, 5-sulfosalicyclic acid, glucoheptanoic acid, tiron, ethylenediaminetetraacetic acid, diethylenetriaminepentaacetic acid, nitrilotriacetic acid, and salts thereof. From the viewpoint of protecting the circumstance in recent years, it is preferable that boric acid is not contained. Examples of a fixing agent of the fixation solution which is used in the invention include sodium thiosulfate and ammonium thiosulfate; and though ammonium thiosulfate is preferable in view of a fixation rate, sodium thiosulfate may be used from the viewpoint of protecting the environment in recent years. The use amount of such a known fixing agent can be properly altered, it is in general about 0.1 ˜about 2 moles/liter, and especially preferably 0.2˜1.5 moles/liter. The fixation solution can contain a hardener (for example, water-soluble aluminum compounds), a preservative (for example, sulfites and bisulfites), a pH buffer (for example, acetic acid), a pH adjuster (for example, ammonia and sulfuric acid), a chelating agent, a surfactant, a wetting agent, and a fixation promoter, if desired.

Examples of the foregoing surfactant include anionic surfactants such as sulfates and sulfonates, polyethylene based surfactants, and ampholytic surfactants described in JP-A-57-6740. Also, a known antifoaming agent may be added in the foregoing fixation solution.

Examples of the foregoing wetting agent include alkanolamines and alkylene glycols. Also, examples of the foregoing fixation promoter include thiourea derivatives described in JP-B-45-35754, JP-B-58-122535 and JP-B-58-122536; alcohols containing a triple bond in a molecule thereof; thioether compounds described in U.S. Pat. No. 4,126,459; and meso ion compounds described in JP-A-4-229860; and compounds described in JP-A-2-44355 may also be used. Also, as the foregoing pH adjuster, organic acids such as acetic acid, malic acid, succinic acid, tartaric acid, citric acid, oxalic acid, maleic acid, glycolic acid, and adipic acid; and inorganic buffers such as boric acid, phosphates, and sulfites can be used. As the foregoing pH buffer, acetic acid, tartaric acid, and sulfites are preferably used. Here, the pH buffer is used for the purpose of preventing an increase of the pH of the fixing agent to be carried in by the developing solution and preferably used in an amount of about 0.01˜1.0 mole/liter, and more preferably about 0.02˜0.6 moles/liter. The pH of the fixation solution is preferably in the range of 4.0˜6.5, and especially preferably 4.5˜6.0. Compounds described in JP-A-64-4739 can also be used as the foregoing coloring matter elution promoter.

Examples of the hardener in the fixation solution of the invention include water-soluble aluminum salts and chromium salts. A preferred compound as the foregoing hardener is a water-soluble aluminum salt; and examples thereof include aluminum chloride, aluminum sulfate, and potassium alum. The addition amount of the foregoing hardener is preferably 0.01˜0.2 moles/liter, and more preferably 0.03˜0.08 moles/liter.

A fixation temperature in the foregoing fixation step is preferably about 20° C. about 50° C., and more preferably 25˜45° C. Also, a fixation time is preferably 5 seconds one minute, and more preferably 7 seconds˜50 seconds. A replenishment amount of the fixation solution is preferably not more than 600 mL/m², more preferably not more than 500 mL/m², and especially preferably not more than 300 mL/m² against the treatment amount of the photosensitive material.

It is preferable that the photosensitive material which has been subjected to development and fixation treatments is subjected to a water washing treatment or a stabilization treatment. The foregoing water washing treatment or stabilization treatment is usually carried out in an amount of washing water of not more than 20 liters per m² of the photosensitive material and can also be carried out in a replenishment amount of not more than 3 liters (inclusive of zero, namely washing with stored water). For that reason, not only a water-saving treatment becomes possible, but also a conduit for setting up an automatic processor can be made unnecessary. As a method of minimizing the replenishment amount of washing water, a multistage countercurrent system (for example, two stages and three stages) is known from old. In the case of applying this multistage countercurrent system to the manufacturing method of the invention, since the photosensitive material after the fixation is gradually treated towards a normal direction, namely is successively contacted and treated towards a direction of a treatment liquid which is stained with the fixation solution, water washing is achieved more efficiently. Also, in the case where the water washing is carried out with a small amount of water, it is more preferred to provide washing tanks of squeeze rollers and cross-over rollers described in JP-A-63-18350, JP-A-62-287252, and the like. Also, for the purpose of reducing an environmental pollution load which becomes a problem at the washing with a small amount of water, addition of various oxidizing agents and filter filtration may be combined. Furthermore, in the foregoing method, a part or the whole of an overflow liquid from a water washing bat or stabilization bath formed by optionally replenishing water in the water washing bath or stabilization bath which has been subjected to a fungicidal measure can be utilized for the treatment liquid having a fixation ability as a preceding treatment step as described in JP-A-60-235133. In order to prevent bubble unevenness readily generated at the washing with a small amount of water and/or transfer of treating agent components attached to the squeeze rollers to the treated film, a water-soluble surfactant or a defoaming agent may also be added.

In the foregoing water washing treatment or stabilization treatment, for the purpose of preventing staining due to a dye eluted from the photosensitive material, a dye adsorbing agent described in JP-A-63-163456 may also be set in a water washing tank. Also, in the stabilization treatment subsequent to the water washing treatment, a bath containing a compound described in each of JP-A-2-201357, JP-A-2-132435, JP-A-1-102553 and JP-A-46-44446 may be used as a final bath of the photosensitive material. On that occasion, ammonium compounds, metal compounds such as Bi and Al, fluorescent brighteners, various chelating agents, film pH adjusters, hardeners, sterilizers, fungicides, alkanolamines, and surfactants can be added as the need arises. As the water which is used in the water washing step or stabilization step, in addition to city water, water having been subjected to a deionization treatment or water sterilized by a halogen, an ultraviolet bactericidal lamp, an oxidizing agent of every kind (for example, ozone, hydrogen peroxide, and chlorates), or the like is preferably used. Also, washing water containing a compound described in JP-A-4-39652 or JP-A-5-241309 may be used. It is preferable that the bath temperature and time in the water washing treatment or stabilization treatment are 0˜50° C. and 5 seconds˜2 minutes, respectively.

For the preservation of a treatment liquid such as a developing solution and a fixation solution as used in the invention, it is preferable that the treatment liquid is kept by a packaging material with low oxygen permeability described in JP-A-61-73147. Also, in the case of reducing the replenishment amount, it is preferred to prevent vaporization and air oxidation of the liquid by making a contact area of the treatment tank with air small. A roller-carrying type automatic processor is described in U.S. Pat. Nos. 3,025,779 and 3,545,971, etc. In the present description, this is simply referred to as “roller carrying type processor”. Also, it is preferable that the roller carrying type processor is composed of four steps of development, fixation, water washing and drying; and in the invention, though other steps (for example, a stopping step) are not excluded, it is the most preferable that the roller carrying type processor follows these four steps. Also, the roller carrying type processor may be composed of four steps including a stabilization step in place of the water washing step.

In the foregoing respective steps, the components after removing water from the composition of the developing solution or fixation solution may be fed in a solid form and then used as a developing solution or fixation solution upon being dissolved in a prescribed amount of water in the use. A treating agent in such a form is called as a solid treating agent. The solid treating agent is used in a form of power, tablet, granule, powder, block or paste. A preferred form of the foregoing treating agent is a form or tablet as described in JP-A-61-259921. With respect to a manufacturing method of the tablet, the tablet can be manufactured by a general method described in, for example, each of JP-A-51-61837, JP-A-54-155038 and JP-A-52-88025 and U.K. Patent No. 1,213,808. Furthermore the granular treating agent can be manufactured by a general method described in, for example, JP-A-2-109042, JP-A-2-109043, JP-A-3-39735 and JP-A-3-39739. Also, the powdered treating agent can be manufactured by a general method described in, for example, JP-A-54-133332, U.K. Patents Nos. 725,892 and 729,862, and German Patent No. 3,733,861.

A bulk density of the foregoing solid treating agent is preferably 0.5˜6.0 g/cm³, and especially preferably 1.0˜5.0 g/cm³ from the viewpoint of its solubility.

In preparing the foregoing solid treating agent, a method in which at least two kinds of mutually reactive granular substances of substances configuring the treating agent are placed in a stratiform state such that they are separated by at least one mediating separation layer composed of an inert substance to the reactive substances, packaged by a vacuum packing bag and sealed by evacuating from the inside of the bag may be employed. The term “inert” as referred to herein means that when substances are brought into physical contact with each other, they do not react with each other in a usual state within a package or even when a reaction of some sort takes place, it is not remarkable. With respect to the inert substance, separately from the matter that it is inert to the two mutually reactive substances, the two reactive substances may be inactive in an intended use. Furthermore, the inert substance is a substance which is simultaneously used with the two reactive substances. For example, in a developing solution, when hydroquinone and sodium hydroxide come into direct contact with each other, they react with each other; and therefore, in vacuum packaging, by using sodium sulfite or the line as a differential layer between hydroquinone and sodium hydroxide, the both can be preserved in a package over a long period of time. Also, by briquetting hydroquinone or the like to reduce a contact area with sodium hydroxide, the preservability is enhanced, and the both can be mixed and used. As a packaging material to be used for such vacuum packaging, a bag made of an inert plastic film or a laminate of a plastic substance and a metal foil is useful.

A mass of metallic silver contained in an exposed area after the development treatment is preferably a content of 50% by mass or more, and more preferably 80% by mass or more based on the mass of silver contained in the exposed are before the exposure. What the mass of silver contained in the exposed area is 50% by mass or more based on the mass of silver contained in the exposed area before the exposure is preferable because high conductivity is obtainable.

Though a gradation of the photosensitive material of the invention is not particularly limited, it is preferable that the gradation of the photosensitive material is contrasty. When the gradation of the photosensitive material is contrasty, a boundary between a conductive metal part and a non-metal part made be distinct, and it is possible to enhance the conductivity of the conductive metal part.

In particular, in the case where the support of the photosensitive material of the invention is light transmitting, what the gradation of the photosensitive material is contrasty is preferable because it is possible to enhance the light transmittance of the non-conductive metal part.

In the case where the support of the photosensitive material of the invention is light transmitting, it is preferable that an optical density gradation as defined below is 4 or more.

Optical density gradation=1/(log ED(1.2)−log ED(0.2))

Here, ED(1.2) and ED(0.2) each represents an exposure amount required when the optical density of the exposed area of the photosensitive material after the development treatment becomes 1.2 and 0.2, respectively.

Also, in the case where the photosensitive material is not light transmitting, the gradation of the photosensitive material is preferably 2 or more, more preferably 3 or more, and further preferably 4 or more in terms of a silver amount gradation as defined by the following expression.

Silver amount gradation=1/(log ED(1.2)−log ED(0.2))

Here, ED(1.2) and ED(0.2) each represents an exposure amount required when the amount of developed silver of the exposed area of the photosensitive material after the development treatment becomes 1.2 g/m² and 0.2 g/m², respectively.

Examples of a measure for making the gradation of the photosensitive material contrasty include the foregoing doping with a rhodium ion or an iridium ion.

### [Physical Development and Plating Treatment]

In the invention, for the purpose of imparting conductivity to a metallic silver part formed by the foregoing exposure and development treatments, physical development and/or plating treatment for supporting a conductive metal particle on the foregoing metallic silver part is carried out. In the invention, though it is possible to support a conductive metal particle on the metallic silver part by only one of physical development or plating treatment, it is also possible to support a conductive metal particle on the metallic silver part by a combination of physical development and plating treatment. Incidentally, the metallic silver part having been subjected to physical development and/or plating treatment is called as “conductive metal part”.

The “physical development” as referred to in the invention means deposition of a metal particle on a nucleus of a metal or a metal compound upon reduction of a metal ion such as a silver ion with a reducing agent. This physical development is utilized in manufacture of instant black-and-white films, instant slide films, printing plates, and the like, and technologies used therein can be applied in the invention.

Also, the physical development may be carried out simultaneously with the development treatment after the exposure or may be separately carried out after the development treatment.

In the invention, the plating treatment can be achieved by electroless plating (for example, chemical reduction plating and displacement plating) or electroplating or both of electroless plating and electroplating. In the electroless plating in the invention, known electroless plating technologies can be employed. For example, an electroless plating technology which is employed in printed wiring boards or the like can be employed; and it is preferable that the electroless plating is electroless copper plating.

Examples of chemical species contained in an electroless copper plating liquid include copper sulfate and copper chloride; examples of a reducing agent include formalin and glyoxalic acid; examples of a ligand of copper include EDTA and triethanolamine; and besides, examples of additives for the purpose of stabilizing a bath or improving the smoothness of a plated film include polyethylene glycol, yellow prussiate of potash, and bipyridine.

Examples of a copper electroplating bath include of a copper sulfate bath and a copper pyrophosphate bath.

With respect to the plating rate at the plating treatment in the invention, the plating can be carried out under a mild condition; and furthermore, high-speed plating at 5 μm/hr or more is possible. In the plating treatment, from the viewpoint of enhancing the stability of the plating liquid, various additives such as ligands, for example, EDTA can be used.

### [Oxidation Treatment]

In the invention, it is preferable that an oxidation treatment is applied to the metallic silver part after the physical treatment and the conductive metal part formed by the physical development and/or plating treatment. By performing the oxidation treatment, for example, in the case where a metal is slightly deposited in a light transmitting part, it is possible to control the transmittance of the light transmitting part at substantially 100% upon removal of the subject metal.

Examples of the oxidation treatment include known methods using an oxidizing agent of every kind such as an Fe(III) ion treatment. As described previously, the oxidation treatment can be carried out after the exposure and development treatments of the emulsion layer or after the physical development or plating treatment; and furthermore, the oxidation treatment may be carried out after the development treatment and after the physical treatment or plating treatment, respectively.

In the invention, the developed silver part after the exposure and development treatments can be further treated with a solution containing Pd. Pd may be a divalent palladium ion or may be metallic palladium. According to this treatment, an electroless plating or physical development rate can be accelerated.

### [Conductive Metal Part]

Next, the conductive metal part in the invention is described.

In the invention, the conductive metal part is formed by applying physical development or plating treatment to a metallic silver part formed by the foregoing exposure and development treatments and supporting a conductive metal particle on the metallic silver part.

Examples of the conductive metal particle which is supported on the metal part include, in addition to the foregoing silver, metals such as copper, aluminum, nickel, iron, gold, cobalt, tin, stainless steel, tungsten, chromium, titanium, palladium, platinum, manganese, zinc, and rhodium and particles of an alloy made of a combination thereof. From the viewpoints of conductivity, costs, and the like, the conductive metal particle is preferably a particle of copper, aluminum or nickel. Also, in the case of imparting magnetic field shielding properties, it is preferred to use a paramagnetic metal particle as the conductive metal particle.

From the viewpoints that the foregoing conductive metal part has contrast and is prevented from fading upon being oxidized with time, it is preferable that the conductive metal particle contained in the conductive metal part is a copper particle; and it is more preferable that at least its surface is blackened. The blackening can be carried out by employing a method which is performed in the field of a printed wiring board. For example, the blackening can be carried out through a treatment in an aqueous solution of sodium chlorite (31 g/L), sodium hydroxide (15 g/L) and trisodium phosphate (12 g/L) at 95° C. for 2 minutes.

The foregoing conductive metal part preferably contains silver in an amount of 50% by mass or more, and more preferably 60% by mass or more based on the total mass of metals contained in the conductive metal part. When the conductive metal part contains 50% by mass or more of silver, the time required for the physical development and/or plating treatment can be shortened, and the productivity can be enhanced, thereby achieving low costs.

Furthermore, in the case where copper and palladium are used as the conductive metal particle capable of forming the conductive metal part, the mass of a total sum of silver, copper and palladium is preferably 80% by mass or more, and more preferably 90% by mass or more based on the total mass of metals contained in the conductive metal part.

Since the conductive metal part in the invention supports a conductive metal particle, good conductivity is obtained. For that reason, a surface resistivity value of the translucent electromagnetic wave shielding film (conductive metal part) of the invention is preferably not more than 10 Ω/sq, more preferably not more than 2.5 Ω/sq, further preferably not more than 1.5 Ω/sq, and most preferably not more than 0.1 Ω/sq.

In the case where the conductive metal part in the invention is applied as a light transmitting electromagnetic wave shielding material, it preferably has a geometrical figure made of a combination of a triangle, for example, an equilateral triangle, an isosceles triangle, and a right triangle, a quadrilateral, for example, a regular square, a rectangle, a rhomb, a parallelogram, and a trapezoid, a (regular) n-gon, for example, a (regular) hexagon and a (regular) octagon, an ellipse, a star shape, and the like; and is more preferably in a mesh-like form made of such a geometrical figure. From the viewpoint of EMI shielding properties, a triangular shape is the most preferable. But, from the viewpoint of visible light transmittance, so far as the line width is identical, when the n-number of the (regular) n-gon increases, an opening ratio increases, and the visible light transmittance becomes large, and therefore, such is advantageous.

Incidentally, in the case of utilization of a conductive wring material, the shape of the foregoing conductive metal part is not particularly limited, but arbitrary shape can be properly determined depending upon the purpose.

In the application of the light transmitting electromagnetic wave shielding material, a line width of the foregoing conductive metal part is preferably not more than 20 μm, and a line gap is preferably 50 μm or more. Also, for the purpose of grounding, the conductive metal part may have a portion having a line width wider than 20 μm. Also, from the viewpoint of making an image non-conspicuous, the line width of the conductive metal part is preferably less than 15 μm, more preferably less than 10 μm, and most preferably less than 7 μm.

In view of the visible light transmittance, the conductive metal part in the invention preferably has an opening ratio of 85% or more, more preferably 90% or more, and most preferably 95% or more. Also, the “opening ratio” as referred to herein is a ratio occupied by a portion where fine lines configuring a mesh do not exist; and for example, an opening ratio of a lattice-like mesh of a regular square having a line width of 10 μm and a pitch of 200 μm is 90%. Incidentally, with respect to the opening ratio of the metallic silver part in the invention, though there is no particular upper limit, in a relationship between the surface resistivity value and the line width value, the foregoing opening ratio is preferably 98% or more.

### [Light Transmitting Part]

The “light transmitting part” as referred to in the invention means a portion with transparency of the light transmitting electromagnetic wave shielding film exclusive of the conductive metal part.

Incidentally, the “transmittance of the light transmitting part” as referred to in the invention refers to a transmittance expressed by an average of the transmittance in a wavelength region of 380˜780 nm exclusive of the light absorption of the support and the contribution of reflection and is expressed by [(transmittance of transparent part of light transmitting electromagnetic wave shielding material)/(transmittance of support)×100(%)]. The foregoing transmittance of the light transmitting part is preferably 90% or more, more preferably 95% or more, further preferably 97% or more, and most preferably 99% or more.

From the viewpoint of enhancing the transmittance, it is preferable that the light transmitting part in the invention does not substantially have a physical development nucleus. Different from the conventional silver complex salt diffusion transfer method, in the invention, since it is not required to dissolve an unexposed silver halide to convert into a soluble silver complex compound and then diffuse it, the light transmitting part does not substantially have a physical development nucleus.

It is meant by the terms “does not substantially have a physical development nucleus” as referred to herein that an existence ratio of a physical development nucleus in the light transmitting part falls within the range of 0˜5%.

The light transmitting part in the invention is formed along with the metallic silver part by exposing and developing the foregoing emulsion layer. From the viewpoint of enhancing the transmittance, it is preferable that after the foregoing development treatment, the light transmitting part is further subjected to a physical treatment or plating treatment and then to the foregoing oxidation treatment.

### [Light Transmitting Electromagnetic Wave Shielding Film]

The support in the light transmitting electromagnetic wave shielding film of the invention preferably has a thickness of 5˜200 μm, and more preferably 30˜150 μm. When the thickness is in the range of 5˜200 μm, not only a desired visible light transmittance is obtained, but also handling is easy.

A thickness of the metallic silver part to be provided on the support prior to the physical development and/or plating treatment can be properly determined according to the coating thickness of a paint for silver salt-containing layer to be coated on the support. The thickness of the metallic silver part is preferably not more than 30 μm more preferably not more than 20 μm, further preferably 0.01˜9 μm, and most preferably 0.05˜5 μm. Also, it is preferable that the metallic silver part is in a pattern-like form. The metallic silver part may be configured of a single layer or multiple layers of two or more layers. In the case where the metallic silver part is in a pattern-like formed and configured of multiple layers of two or more layers, it is possible to impart different color sensitivity such that the metallic silver part is sensitive to different wavelengths. Thus, by performing the exposure while altering the exposure wavelength, patterns which are different in the respective layers can be formed. The thus formed light transmitting electromagnetic wave shielding film containing a pattern-like metallic silver part of a multilayered structure can be utilized as a printed wiring board with high density.

In the application as an electromagnetic wave shielding material of display, it is preferable that the thickness of the conductive metal part is thin as far as possible because a viewing angle is widened. Furthermore, in the application of a conductive wiring material, it is required to realize a thin film according to the requirement for high density. From such a viewpoint, a thickness of a layer composed of a conductive metal supported on the conductive metal part is preferably 0.1 μm or more and less than 5 μm, and further preferably 0.1 μm or more and less than 3 μm.

In the invention, since a metallic silver part having a desired thickness can be formed by controlling a coating thickness of the foregoing silver salt-containing layer, and a thickness of a layer composed of a conductive metal particle can be freely controlled by physical development and/or plating treatment, it is possible to form a light transmitting electromagnetic wave shielding film having a thickness of less than 5 μm, and preferably less than 3 μm with ease.

Incidentally, in a conventional method employing etching, it was necessary to remove and dispose of a major part of the metal thin film by etching. On the other hand, in the invention, since a pattern containing only a necessary amount of the conductive metal can be provided on the support, it is enough to use a minimum necessary amount of the metal, and there is brought an advantage from both reduction of manufacturing costs and reduction of the amount of metal wastes.

### <Adhesive Layer>

It is preferable that when incorporated into an optical filter, a liquid crystal display panel, a plasma display panel, other image display flat panel, or an imaging semiconductor integrated circuit represented by CCD, or the like, the electromagnetic wave shielding film according to the invention is joined via an adhesive layer.

It is preferred to use an adhesive having a refractive index of 1.40˜1.70 in the adhesive layer. This is made for the purpose of preventing a lowering of the visible light transmittance by minimizing a difference in the refractive index between the transparent substrate used in the invention, such as plastic films and the adhesive in a relationship therebetween, and when the refractive index is 1.40˜1.70, a lowering of the visible light transmittance is small, and therefore, such is satisfactory.

Also, the adhesive is preferably an adhesive capable of flowing upon heating or pressurization, and especially preferably an adhesive exhibiting fluidity upon heating at not higher than 200° C. or pressurization at 1 kgf/cm² (98 kPa) or more. By using such an adhesive, it is possible to make the electromagnetic wave shielding film in the invention in which a conductive layer is embedded in this adhesive layer adhere to a display or a plastic plate as an adherend while flowing the adhesive layer. Since the adhesive layer can be flown, it is possible to make the electromagnetic wave shielding film easily adhere to even an adherend having a curved surface or a complicated shape by lamination or pressure molding, especially pressure molding. In order to achieve this, it is preferable that the adhesive has a softening temperature of not higher than 200° C. From the standpoint of the application of the electromagnetic wave shielding film, since the environment to be used is usually lower than 80° C., the softening temperature of the adhesive layer is preferably 80° C. or higher, and most preferably from 80 to 120° C. in view of workability. The softening temperature refers to a temperature at which the viscosity becomes not higher than 10¹² poises (10¹³ Pa·s). In general, fluidization is admitted within a time of about 1˜10 seconds at that temperature.

As the adhesive capable of flowing upon heating or pressurization, the following thermoplastic resins are mainly enumerated as representative examples thereof. Examples of the adhesive which can be used include natural rubber (refractive index n=1.52), (di)enes such as polyisoprene (n=1.521), poly-1,2-butadiene (n=1.50), polyisobutene (n=1.505˜1.51), polybutene (n=1.513), poly-2-heptyl-1,3-butadiene (n=1.50), poly-2-t-butyl-1,3-butadiene (n=1.506), and poly-1,3-butadiene (n ˜1.515), polyoxyethylene (n=1.456), polyoxypropylene (n=1.450), polyethers such as polyvinyl ethyl ether (n=1.454), polyvinyl hexyl ether (n=1.459), and polyvinyl butyl ether (n=1.456), polyesters such as polyvinyl acetate (n=1.467) and polyvinyl propionate (n=1.467), polyurethane (n=1.5˜1.6), ethyl cellulose (n=1.479), polyvinyl chloride (n=1.54˜1.55), polyacrylonitrile (n=1.52), polymethacrylonitrile (n=1.52), polysulfone (n=1.633), polysulfide (n=1.6), phenoxy resins (n=1.5˜1.6), and poly(meth)acrylic esters such as polyethyl acrylate (n=1.469), polybutyl acrylate (n=1.466), poly-2-ethylhexyl acrylate (n=1.463), poly-t-butyl acrylate (n=1.464), poly-3-ethoxypropyl acrylate (n=1.465), poly-oxycarbonyl tetramethylene (n=1.465), polymethyl acrylate (n=1.472˜1.480), polyisopropyl methacrylate (n=1.473), polydodecyl methacrylate (n=1.474), polytetradecyl methacrylate (n=1.475), poly-n-propyl methacrylate (n=1.484), poly-3,3,5-trimethylcyclohexyl methacrylate (n=1.484), polyethyl methacrylate (n=1.485), poly-2-nitro-2-methylpropyl methacrylate (n=1.487), poly-1,1-diethylpropyl methacrylate (n=1.489), and polymethyl methacrylate (n=1.489). Such an acrylic polymer may be used as a copolymer of two or more kinds thereof or a blend of two or more kinds thereof as the need arises.

Furthermore, examples of the copolymer resin of an acrylic resin and a substance other than the acrylic resin which can be used include epoxy acrylates (n=1.48˜1.60), urethane acrylates (n=1.5˜1.6), polyether acrylates (n=1.48˜1.49), and polyester acrylates (n=1.48˜1.54). In view of adhesive properties, urethane acrylates, epoxy acrylates and polyether acrylates are excellent; and examples of the epoxy acrylate include (meth)acrylic acid adducts such as 1,6-hexanediol diglycidyl ether, neopentyl glycol diglycidyl ether, allyl alcohol diglycidyl ether, resorcinol diglycidyl ether, diglycidyl adipate, diglycidyl phthalate, polyethylene glycol diglycidyl ether, trimethylolpropane triglycidyl ether, glycerin triglycidyl ether, pentaerythritol tetraglycidyl ether, and sorbitol tetraglycidyl ether. A polymer containing a hydroxyl group in a molecule thereof such as epoxy acrylates is effective for enhancing the adhesive properties. Such a copolymer resin can be used in combination of two or more kinds thereof as the need arises. In view of handling properties, a softening temperature of the polymer which becomes such an adhesive is suitably not higher than 200° C., and more preferably not higher than 150° C. From the standpoint of the application of the electromagnetic wave shielding film, since the environment to be used is usually lower than 80° C., the softening temperature of the adhesive layer is most preferably 80˜120° C. in view of workability. On the other hand, one having a weight average molecular weight (measured by using a calibration curve of standard polystyrene by gel permeation chromatography; hereinafter the same) of 500 or more is preferably used. When the molecular weight is less than 500, since a cohesive power of the adhesive composition is too low, the adhesion to an adherend is possibly lowered. The adhesive which is used in the invention may be blended with additives such as a diluent, a plasticizer, an antioxidant, a filler, a colorant, an ultraviolet ray absorber, and a tackifier as the need arises. A thickness of the adhesive layer is preferably 10˜80 μm, and especially preferably the thickness of the conductive layer or more and 20˜50 μm.

Also, an adhesive for covering the geometrical figure is regulated so as to have a difference in refractive index from the transparent plastic substrate of not more than 0.14. Also, in the case where the transparent plastic substrate and the conductive material are stuck via the adhesive layer, a difference in refractive index between the adhesive layer and the adhesive for covering the geometric figure is regulated at not more than 0.14. This is because when the refractive index is different between the transparent plastic substrate and the adhesive, or the refractive index is different between the adhesive and the adhesive layer, the visible light transmittance is lowered; and when the difference in the refractive index is not more than 0.14, a lowering of the visible light transmittance is small, and therefore, such is satisfactory. In the case where the transparent plastic substrate is polyethylene terephthalate (refractive index n=1.575), as a material of the adhesive which meets such requirements, bisphenol A type epoxy resins, bisphenol F type epoxy resins, tetrahydroxyphenylmethane type epoxy resins, novolak type epoxy resins, resorcin type epoxy resins, polyalcohol/polyglycol type epoxy resins, polyolefin type epoxy resins, and alicyclic or halogenated bisphenol epoxy resins (all of which have a refractive index of 1.55˜1.60) can be used. Besides the epoxy resins, examples include natural rubber (n=˜1.52), (di)enes such as polyisoprene (n=1.521), poly-1,2-butadiene (n=1.50), polyisobutene (n=1.505˜1.51), polybutene (n=1.5125), poly-2-heptyl-1,3-butadiene (n=1.50), poly-2-t-butyl-1,3-butadiene (n=1.506), and poly-1,3-butadiene (n=1.515), polyoxyethylene (n=1.4563), polyoxypropylene (n=1.4495), polyethers such as polyvinyl ethyl ether (n=1.454), polyvinyl hexyl ether (n=1.459), and polyvinyl butyl ether (n=1.4563), polyesters such as polyvinyl acetate (n=1.4665) and polyvinyl propionate (n=1.4665), polyurethane (n=1.5˜1.6), ethyl cellulose (n=1.479), polyvinyl chloride (n=1.54˜1.55), polyacrylonitrile (n=1.52), polymethacrylonitrile (n=1.52), polysulfone (n=1.633), polysulfide (n=1.6), and phenoxy resins (n=1.5˜1.6). These reveal a suitable visible light transmittance.

On the other hand, in the case where the transparent plastic substrate is an acrylic resin, besides the foregoing resins, examples include poly(meth)acrylic esters such as polyethyl acrylate (n=1.4685), polybutyl acrylate (n=1.466), poly-2-ethylhexyl acrylate (n=1.463), poly-t-butyl acrylate (n=1.4638), poly-3-ethoxypropyl acrylate (n=1.465), poly-oxycarbonyl tetramethylene (n=1.465), polymethyl acrylate (n=1.472˜1.480), polyisopropyl methacrylate (n=1.4728), polydodecyl methacrylate (n=1.474), polytetradecyl methacrylate (n=1.4746), poly-n-propyl methacrylate (n=1.484), poly-3,3,5-trimethylcyclohexyl methacrylate (n=1.484), polyethyl methacrylate (n=1.485), poly-2-nitro-2-methylpropyl methacrylate (n=1.4868), polytetracarbanyl methacrylate (n=1.4889), poly-1,1-diethylpropyl methacrylate (n=1.4889), and polymethyl methacrylate (n=1.4893). Such an acrylic polymer may be used as a copolymer of two or more kinds thereof or a blend of two or more kinds thereof as the need arises.

Furthermore, examples of the copolymer resin of an acrylic resin and a substance other than the acrylic resin which can be used include epoxy acrylates, urethane acrylates, polyether acrylates, and polyester acrylates. In view of adhesiveness, epoxy acrylates and polyether acrylates are excellent; and examples of the epoxy acrylate include (meth)acrylic acid adducts such as 1,6-hexanediol diglycidyl ether, neopentyl glycol diglycidyl ether, allyl alcohol diglycidyl ether, resorcinol diglycidyl ether, diglycidyl adipate, diglycidyl phthalate, polyethylene glycol diglycidyl ether, trimethylolpropane triglycidyl ether, glycerin triglycidyl ether, pentaerythritol tetraglycidyl ether, and sorbitol tetraglycidyl ether. A polymer containing a hydroxyl group in a molecule thereof such as epoxy acrylates is effective for enhancing the adhesiveness. Such a copolymer resin can be used in combination of two or more kinds thereof as the need arises. As the polymer which is a major component of the adhesive, one having a weight average molecular weight of 1,000 or more is used. When the molecular weight is not more than 1,000, since a cohesive power of the composition is too low, the adhesion to an adherend is lowered.

As a hardening agent of the adhesive, amines such as triethylenetetramine, xylenediamine, and diaminodiphenylmethane, acid anhydrides such as phthalic anhydride, maleic anhydride, dodecylsuccinic anhydride, pyromellitic anhydride, benzophenonetetracarboxylic anhydride, diaminodiphenylsulfone, tris(dimethylaminomethyl)phenol, polyamide resins, dicyanediamide, ethylmethylimidazole, and the like can be used. Such a compound may be used singly or in admixture of two or more kinds thereof. The addition amount of such a crosslinking agent may be chosen within the range of 0.1˜50 parts by weight, and preferably 1˜30 parts by weight based on 100 parts by weight of the foregoing polymer. When this addition amount is less than 0.1 parts by weight, the hardening becomes insufficient, whereas when it exceeds 50 parts by weight, excessive crosslinking occurs, and the adhesiveness may possibly be adversely affected. The resin composition of the adhesive which is used in the invention may be blended with additives such as a diluent, a plasticizer, an antioxidant, a filler, and a tackifier as the need arises. Then, in order to cover partially or entirely the substrate of the configuration material provided with a geometrical figure which is drawn with a conductive material on the surface of the transparent plastic substrate, this resin composition of the adhesive is formed into an adhesive film according to the invention through coating, solvent drying and heat hardening steps. The above-obtained adhesive film having electromagnetic shielding properties and transparency is directly stuck to a display such as CRT, PDP, liquid crystal, and EL due to the adhesive of the adhesive film and used, or is stuck to a plate or sheet of an acrylic plate, a glass plate, etc. and used for a display. Also, this adhesive film is similarly used in a window or casing for looking in a measurement apparatus emitting electromagnetic waves, a measurement appliance, or a manufacturing apparatus. Furthermore, the adhesive film is provided in a window of a building which is possibly affected by electromagnetic interference due to a radio tower, a high-voltage cable, or the like, a car window, and the like. Moreover, it is preferred to provide a ground wire in the geometrical figure drawn with a conductive material.

In a portion on the transparent plastic substrate where the conductive material is removed, irregularities are intentionally provided for the purpose of enhancing the adhesiveness; or for the purpose of transferring a back surface shape of the conductive material, though light is scattered on the surface and transparency is impaired, by coating smoothly a resin having a refractive index close to the transparent plastic substrate on the irregular surface, diffused reflection is controlled to minimum, thereby revealing transparency. Furthermore, in the geometrical figure drawn with a conductive material on the transparent plastic substrate, a line width thereof is very small so that it cannot be visually confirmed. Also, since its pitch is thoroughly large, it is thought that apparent transparency is revealed. On the other hand, since the pitch of the geometrical figure is thoroughly small as compared with a wavelength of electromagnetic waves to be shielded, it is thought that excellent shielding properties are revealed.

As described in JP-A-2003-188576, when an ethylene-vinyl acetate copolymer resin with high heat fusibility or a film of a heat fusible resin such as ionomer resins is used singly or stacked with other resin film and used as the transparent substrate film, it is possible to achieve stacking of the transparent substrate film and the metal foil without providing an adhesive layer. But, stacking is in general carried out by a dry lamination method using an adhesive layer or the like. Examples of the adhesive which configures the adhesive layer include adhesives such as acrylic resins, polyester resins, polyurethane resins, polyvinyl alcohol resins, vinyl chloride/vinyl acetate copolymer resins, and ethylene-vinyl acetate copolymer resins. Besides, thermosetting resins and ionizing radiation-curable resins (for example, ultraviolet ray curable resins and electron beam-curable resins) can also be used.

In general, since the surface of the display is made of a glass, the transparent plastic film and the glass plate are stuck by using the adhesive; and when an air bubble is generated on the adhesive surface or peeling occurs, an image is warped, thereby bringing a problem that the display color differs from an original color of the display or other problems. Also, in all of the cases, the air bubble and peeling problems are generated by the matter that the adhesive is peeled from the plastic film or glass plate. This phenomenon is possibly generated on both the plastic film side and the glass plate side, and the peeling occurs on a side with a weaker adhesive force. Accordingly, it is required that the adhesive force of the adhesive to the plastic film or glass plate at high temperatures is high. Concretely, an adhesive force of the adhesive layer to the transparent plastic film and glass plate is preferably 10 g/cm or more, and more preferably 30 g/cm at 80° C. However, an adhesive exceeding 2,000 g/cm is sometimes not preferable because sticking works become difficult. However, it can be used without problems in the case where such a problem does not occur. Furthermore, it is also possible to provide slip paper (separator) such that a portion of this adhesive not facing at the transparent plastic film does not come into contact with other unnecessary portions.

It is preferable that the adhesive is transparent. Concretely, its total light transmittance is preferably 70% or more, more preferably 80% or more, and most preferably 85˜92%. Furthermore, it is preferable that the adhesive has a low haze. Concretely, its haze is preferably 0˜3%, and more preferably 0˜1.5%. In order that the original display color of the display may not change, it is preferable that the adhesive used in the invention is colorless. However, even when a resin itself is colored, in the case where the thickness of the adhesive is thin, it is possible to consider that the adhesive is colorless. Also, as described later, the case where coloring is intentionally performed is not included in this range.

Examples of the adhesive having the foregoing characteristics include acrylic resins, α-olefin resins, vinyl acetate based resins, acrylic copolymer based resins, urethane based resins, epoxy based resins, vinylidene chloride based resins, vinyl chloride based resins, ethylene-vinyl acetate based resins, polyamide based resins, and polyester based resins. Of these, acrylic based resins are preferable. Even in the case of using the same resin, it is also possible to enhance the adhesiveness by a method such as reduction of the addition amount of a crosslinking agent during the synthesis of an adhesive by the polymerization method, addition of a tackifier, and alternation of a terminal group of the molecule. Also, even in the case of using the same adhesive, it is possible to enhance the adhesiveness by modifying the surface to which the adhesive is stuck, namely the surface of the transparent plastic film or glass plate. Examples of such a surface modification method include physical measures such as a corona discharge treatment and a plasma glow treatment; and the formation of a base layer for the purpose of enhancing the adhesion.

From the viewpoints of transparency, colorless properties and handling properties, it is preferable that a thickness of the adhesive layer is about 5˜50 μm. In the case where the adhesive layer is formed of an adhesive, it is preferable that its thickness is made thin within the foregoing range. Concretely, the thickness is about 1˜20 μm. However, as described previously, in the case where the display color of the display itself is not altered and the transparency falls within the foregoing range, the thickness may exceeds the foregoing range.

### <Peelable Protective Film>

A peelable protective film can be provided in the light transmitting electromagnetic wave shielding film according to the invention.

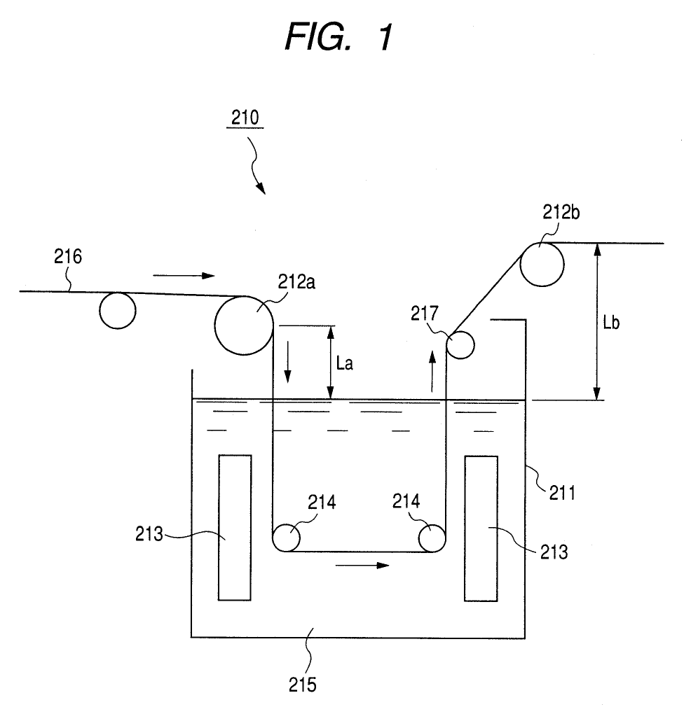

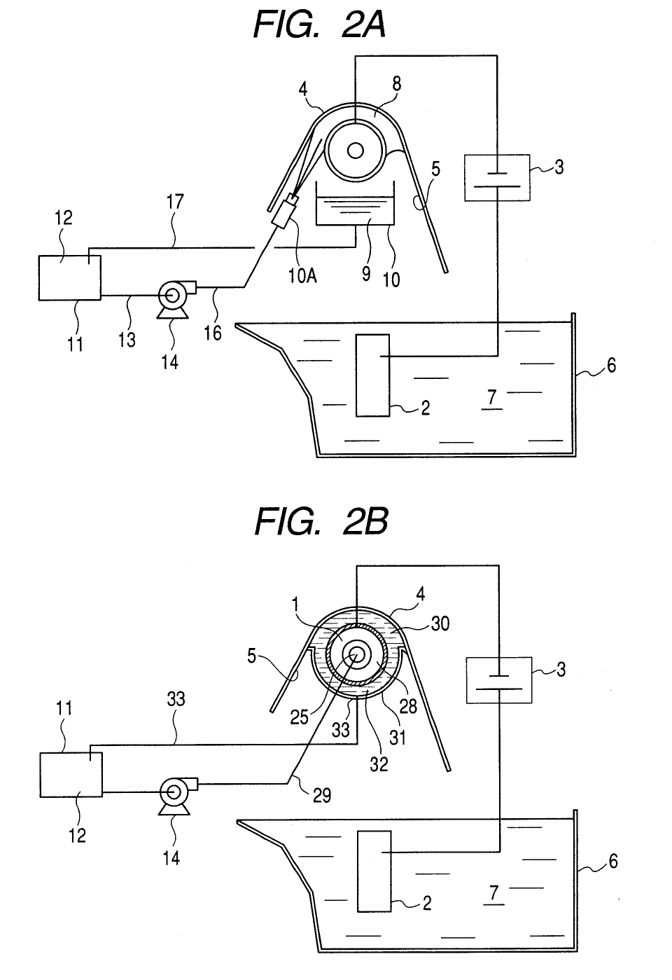

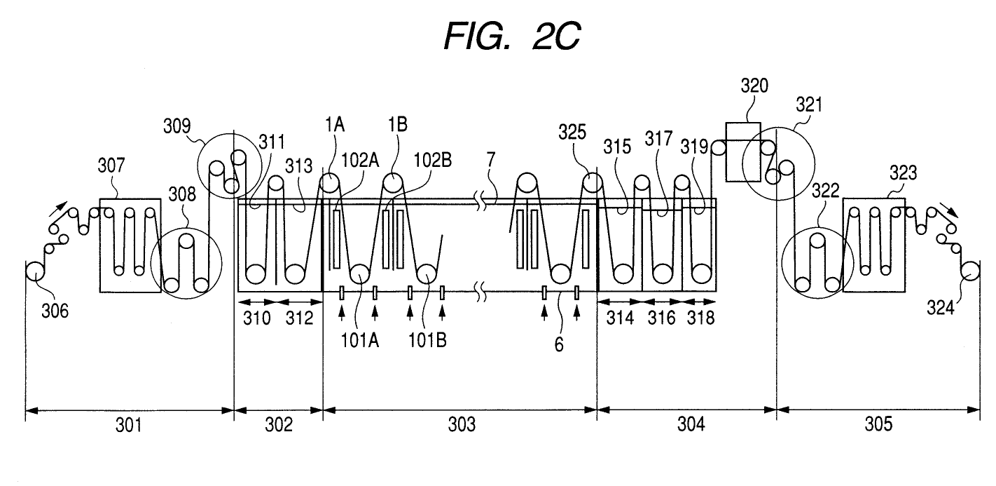

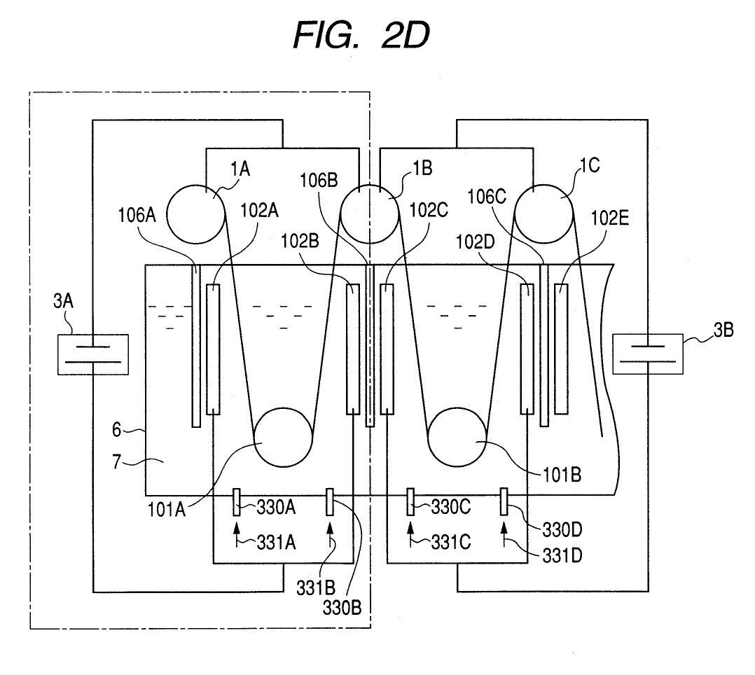

The protective film may be not always provided on both surfaces of an electromagnetic wave shielding sheet 1 (light transmitting electromagnetic wave shielding film); and, as illustrated in FIG. 2(a) of JP-A-2003-188576, a protective film 20 may be provided only on a mesh-like metal foil 11′ of a stack 10 but not on a side of a transparent substrate film 14. Also, as illustrated in FIG. 2(b) of the foregoing patent document, a protective film 30 may be provided only on a side of a transparent substrate film 14 of the stack 10 but not on the metal foil 11′. Incidentally, in FIG. 2 and FIG. 1 of the foregoing patent document, portions given common symbols show the same portions.

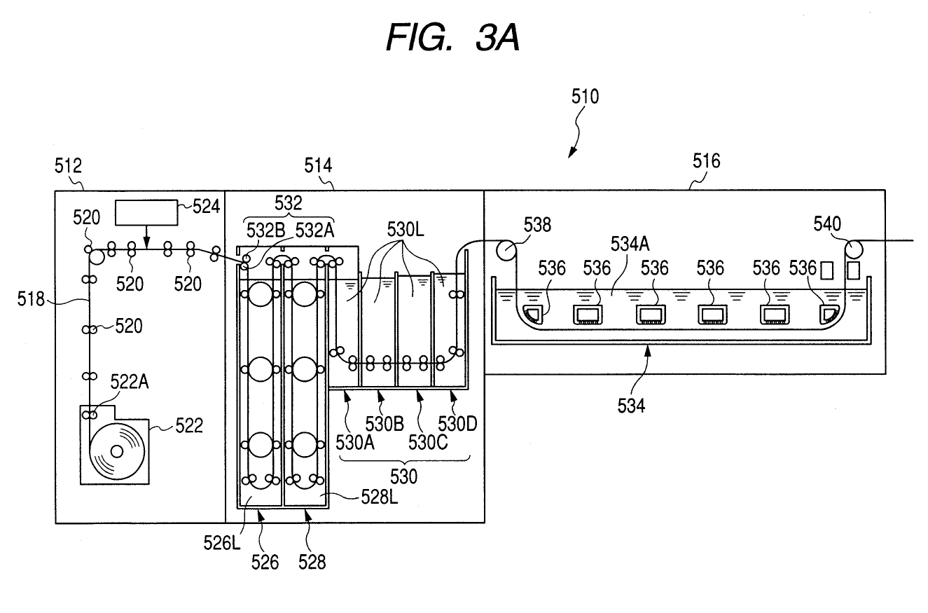

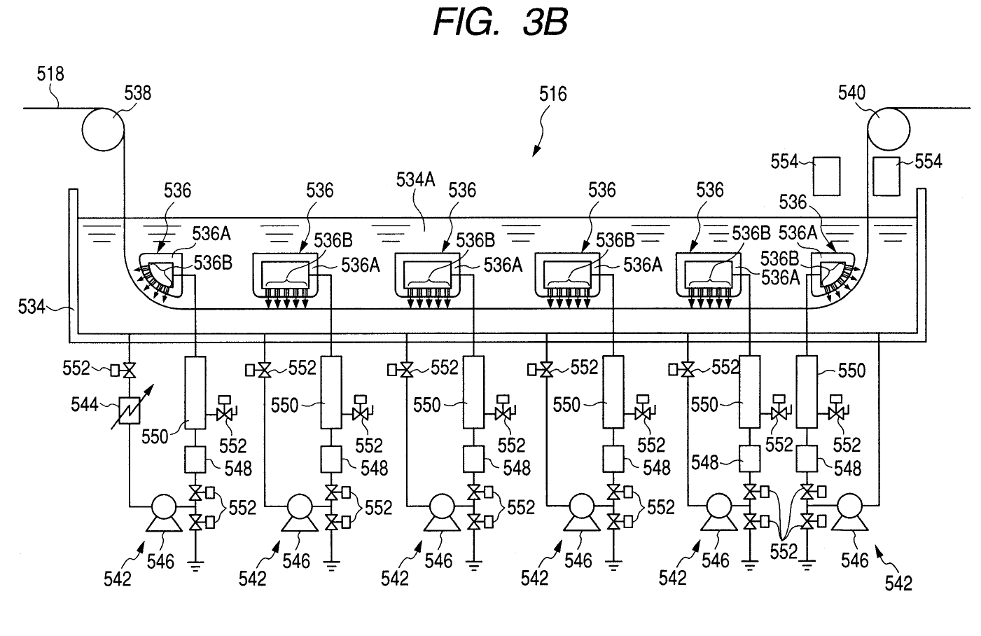

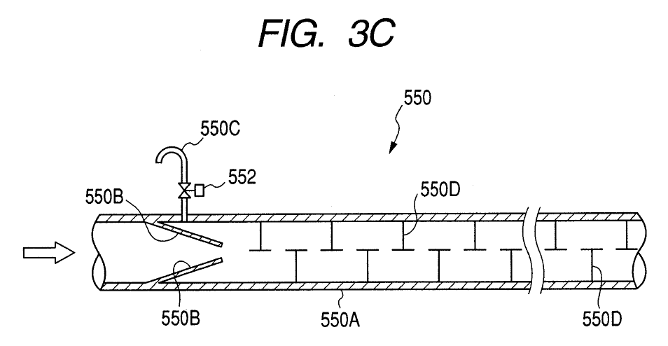

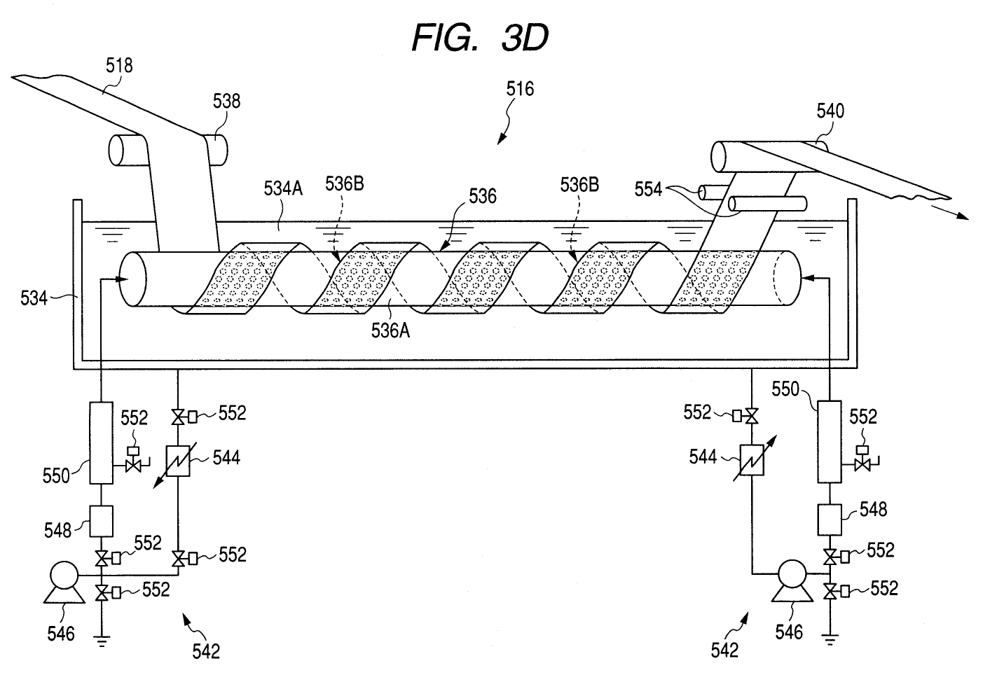

A layer configuration of a stack configured by at least stacking the transparent substrate film 14 in the electromagnetic wave shielding sheet 1 and a transparent electromagnetic wave shielding layer composed of the mesh-like metal foil 11′ in which openings are densely arranged and a manufacturing process of a stack are hereunder described while referring to FIGS. 3(a) to 3(f) of the foregoing patent document. Incidentally, stacking of the protective film 20 and/or the protective film 30 is again described after the explanation of the manufacturing process of a stack.

First of all, as illustrated in FIG. 3(a) of the foregoing patent document, a stack having a transparent substrate film 14 and a metal foil 11 stacked via an adhesive layer 13 is prepared. As the transparent substrate film 14, a film of an acrylic resin, a polycarbonate resin, a polypropylene resin, a polyethylene resin, a polystyrene resin, a polyester resin, a cellulose based resin, a polysulfone resin, a polyvinyl chloride resin, or the like can be used. In general, a film of a polyester resin having excellent mechanical strengths and high transparency, such as a polyethylene terephthalate resin, is preferably used. Though a thickness of the transparent substrate film 14 is not particularly limited, in view of bringing mechanical strengths and increasing resistance against bending, it is preferably about 50 μm 200 μm. Though the thickness may be further increased, in the case where an electromagnetic wave shielding sheet 1 is stacked on other transparent substrate and used, the thickness may not always exceed this range. If desired, one or both surfaces of the transparent substrate film 14 may be subjected to a corona discharge treatment or may be provided with an easily adhesive layer.

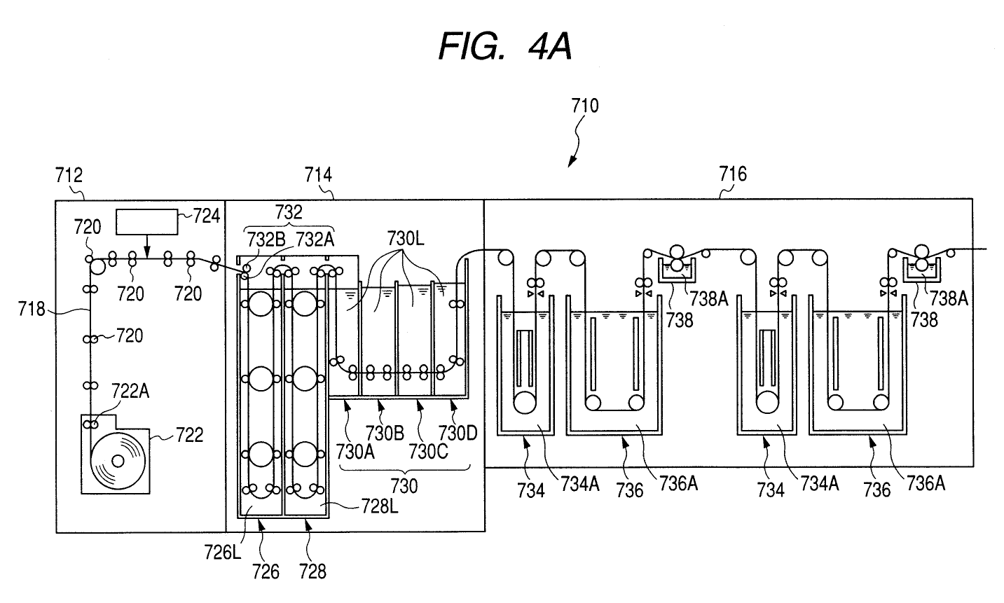

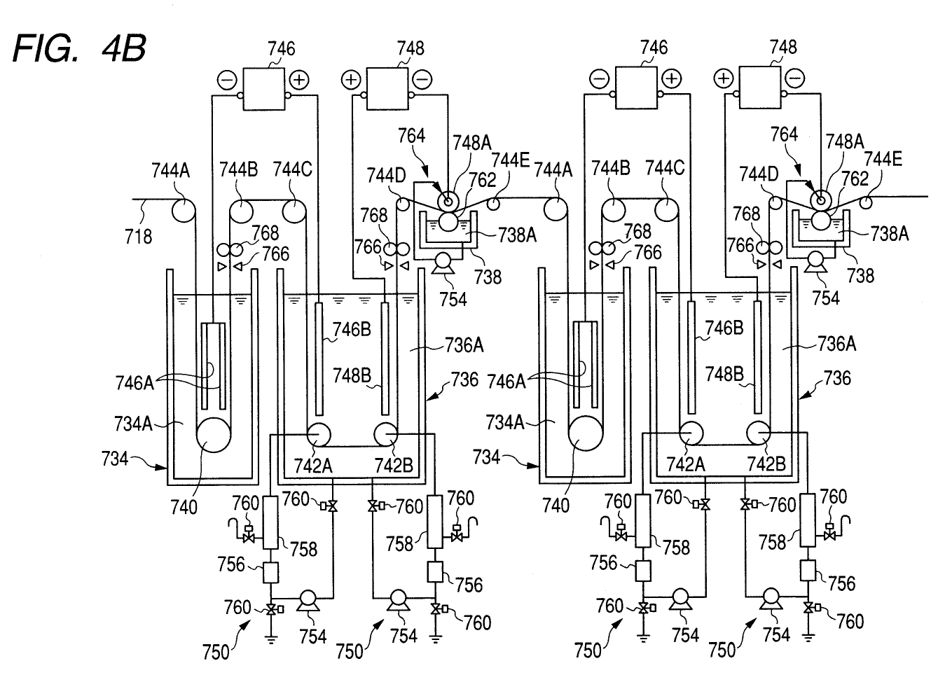

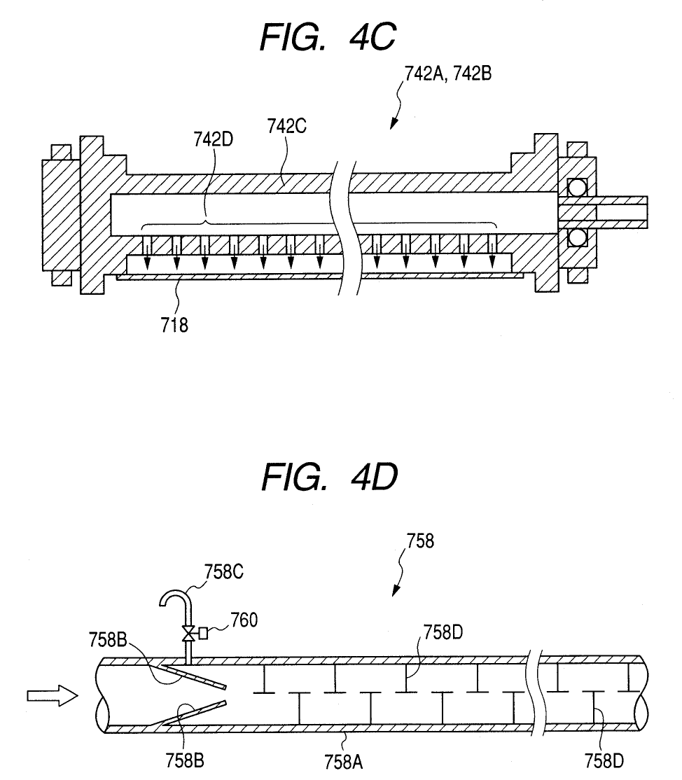

As described later while referring to FIG. 4 of the foregoing patent document, since the electromagnetic wave shielding sheet 1 is used by stacking the foregoing stack on a substrate via an infrared ray cut filter layer or the like and further stacking a sheet having an effect for strengthening an outermost surface, imparting antireflection properties or imparting antifouling properties or other effect on the front and back surfaces thereof, the foregoing protective film must be stripped during such stacking. For that reason, it is desirable that stacking to the metal foil side of the protective film is performed in a so-called strippable manner.

A stripping strength of the protective film during stacking on the metal foil is preferably 5 mN/25 mm-width˜5 N/25 m-width, and more preferably 10 mN/25 mm-width˜100 mN/25 mm-width. What the stripping strength is less than the lower limit is not preferable because stripping is too easy, and the protective film is possibly stripped during handling or due to careless contact. Also, what it exceeds the upper limit is not preferable, too because not only a large force is required for stripping, but also the mesh-like metal foil is possibly stripped from the transparent substrate film (or the adhesive layer) during stripping.

In the electromagnetic wave shielding sheet 1 of the invention, the protective film to be stacked on the side of the lower surface of the stack (which may be provided with a blackened layer) in which the mesh-like metal foil is stacked on the transparent substrate film 14 via the adhesive layer 13, namely on the transparent substrate film side is to achieve the protection such that the lower surface of the transparent substrate film is not damaged during handling or due to careless contact and that in respective steps of providing a resist layer on the metal foil and performing etching, especially during etching, the exposure surface of the transparent substrate film is not stained or corroded.

Likewise the foregoing case of the protective film, since this protective film must be stripped during further stacking of the stack, it is also desirable that stacking to the transparent substrate film side of the protective film is performed in a so-called strippable manner. Similar to the protective film, a stripping strength is preferably 5 mN/25 mm-width˜5 N/25 mm-width, and more preferably 10 mN/25 mm-width˜100 mN/25 mm-width. What the stripping strength is less than the lower limit is not preferable because stripping is too easy, and the protective film is possibly stripped during handling or due to careless contact; and what it exceeds the upper limit is not preferable because a large force is required for stripping.

It is preferable that the protective film to be stacked on the transparent substrate film side withstands an etching condition, for example, an etching solution at about 50° C., and in particular, is not corroded with alkali components thereof during dipping for several minutes, or in the case of dry etching, it is desirable that the protective film withstands a temperature condition at about 100° C. Also, in stacking a photosensitive resin layer, when the stack is subjected to dip coating (immersion coating), the coating solution is also deposited on the opposite surface of the stack. Accordingly, it is preferable that an adhesive force of the photosensitive resin is obtained such that the photosensitive resin does not strip and float in the etching solution in a step of etching or the like; and when the etching solution is used, it is preferable that the protective film has durability against staining due to the etching solution containing iron chloride, copper chloride, etc. or has durability against corrosion or staining or the like due to a resist removing solution such as an alkaline solution.

In order that the protective film may be satisfied with the foregoing respective requirements, it is preferred to use, as a film configuring the protective film, a film of a polyethylene resin or a polypropylene resin as a polyolefin based resin, a polyester resin such as polyethylene terephthalate resins, a polycarbonate resin, an acrylic resin, or the like. Also, from the foregoing viewpoints, it is preferable that the surface of the protective film on a side which when applied to the stack, becomes an uppermost surface is at least subjected to a corona discharge treatment or stacked with an easily adhesive layer.

Also, as an adhesive configuring the protective film, an acrylic ester based, rubber based or silicone based adhesive can be used.

Since with respect to the protective film to be applied on the metal foil side, the material of the film for the protective film and the material of the adhesive as described previously can be applied as they are, though a different material may be used for the both protective films, the same material can be used for the both protective films.

### <Blackening Treatment>

When the configuration drawings as illustrated in JP-A-2003-188576 are referred to as an example, the metal foil may have a blackened layer caused due to a blackening treatment on the transparent substrate film side or can be imparted antireflection properties in addition to a rustproof effect. The blackened layer can be formed by, for example, Co—Cu alloy plating and is able to prevent reflection on the surface of the metal foil 11. Furthermore, a chromate treatment may be further applied thereon as a rustproof treatment. Though the chromate treatment is to form a rustproof film by dipping in a solution containing a chromate or bichromate as a major component and drying and can be applied on one or both surfaces of the metal foil as the need arises, commercially available chromate treated copper foils and the like may be used. Incidentally, when a metal foil which has been subjected to a blackening treatment in advance is not used, the metal foil may be subjected to a blackening treatment in an appropriate later step. Incidentally, the blackened layer can be formed by forming a photosensitive resin layer which is able to become a resist layer by using a black colored composition as described later and after completion of etching, retaining the resist layer without being removed; and may be formed by a plating method for giving a black film.

Also, a configuration shown in JP-A-11-266095 may be employed as an example of the configuration containing a blackened layer. In the foregoing electromagnetic wave shielding plate, a blackened layer configuring a first blackened layer 3a, a second blackened layer 3b, and the like for forming a mesh-like conductive pattern P configured by intersection of a line x in a lateral direction and a line y in a longitudinal direction can be formed by properly selecting and utilizing it on a basis of the following thought. In the invention, the method of forming a mesh-like conductive pattern P as a principal object include two methods; and one of the methods is a metal plating method, with the other method being an etching method. In the invention, by employing any one of the foregoing methods, the formation method of the first blackened layer 3a, the second blackened layer 3b, and the like, the material to be used, and the like are different. That is, in the invention, in order to form the conductive pattern P on the first blackened layer 3a, the second blackened layer 3b, and the like by a metal plating method or the like, a conductive blackened layer capable of being applied to metal plating is necessary; and in the case where blackening is achieved in a final step by an etching method, an electrodeposition method or the like, a non-conductive blackened layer can be formed by using a non-conductive material or the like. In general, the foregoing conductive blackened layer can be formed by using a conductive metal compound, for example, compounds of nickel (Ni), zinc (Zn), and copper (Cu). Also, the non-conductive blackened layer can be formed by using a pasty black high molecular weight material, for example, a black ink, a blackening chemical conversion material, for example, a material in which a metal plated surface is subjected to a chemical conversion treatment to form a black compound, and an electrodeposting ionic high molecular weight material, for example, an electrodeposting coating material. In the invention, the blackened layer can be formed by utilizing the foregoing blackened layer formation method, choosing a proper method adaptive to a manufacturing step in the manufacturing method of an electromagnetic wave shielding plate or the like and employing it.

Next, as a method of providing a blackened layer in the invention, as illustrated in FIG. 5 of JP-A-11-266095, an electrodeposited substrate 14 having a mesh-like resist pattern 12 which is configured of an insulating film capable of hindering electrodeposition on a conductive substrate 11 of the above prepared metal plate or the like is first dipped in an electrolyte of blackened copper, blackened nickel, etc. and plated by a known electrochemical plating method, thereby forming a mesh-like second blackened layer 3b composed of a blackened copper layer, a blackened nickel layer, or the like. Incidentally, in the invention, as the foregoing black plating bath, a black plating bath containing nickel sulfate as a major component can be used; and commercially available black plating baths can be similarly used. Concretely, for example, a black plating bath manufactured by Shimizu Co., Ltd. (a trade name: NOBLOY SNC, Sn—Ni alloy base), a black plating bath manufactured by Nihon Kagaku Sangyo Co., Ltd. (a trade name: NIKKA BLACK, Sn—Ni alloy base), a black plating bath manufactured by Kinzoku Kagaku Kogyo Co., Ltd. (a trade name: EBONICHROM 85 Series, Cr base), and the like can be used. Also, in the invention, various black plating bats such as Zn bases, Cu bases, and others can be used as the foregoing black plating bath. Next, in the invention, as illustrated in FIG. 5 of the foregoing patent document, the electrodeposited substrate 14 having the second blackened layer 3b provided thereon as described previously is similarly dipped in an electrolyte of an electromagnetic wave shielding metal, thereby stacking and electrodepositing a mesh-like conductive pattern 4 in a desired thickness in a place corresponding to the blackened layer 3b of the electrodeposited substrate 14. In the foregoing, the foregoing metals as a good conductive substance can be used the most advantageous material as a material configuring the mesh-like conductive pattern 4. Then, in the case of forming the foregoing metal electrodeposited layer, since an electrolyte of a general-purpose metal can be used, there is brought an advantage that various kinds of cheap metal electrolytes exist and can be freely chosen adaptive with the purpose. In general, Cu is frequently used as the cheap good conductive metal, and in the invention, it is also effective to use Cu in conformity with the purpose. As a matter of course, other metals can be similarly used. Next, the mesh-like conductive pattern 4 is not always configured of only a single metal layer, and for example, though not illustrated, since the mesh-like conductive pattern P made of Cu in the foregoing example is relatively soft and easily scratched, it can be configured of a metal deposited layer composed of two layers using, as a protective layer thereof, a general-purpose rigid metal such as Ni and Cr. Next, in the invention, as illustrated in FIG. 5, after forming the mesh-like conductive pattern 4 as described previously, for example, the surface of the mesh-like conductive pattern 4 is similarly subjected to a chemical conversion treatment. Concretely, for example, when the conductive pattern P is made of copper (Cu), the surface of copper is treated with a hydrogen sulfide (H₂S) solution and blackened as copper sulfide (CuS); the surface of the metal deposited layer configuring the mesh-like conductive pattern 4 is subjected to a blackening treatment to form the first blackened layer 3a; and the mesh-like conductive pattern P configured by superimposing the foregoing second blackened layer 3b, conductive pattern layer 4 and first blackened layer 3a in this order is formed. Incidentally, in the invention, as the foregoing blackening treatment agent of the copper surface, sulfide based materials, materials which can be easily manufactured by using a sulfide based compound, and various commercially available products, for example, trade names: COPPER BLACK CuO, COPPER BLACK CuS, and selenium based COPPER BLACK No. 65 (all of which are manufactured by Isolate Chemical Laboratories Co., Ltd.) and a trade name: EBONOL C Special (manufactured by Meltex Inc.) can be used.

In the foregoing electromagnetic wave shielding plate, an etching resist pattern 35 may be removed or may be retained; and furthermore, in the case of removing the etching resist pattern 35, after removing the etching resist pattern 35, a surface of a remaining conductive metal layer 33 can be subjected to a blackening treatment. Then, the foregoing blackening treatment can be carried out by utilizing a known blackening treatment method such as a plating method of black copper (Cu), black nickel (Ni), or the like and a chemical blackening treatment method.

### [Optical Filter]

The optical filter according to the invention can have a functional film provided with a multifunctional layer in addition to the foregoing light transmitting electromagnetic wave shielding film.

### <Multifunctional Layer>

In a display, since a display screen is hardly viewed due to reflection by an illuminator or the like, a functional film (C) is required to have any one function of antireflection (AR) properties for suppressing external light reflection, antiglare (AR) properties for preventing reflection of a mirror image, or antireflection antiglare (ARAG) properties provided with the both properties. When a visible light reflectance of the surface of the optical filter is low, it is possible to enhance not only the antireflection but also the contrast and the like.

The functional film (C) having antireflection properties has an antireflection film; and specific examples thereof include films in which a thin film having a low refractive index as not more than 1.5, and preferably not more than 1.4 and made of a fluorocarbon based transparent high molecular weight resin, magnesium fluoride, a silicon based resin, or silicon oxide is formed into a single layer in an optical film thickness of for example, a ¼ wavelength; and multilayered stacks of two or more thin layers having a different refractive index and made of an inorganic compounds such as metal oxides, fluorides, silicides, nitrides, and sulfides or an organic compound such as silicon based resins, acrylic resins, and fluorocarbon based resins. But, it should not be construed that the invention is limited thereto. A visible light reflectance of the surface of the functional film (C) having antireflection properties is not more than 2%, preferably not more than 1.3%, and more preferably not more than 0.8%.

The functional film (C) having antiglare properties has an antiglare film which has a surface state of fine irregularities of about 0.1 μm˜10 μm and which is transparent to visible light. Concretely, this functional film (C) is one obtained by coating an ink prepared by dispersing an inorganic compound or organic compound such as silica, organosilicon compounds, melamine and acryl in a thermosetting or photocurable resin such as acrylic resins, silicon based resins, melamine based resins, urethane based resins, alkyd based resins, and fluorocarbon based resins and then hardening. An average particle size of the particle is 1˜40 μm. Alternatively, the antiglare properties can be obtained by coating the foregoing thermosetting or photocurable resin on a substrate and pressing a die having a desired gloss value or surface state, followed by hardening. However, it should be construed that the invention is not always limited to these methods. A haze of the functional film (C) having antiglare properties is 0.5% or more and not more than 20%, and preferably 1% or more and not more than 10%. When the haze is too small, the antiglare properties are insufficient, whereas when the haze is too large, the sharpness of the transmitted image tends to become low.

In order to add scratch resistance to the optical filter, it is suitable that the functional film (C) also has hard coat properties. Examples of a hard coat film include thermosetting or photocurable resins such as acrylic resins, silicon based resins, melamine based resins, urethane based resins, alkyd based resins, and fluorocarbon based resins, but its kind and formation method are not particularly limited. A thickness of such a film is about 1˜50 μm. A surface hardness of the functional film (C) having hard coat properties is at least H, preferably 2H or more, and more preferably 3H or more in terms of a pencil hardness according to JIS (K-5400). What an antireflection film and/or an antiglare film is formed on the hard coat film is suitable because the functional film (C) having scratch resistance and antireflection properties and/or antiglare properties is obtainable.

Since dusts are easy to deposit on the optical filter due to electrostatic charge and when a human body comes into contact therewith, charge occurs to give an electric shock thereto, there may be the case where an antistatic treatment is required. Accordingly, in order to impart an antistatic ability, the functional film (C) may have conductivity. In that case, the required conductivity may be not more than about 10¹¹Ω/□. Examples of a method of imparting conductivity include a method of containing an antistatic agent in the film and a method of forming a conductive layer. Specific examples of the antistatic agent include a trade name: PELESTAT (manufactured by Sanyo Chemical Industries, Ltd.) and a trade name: FLECTROSTRIPPER (manufactured by Kao Corporation). Examples of the conductive layer include known transparent conductive films including ITO; and conductive films having dispersed therein a conductive superfine particle including an ITO superfine particle and a tin oxide superfine particle. It is suitable that the hard coat film, the antireflection film or the antiglare film has a conductive film or contains a conductive fine particle.

What the surface of the functional film (C) has antifouling properties is suitable because staining with a fingerprint or the like can be prevented, and when a stain is deposited, it can be easily removed. Examples of a material having antifouling properties include those having non-wettability against water and/or fats and oils, for example, fluorocarbon compounds and silicon compounds. Concretely, examples of the fluorocarbon based antifouling agent include a trade name: OPTOOL (manufactured by Daikin Industries, Ltd.); and examples of the silicon compound include a trade name: TAKATA QUANTUM (manufactured by NOF Corporation). What such a layer having antifouling properties is used for the antireflection film is suitable because an antireflection film having antifouling properties is obtainable.

It is preferable that the functional film (C) has ultraviolet ray cut properties for the purpose of preventing deterioration of a coloring matter or a high molecular weight film as described later or the like. For the functional film (C) having ultraviolet ray cut properties, a method of containing an ultraviolet ray absorber in the foregoing high molecular weight film or imparting an ultraviolet ray absorbing film is applicable.

When the optical filter is used in a higher temperature and humidity circumstance than normal temperature and normal humidity, since there is the possibility that a coloring matter as described later is deteriorated due to moisture which has passed through the film, moisture is condensed in an adhesive material to be used for sticking or at a sticking interface to cause cloudiness, or a tackifier or the like in the adhesive material causes phase separation due to an influence by moisture to cause cloudiness, it is preferable that the functional film (C) has gas barrier properties. For the purpose of preventing such deterioration of the coloring matter or cloudiness, it is important to prevent invasion of the moisture into the layer containing a coloring matter or the adhesive material layer; and it is suitable that a water vapor permeability of the functional film (C) is not more than 10 g/m²·day, and preferably not more than 5 g/m²·day.

In the invention, the high molecular weight film (A), the conductive mesh layer (B) and the functional film (C) and optionally a transparent molded article (E) as described later are stuck to each other via an arbitrary adhesive material (D1) or adhesive (D2) which is transparent to visible light. Specific examples of the adhesive material (D1) or adhesive (D2) include acrylic adhesives, silicon based adhesives, urethane based adhesives, polyvinyl butyral (PVB) adhesives, ethylene-vinyl acetate (EVA) based adhesives, polyvinyl ethers, saturated amorphous polyesters, and melamine resins; and the adhesive material (D1) or adhesive (D2) may be in a sheet-like form or liquid so far as it has a practically useful adhesive strength. As the adhesive material, a pressure-sensitive adhesive in a sheet-like form can be suitably used. Sticking is carried out by sticking a sheet-like adhesive material or coating an adhesive and then laminating the respective members. A liquid material is an adhesive which is cured upon being allowed to stand at room temperature or heating after coating and sticking. Examples of the coating method include a bar coating method, a reverse coating method, a gravure coating method, a die coating method, and a roll coating method; and the coating method is considered and chosen depending upon the kind, viscosity and coating amount of the adhesive, and the like. Though a thickness of the layer is not particularly limited, it is 0.5 μm˜50 μm and preferably 1 μm˜30 μm. It is suitable that the surface on which the adhesive material layer is formed or stuck is subjected to an easily adhesive treatment such as an easily adhesive coating or corona discharge treatment in advance, thereby enhancing wettability. In the invention, the adhesive material or adhesive which is transparent to the foregoing visible light is called as “light transmitting adhesive material”.

In the invention, in sticking the functional film (C) on the conductive mesh layer (B), in particular, the light transmitting adhesive material layer (D1) is used. Though specific examples of the light transmitting adhesive material which is used in the light transmitting adhesive material layer (D1) are the same as described previously, with respect to its thickness, it is important that a recess of the conductive mesh layer (B) can be sufficiently embedded. When the thickness is too tin as compared with that of the conductive mesh layer (B), embedding is insufficient, a gap is formed, and an air bubble is bitten into the recess, whereby a display filter which is cloudy and insufficient in light transmission properties is formed. Also, when it is too thick, there are brought problems that the costs for manufacturing the adhesive material increase and that handling of the member becomes worse. When the thickness of the conductive mesh layer (B) is defined as “d μm”, the thickness of the light transmitting adhesive material (D1) is preferably (d−2)˜(d+30) μm.

A visible light transmittance of the optical filter is preferably 30˜85%, and more preferably 35˜70%. When this visible light transmittance is less than 30%, luminance is excessively low so that the visibility becomes worse. Also, when the visible light transmittance of the display filter is too high, the contrast of the display cannot be improved. Incidentally, the visible light transmittance in the invention is one calculated from wavelength dependency of a transmittance in a visible light region according to JIS (K-3106).

Also, when the functional film (C) is stuck on the conductive mesh layer (B) via the light transmitting adhesive material layer (D1), there is a possibility that it bites an air bubble into a recess thereof and becomes cloudy, whereby the light transmission properties becomes insufficient. In that case, for example, by applying a pressurization treatment, it is possible to degas the gas which has been incorporated between the members at the sticking or dissolve it as a solid in the adhesive material, eliminate cloudiness and enhance light transmission properties. The pressurization treatment may be carried out in a state of the (C)/(D1)/(B)/(A) configuration or may be carried out in a state of the display filter of the invention.

Though the pressurization method is not particularly limited, examples thereof include a method of interposing the stack between flat plates and pressing it, a method of passing through nip rollers while pressurizing, and a method of charging in a pressure vessel and pressurizing. The method of pressurizing in a pressure vessel is suitable because the pressure is uniformly applied over the whole of the stack, it is free from unevenness in pressurization, and plural stacks can be treated at once. As the pressure vessel, an autoclave unit can be used.

With respect to the pressurization condition, when the pressure is high, not only an air bubble to be bitten can be eliminated, but also the treatment time can be shortened. However, in view of restrictions of pressure resistance of the stack and the unit regarding the pressurization method, a pressure is about 0.2 MPa˜2 MPa, and preferably 0.4˜1.3 MPa. Also, though the pressurization time varies with the pressurization condition and is not particularly limited, when it is too long, a long time is required for the treatment, and the costs increase. Therefore, it is preferable that a retention time is not more than 6 hours under an appropriate pressurization condition. In particular, in the case of a pressure vessel, it is suitable that after reaching a set pressure, it is held for about 10 minutes˜3 hours.

Also, there may be the case where it is preferable to raise the temperature simultaneously at the pressurization. By raising the temperature, the fluidity of the light transmitting adhesive material increases temporarily, whereby a bitten air bubble is easily degassed or is easily dissolved as a solid in the adhesive material. With respect to the condition for raising the temperature, though the temperature is not particularly limited, it is room temperature or higher and not higher than about 80° C. depending upon the heat resistance of each of the members configuring the optical filter.

Furthermore, the pressurization treatment or the pressurization and temperature-raising treatment is suitable because it is able to enhance an adhesive force after sticking between the respective members configuring the optical filter.

In the optical filter of the invention, a light transmitting adhesive material layer (D2) is provided on the other major surface of the high molecular weight film (A) on which the conductive mesh layer (B) is not formed. A light transmitting adhesive material which is used in the light transmitting adhesive material layer (D2) is not particularly limited, and specific examples thereof are the same as described previously. Though its thickness is not particularly limited, it is 0.5 μm˜50 μm, and preferably 1 μm˜30 μm. It is suitable that the surface on which the light transmitting adhesive material layer (D2) is formed or stuck is subjected to an easily adhesive treatment such as easily adhesive coating and corona discharge treatment in advance, thereby enhancing wettability.

A release film may be formed on the light transmitting adhesive material layer (D2). That is, the configuration is at least the functional film (C)/light transmitting adhesive material layer (D1)/conductive mesh layer (B)/high molecular weight film (A)/light transmitting adhesive material layer (D2)/release film. The release film is one obtained by coating a silicone or the like on the major surface of the high molecular weight film coming into contact with the adhesive material layer. In sticking the optical filter of the invention onto a major surface of a transparent molded article (E) as described later or in sticking it on a display surface or a front glass of a plasma display panel, the release film is striped off to expose the light transmitting adhesive material layer (D2), followed by sticking.

The optical filter of the invention is used mainly for the purpose of shielding electromagnetic waves emitted from a display of every kind. Preferred examples thereof include a plasma display filter.

As described previously, since a plasma display emits strong near infrared rays, the display filter of the invention is required to cut not only electromagnetic waves but also near infrared rays to a level where there is no problem in practical use. It is required that a transmittance in a wavelength region of 800˜1,000 nm is not more than 25%, preferably not more than 15%, and more preferably not more than 10%. Also, the optical filter to be used for a plasma display is required to have a neutral blue or blue gray transmitted color. This is because it is necessary to keep or enhance light emission characteristics and contrast of the plasma display or a white color of a color temperature slightly higher than a standard white color is sometimes desired. Moreover, it is said that a color plasma display is insufficient with respect to color reproducibility, and it is preferred to reduce selectively unnecessary light emission from a phosphor or a discharge gas as a cause thereof. In particular, an emission spectrum of red display exhibits several emission peaks over a wavelength of from about 580 nm to 700 nm and involves a problem that the red emission becomes not good in terms of a color purity close to orange due to emission peaks on a side of a relatively strong short wavelength. Such optical characteristics can be controlled by using a coloring matter. Namely, by using a near infrared ray absorber for near infrared ray cutting and by using a coloring matter capable of absorbing selectively unnecessary light emission for reducing the unnecessary light emission, desired optical characteristics can be obtained. Also, the color tone of the optical filter can be made suitable by using a coloring matter having appropriate absorption in a visible region.

For the method of containing a coloring matter at least one of (1) a high molecular weight film or a resin plate in which at least one coloring matter is kneaded in a transparent resin; (2) a high molecular weight film or a resin plate prepared by dispersing and dissolving at least one coloring matter in a resin or a resin concentrated solution of resin monomer/organic solvent and casting; (3) a material obtained by adding at least one coloring matter in a resin binder and an organic solvent to form a paint and coating it on a high molecular weight film or a resin plate, and (4) a transparent adhesive material containing at least coloring matter can be chosen, but it should not be construed that the invention is limited thereto. The term “containing” as referred to in the invention means not only a state that the coloring matter is contained in a substrate or a layer such as a coating or in the inside of an adhesive material, but also a state that the coloring matter is coated on a surface of a substrate or a layer.

The foregoing coloring matter is a general dye or pigment having a desired absorption wavelength in a visible region or a near infrared ray absorber and is not particularly limited with respect to a kind thereof. Examples thereof include generally commercially available organic coloring matters such as anthraquinone based, phthalocyanine based, methine based, azomethine based, oxazine based, immonium based, azo based, styryl based, coumarin based, porphyrin based, dibenzofuranone based, diketopyrrolopyrrole based, rhodamine based, xanthene based, pyrromethene based, dithiol based and diiminium based compounds. The kind and concentration thereof is determined by the absorption wavelength and absorption coefficient of the coloring matter, the transmission characteristic and transmittance required for an optical filter, and the kind and thickness of a dispersing medium or a coating and is not particularly limited.

In the plasma display panel, the temperature on the panel surface is high, and when the temperature of the circumstance is high, in particular, the temperature of the optical filter also increases. Accordingly, it is suitable that the coloring matter has heat resistance such that it is not remarkably deteriorated due to, for example, decomposition at 80° C. Also, in addition to the heat resistance, some coloring matters are poor in light fastness. In the case where the deterioration due to light emission of the plasma display or ultraviolet rays or visible light of the external light is of a problem, it is important to reduce the deterioration of the coloring matter due to ultraviolet rays and to use a coloring matter which does not cause remarkable deterioration due to ultraviolet rays or visible light by using a member containing an ultraviolet ray absorber or a member which does not transmit ultraviolet rays therethrough. The same is applicable with respect to humidity or a composite circumstance thereof in addition to heat and light. When deterioration occurs, the transmission characteristics of the display filter change, the color tone changes, and a near infrared ray cutting ability is lowered. Furthermore, in order to disperse the coloring matter in a medium or a coating, the solubility or dispersibility in an appropriate solvent is important, too. Also, in the invention, two or more kinds of coloring matters having a different absorption wavelength may be contained in a single medium or coating, or two or more coloring matter-containing media or coatings may be included.

The foregoing methods (1) to (4) for containing a coloring matter can be employed for the optical filter of the invention in a form of at least one of the coloring matter-containing high molecular weight film (A), the coloring matter-containing functional film (C), the coloring matter-containing light transmitting adhesive material (D1) or (D2), and besides, other coloring matter-containing light transmitting adhesive material or adhesive to be used for sticking.

In general, a coloring matter is easily deteriorated by ultraviolet rays. Ultraviolet rays which an optical filter receives under a usual use condition are contained in external light such as sunlight. Accordingly, in order to prevent deterioration of a coloring matter by ultraviolet rays, it is suitable that a layer having an ultraviolet ray cutting ability is included in at least one layer selected among a coloring matter-containing layer per se and a layer on a side of a human being who receives external light from the subject layer. For example, in the case where the high molecular weight film (A) contains a coloring matter, when the light transmitting adhesive material layer (D1) and/or the functional film (C) contains an ultraviolet ray absorber or has a functional film having an ultraviolet ray cutting ability, the coloring matter can be protected from ultraviolet rays contained in the external light. With respect to the ultraviolet ray cutting ability necessary for protecting the coloring matter, a transmittance in an ultraviolet ray region shorter than a wavelength of 380 nm is not more than 20%, preferably not more than 10%, and more preferably not more than 5%. The functional film having an ultraviolet ray cutting ability may be a coating containing an ultraviolet ray absorber or may be an inorganic film capable of reflecting or absorbing ultraviolet rays. As the ultraviolet ray absorber, compounds which have hitherto been known, for example, benzotriazole based compounds and benzophenone based compounds can be used. The kind and concentration thereof are determined by dispersibility or solubility in a medium for dispersing or dissolving it, absorption wavelength or absorption coefficient, thickness of a medium, and the like and are not particularly limited. Incidentally, it is preferable that the layer or film having an ultraviolet ray cutting ability is low in absorption of a visible light region, is free from a remarkable lowering of the visible light transmittance and is not colored yellow or the like. In the coloring matter-containing functional film (C), in the case where a coloring matter-containing layer is formed, it is better that the film or functional film on a side of a human being than that layer has an ultraviolet ray cutting ability; and in the case where the high molecular weight film contains a coloring matter, it is better that the functional film or functional layer having an ultraviolet ray cutting ability is present on a side of a human being than the subject film.

The coloring matter may possibly be deteriorated due to the contact with a metal, too. In the case of using such a coloring matter, it is more preferable that the coloring matter is disposed in such a manner that it does not come into contact with the conductive mesh layer (B) as far as possible. Concretely, the coloring matter-containing layer is preferably the functional film (C), the high molecular film (A) or the light transmitting adhesive material layer (D2), and especially preferably the light transmitting adhesive material layer (D2).

In the optical filter of the invention, the high molecular weight film (A), the conductive mesh layer (B), the functional film (C), the light transmitting adhesive material layer (D1) and the light transmitting adhesive material layer (D2) are configured in the order of (C)/(D1)/(B)/(A)/(D2); and preferably, the conductive mesh film composed of the conductive mesh layer (B) and the high molecular weight film (A) and the functional film are stuck by the light transmitting adhesive layer (D1), and the light transmitting adhesive layer (D2) is applied to the major surface of the high molecular weight film (A) opposite to the conductive mesh layer (B).

The optical filter of the invention is installed in a display in a manner such that the functional film (C) is disposed on a side of a human being, whereas the light transmitting adhesive layer (D2) is disposed on a side of the display.

Examples of a method in which the optical filter of the invention is provided in front of the display and used include a method in which it is used a frontal filter plate containing as a support a transparent molded article (E) as described layer; and a method in which it is stuck on a surface of the display via the light transmitting adhesive material layer (D2) and used. In the case of the former, setting of the optical filter is relatively easy, mechanical strengths are enhanced by the support, and this is suitable for protecting the display. In the case of the latter, because of the matter that no support is provided, it is possible to realize light weight and thinning, reflection on the surface of the display can be prevented, and this is suitable.

Examples of the transparent molded article (E) include glass plates and light transmitting plastic plates. In view of mechanical strengths, light weight and hard breakage, plastic plates are preferable, but glass plates can also be suitably used from the standpoint of thermal stability such that they are less in deformation by heat or the like. Specific examples of the plastic plate which can be used include acrylic resins including polymethyl methacrylate (PMMA), polycarbonate resins, and transparent ABS resins, but it should not be construed that the invention is limited to these resins. In particular, PMMA can be suitably used because it is high in transparency and mechanical strengths over a wide wavelength region. A thickness of the plastic plate is not particularly limited so far as sufficient mechanical strengths and stiffness for keeping flatness without causing a warp are obtained, but it is usually about 1 mm˜10 mm. As the glass, semi-tempered glasses or tempered glasses produced by chemical strengthening working or forced air cooling strengthening working for the purpose of imparting mechanical strengths are preferable. Though its thickness is not particularly limited, taking into consideration its weight, it is preferably about 1˜4 mm. The transparent molded article (E) can be subjected to various known necessary pre-treatments prior to sticking to the film, and colored picture frame printing with a black color or the like may be applied in a portion which becomes the surroundings of the optical filter.

In the case of using the transparent molded article (E), the optical filter is configured of at least the functional film (C)/light transmitting adhesive material layer (D1)/conductive mesh layer (B)/high molecular weight film (A)/light transmitting adhesive material layer (D2)/transparent molded article (E). Also, the functional film (C) may be provided on the major surface of the transparent molded article (E) opposite to the surface on which the transparent adhesive material layer (D2) is stuck via the light transmitting adhesive material layer. In that case, it is not necessary that this functional film (C) has the same function and configuration as in the functional film (C) provided on the side of the human being; and for example, in the case where it has an antireflection ability, it is able to reduce the reflection on a back surface of the optical filter having a support. Similarly, a functional film (C2) such as an antireflection film may be formed on the major surface of the transparent molded article (E) opposite to the surface on which the light transmitting adhesive material layer (D2) is stuck. In that case, though a display can be placed in such a manner that the functional film (C2) is located on the side of the human being, as described previously, it is preferable that a layer having an ultraviolet ray cutting ability is provided in the coloring matter-containing layer and a layer on the side of the human being than the coloring matter-containing layer.

In an appliance requiring electromagnetic wave shielding, it is necessary to shield electromagnetic waves by providing a metal layer in the inside of a case of the appliance or using a conductive material for the case. In the case where transparency is required in a display part as in displays, a window-like electromagnetic wave shielding filter having a light transmitting conductive layer as in the optical filter of the invention is set up. Here, since the electromagnetic waves are absorbed in the conductive layer and then induce a charge, unless the charge is released by grounding, the optical filter becomes again an antenna to oscillate the electromagnetic waves, whereby the electromagnetic wave shielding ability is lowered. Accordingly, it is required that the optical filter and the ground part of the display main body are electrically connected to each other. For that reason, it is necessary that the foregoing light transmitting adhesive material layer (D1) and the functional film (C) are formed on the conductive mesh layer (B) while remaining a continuity part capable of taking continuity from the outside. Though the shape of the continuity part is not particularly limited, it is important that a space from which electromagnetic waves leak is not present between the optical filter and the display main body. Accordingly, it is suitable that the continuity part is continuously provided in the surroundings of the conductive mesh layer (B). That is, it is preferable that the continuity part is provided in a frame work-like form exclusive of a central portion which is the display part of the display.

Though the continuity part may be a mesh pattern layer or may be a non-patterned layer, for example, a solid metal foil layer, in order to make the electrical contact with a ground part of the display main body good, it is preferable that the continuity part is a non-patterned layer such as a solid metal foil layer.

In the case where the continuity part is not patterned as in, for example, a solid metal foil layer and/or mechanical strengths of the continuity part are sufficiently strong, the continuity part can be used as an electrode as it is, and therefore, such is suitable.

In order that the continuity part may be protected and/or when the continuity part is a mesh pattern layer, the electrical contact with a ground part may be made good, there may be the case where an electrode is formed in the continuity part. Though the shape of the electrode is not particularly limited, it is suitable that the electrode is formed so as cover entirely the continuity part.

From the standpoints of conductivity, corrosion resistance, adhesion to the transparent conductive film and the like, as a material which is used for the electrode, pastes composed of a single substance such as silver, copper, nickel, aluminum, chromium, iron, zinc, and carbon or an alloy of two or more kinds thereof, a mixture of a synthetic resin and such a single substance or alloy, or a mixture of a borosilicate glass and such a single substance or alloy can be used. For printing and coating of the paste, conventionally known methods can be employed. Commercially available conductive tapes can also be used suitably. The conductive tape has conductivity on both the surfaces thereof, and a pressure sensitive adhesive single coated type and a pressure sensitive adhesive double coated type can be suitably used. Though a thickness of the electrode is not particularly limited, it is about several μm˜several mm.

According to the invention, it is possible to obtain an optical filter having excellent optical characteristics and capable of keeping or enhancing the image quality without remarkably impairing the luminance of a plasma display. Also, it is possible to obtain an optical filter which has an excellent electromagnetic wave shielding ability for shielding electromagnetic waves emitted from a plasma display and pointed out to have a possibility of injuring the health and which does not adversely affect wavelengths used by a remote controller of a peripheral electronic appliance, a transmission optical communication, and the like but is able to prevent a malfunction thereof because it is able to cut efficiently near infrared rays in the vicinity of 800˜1,000 nm emitted from a plasma display. Furthermore, it is possible to provide an optical filter with excellent weather resistance at low costs.

### EXAMPLES

The invention is hereunder specifically described with reference with the Examples, but it should not be construed that the invention is limited thereto.

### Example 1

### Preparation of Emulsion A

Liquid 1:

| | | |
|---|---|---|
| Water | 750 | mL |
| Gelatin | 20 | g |
| Sodium chloride | 3 | g |
| 1,3-Dimethylimidazolidin-2-thione | 20 | mg |
| Sodium benzenethiosulfonate | 10 | mg |
| Citric acid | 0.7 | g |

Liquid 2:

| | | |
|---|---|---|
| Water | 300 | mL |
| Silver nitrate | 150 | g |

Liquid 3:

| | | |
|---|---|---|
| Water | 300 | mL |
| Sodium chloride | 38 | g |
| Potassium bromide | 32 | g |
| Potassium hexachloroiridate(III) (0.005% KCl 20% aqueous | 5 | mL |
| solution) | | |
| Ammonium hexachlororhodinate (0.001% NaCl 20% aqueous | 7 | mL |
| solution) | | |

Potassium hexachloroiridate(III) (0.005% KCl 20% aqueous solution) and ammonium hexachlororhodinate (0.001% NaCl 20% aqueous solution) used in the liquid 3 were prepared by dissolving a powder in a KCl 20% aqueous solution and an NaCl 20% aqueous solution, respectively and heating at 40° C. for 120 minutes.

To the liquid 1 kept at 38° C. and a pH of 4.5, the liquid 2 and the liquid 3 were simultaneously added in an amount corresponding to 90%, respectively while stirring over 20 minutes, thereby forming a nucleus particle of 0.16 μm. Subsequently, the following liquid 4 and liquid 5 were added over 8 minutes, and the remaining liquid 2 and liquid 3 in an amount of 10% were added over 2 minutes, thereby growing the particle to 0.21 μm. Furthermore, 0.15 g of potassium iodide was added, the mixture was ripened for 5 minutes, and then the particle formation was accomplished.

Liquid 4:

| | | |
|---|---|---|
| Water | 100 | mL |
| Silver nitrate | 50 | g |

Liquid 5:

| | | |
|---|---|---|
| Water | 100 | mL |
| Sodium chloride | 13 | g |
| Potassium bromide | 11 | g |
| Yellow prussiate of potash | 5 | mg |

Thereafter, the resultant was washed with water by a flocculation method according to a usual way. Concretely, the temperature was dropped to 35° C.; 3 g of the following anionic sedimenting agent agent-1 was added; and the pH was lowered by using sulfuric acid until the silver halide was sedimented (in a pH range of 3.2±0.2). Next, about 3 liters of a supernatant was removed (first water washing). 3 liters of pure water was added, and sulfuric acid was then added until a silver halide was sedimented. 3 liters of the supernatant was again removed (second water washing). The same operation as the second water washing was repeated once more (third water washing), thereby accomplishing a water washing and desalting step. 30 g of gelatin was added to the emulsion after the water washing and desalting, thereby adjusting at a pH of 5.6 and a pAg of 7.5; 10 mg of sodium benzenethiosulfonate, 3 mg of sodium benzenethiosulfinate, 15 mg of sodium thiosulfate and 10 mg of chloroauric acid were added; chemical sensitization was applied at 55° C. so as to have optimum sensitivity; and 100 mg of 1,3,3a,7-tetraazaindene as a stabilizer and 100 mg of PROXEL (a trade name, manufactured by ICI Co., Ltd.) as an antiseptic were added. There was finally obtained a silver iodochlorobromide cubic grain emulsion containing 70% by mole of silver chloride and 0.08% by mole of silver iodide and having an average grain size of 0.22 μm and a fluctuation coefficient of 9% (the emulsion had finally a pH of 5.7, a pAg of 7.5, an electric conductivity of 40 μS/m, a density of 1.2×10³ kg/m³, and a viscosity of 60 mPa·s).

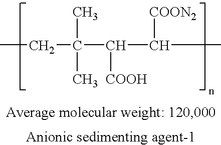

### Preparation of Coated Sample 1-1

A polyethylene terephthalate film support having a vinylidene chloride-containing moistureproof undercoat layer provided on both surfaces thereof as described blow was coated so as to have a UL layer/emulsion layer/protective layer lower layer/protective layer upper layer protective layer configuration, thereby preparing a sample 1-1. The preparation method, coating amount and coating method of each of the layers are shown below,

### <Emulsion Layer>

The emulsion A was subjected to spectral sensitization upon addition of 5.7×10⁻⁴ moles/mole-Ag of a sensitizing coloring matter (sd-1). Furthermore, 3.4×10⁻⁴ moles/mole-Ag of KBr and 8.0×10⁻⁴ moles/mole-Ag of a compound (Cpd-8) were added and well mixed.

Next, 1.2×10⁻⁴ moles/mole-Ag of 1,3,3a,7-tetraazaindene, 1.2×10⁻² moles/mole-Ag of hydroquinone, 3.0×10⁻⁴ moles/mole-Ag of citric acid, 90 mg/m² of 2,4-di-chloro-6-hydroxy-1,3,5-triazine sodium salt, 15% by weight, based on gelatin, of colloidal silica having a particle size of 10 μm, 100 mg/m² of an aqueous latex (aqL-6), 150 mg/m² of polyethyl acrylate latex, 150 mg/m² of a latex copolymer of methyl acrylate, sodium 2-acrylamido-2-methylpropanesulfonate and 2-acetoxyethyl methacrylate (weight ratio: 88/5/7), 150 mg/m² of a core-shell type latex (core: styrene/butadiene copolymer (weight ratio: 37/63), shell: styrene/2-acetoxyethyl acrylate (weight ratio: 84/16), core/shell ratio: 50/50), and 4% by weight, based on gelatin, of a compound (Cpd-7) were added, and the resulting coating solution was adjusted at a pH of 5.6 by using citric acid. The thus prepared coating solution for emulsion layer was coated on the following support so as to have 3.4 g/m² of Ag and 1.1 g/m² of gelatin.

<Protective layer upper layer>

| | | |
|---|---|---|
| Gelatin | 0.3 | g/m² |
| Amorphous silica matting agent of 3.5 μm in average | 25 | mg/m² |
| Compound (Cpd-8) (gelatin dispersion) | 20 | mg/m² |
| Colloidal silica having a particle size of 10~20 μm | 30 | mg/m² |
| (SNOWTEX C, manufactured by Nissan | | |
| Chemical Industries, Ltd.) | | |
| Compound (Cpd-9) | 50 | mg/m² |
| Sodium dodecylbenzenesulfonate | 20 | mg/m² |
| Compound (Cpd-10) | 20 | mg/m² |
| Compound (Cpd-11) | 20 | mg/m² |
| Antiseptic (PROXEL (a trade name, | 1 | mg/m² |
| manufactured by ICI Co., Ltd.)) | | |

<Protective layer lower layer>

| | | |
|---|---|---|
| Gelatin | 0.5 | g/m² |
| 1,5-Dihydroxy-2-benzaldoxime | 10 | mg/m² |
| Polyethyl acrylate latex | 150 | mg/m² |
| Compound (Cpd-13) | 3 | mg/m² |
| Antiseptic (PROXEL) | 1.5 | mg/m² |

<UL layer>

| | | |
|---|---|---|
| Gelatin | 0.5 | g/m² |
| Polyethyl acrylate latex | 150 | mg/m² |
| Compound (Cpd-7) | 40 | mg/m² |
| Compound (Cpd-14) | 10 | mg/m² |
| Antiseptic (PROXEL) | 1.5 | mg/m² |

Incidentally, in the coating solution of each of the layers, a thickener represented by the following structure (Z) was added, thereby adjusting the viscosity.

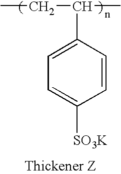

Incidentally, the sample used in the invention has a back layer and a conductive layer each having the following composition.

<Back layer>

| | | |
|---|---|---|
| Gelatin | 3.3 | g/m² |
| Compound (Cpd-15) | 40 | mg/m² |
| Compound (Cpd-16) | 20 | mg/m² |
| Compound (Cpd-17) | 90 | mg/m² |
| Compound (Cpd-18) | 40 | mg/m² |
| Compound (Cpd-19) | 26 | mg/m² |
| 1,3-Divinylsulfonyl-2-propanol | 60 | mg/m² |
| Polymethyl methacrylate fine particle | 30 | mg/m² |
| (average particle size: 6.5 μm) | | |
| Liquid paraffin | 78 | mg/m² |
| Compound (Cpd-7) | 120 | mg/m² |
| Calcium nitrate | 20 | mg/m² |
| Antiseptic (PROXEL) | 12 | mg/m² |

<Conductive layer>

| | | |
|---|---|---|
| Gelatin | 0.1 | g/m² |
| Sodium dodecylbenzenesulfonate | 20 | mg/m² |
| SnO₂/Sb (weight ratio: 9/1, average particle size: 0.25μ) | 200 | mg/m² |
| Antiseptic (PROXEL) | 0.3 | mg/m² |

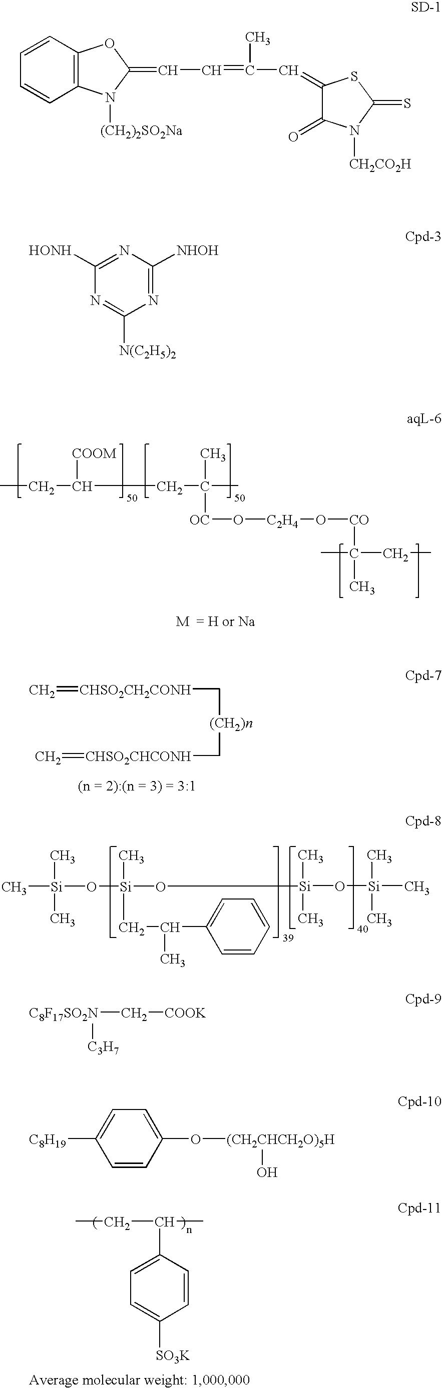

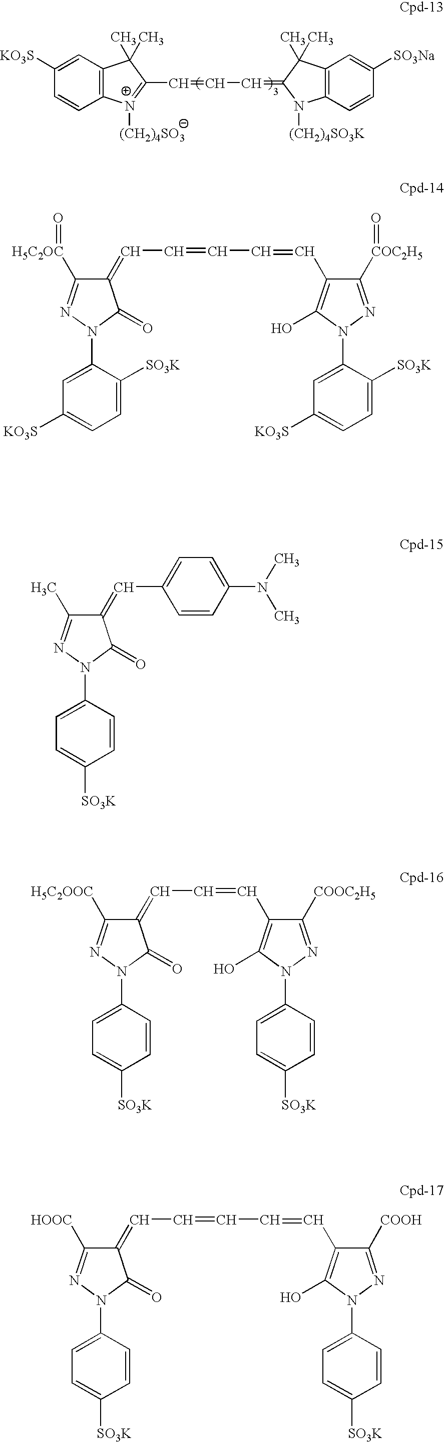

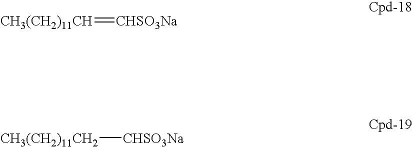

### <Support>

Undercoat layer first layer and second layer each having the following composition were coated on the both surfaces of a biaxially stretched polyethylene terephthalate support (thickness: 100 μm).

<Undercoat layer first layer>

| | |
|---|---|
| Core-shell type vinylidene chloride copolymer (1) | 15 g |
| 2,4-Dichloro-6-hydroxy-s-triazine | 0.25 g |
| Polystyrene fine particle (average particle size: 3 μ) | 0.05 g |
| Compound (Cpd-20) | 0.20 g |
| Colloidal silica (SNOWTEX ZL, particle size: 70~100μm, | 0.12 g |
| manufactured by Nissan Chemical Industries, Ltd.) | |
| Water to make | 100 g |

Furthermore, 10% by weight of KOH was added to adjust at a pH of 6, and the resulting coating solution was coated at a drying temperature of 180° C. for 2 minutes in a dry thickness of 09 μm.

<Undercoat layer second layer>

| | | |
|---|---|---|
| Gelatin | 1 | g |
| Methyl cellulose | 0.05 | g |
| Compound (Cpd-21) | 0.02 | g |
| C₁₂H₂₅O(CH₂CH₂O)₁₀H | 0.03 | g |
| PROXEL | 3.5 × 10⁻³ | g |
| Acetic acid | 0.2 | g |
| Water to make | 100 | g |

This coating solution was coated at a drying temperature of 170° C. for 2 minutes in a dry thickness of 0.1 μm.

### <Coating Method>

On the foregoing undercoat layer-applied support, four layers of the UL layer, the emulsion layer, the protective layer lower layer and the protective layer upper layer were first subjected to simultaneous double jet coating in this order from a side near the support as an emulsion surface side while adding a hardener solution by a slide bead coater system and keeping at 35° C.; and the conductive layer and the back layer were then subjected to simultaneous double jet coating in this order from a side near the support as an opposite side to the emulsion surface while adding a hardener solution by a curtain coater system, followed by passing through a cool air setting zone (5° C.). At a point of time of passing through each setting zone, the coating solution exhibited sufficient setting properties. Subsequently, the both surfaces were simultaneously dried in a drying zone.

Core-shell type vinylidene chloride copolymer (1)

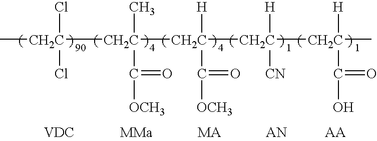

Core: VDC/MMA/Ma (80% by weight)

Shell: VDC/AN/AA (20% by weight)

Average particle size: 70 nm

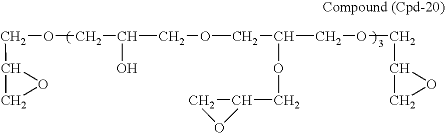

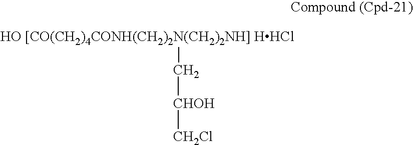

The resulting coated sample 1-1 contains a silver halide emulsion having a content of silver iodide of not more than 1.5% as the silver salt which is preferably used for the conductive film forming photosensitive material of the invention in the emulsion layer. Also, the coating amount of the silver salt is 3.4 g/m² as converted to silver and is a coating amount of the silver salt which is preferably used in the conductive film forming photosensitive material of the invention. Also, the Ag/binder weight ratio of the emulsion is 1.8 and is corresponding to “not more than 1.5” of the Ag/binder ratio which is preferably used in the conductive film forming photosensitive material of the invention. Also, the emulsion layer of the coated sample 1-1 contains sodium benzenethiosulfonate as an oxidizing agent which is preferably used in the emulsion layer of the conductive film forming photosensitive material of the invention, hydroquinone as an antioxidant which is preferably used in the emulsion layer of the conductive film forming photosensitive material of the invention and colloidal silica which is preferably used in the emulsion layer of the conductive film forming photosensitive material of the invention. However, since the coated sample 1-1 has two layers of the protective layers in an upper layer than the emulsion layer, it is not corresponding to the conductive film forming photosensitive material of the invention.

### Preparation of Coated Sample 1-2

A sample was prepared in the same manner as in the coated sample 1-1, except for removing the sodium benzenethiosulfonate as an oxidizing agent which is preferably used in the emulsion layer of the conductive film forming photosensitive material of the invention, the hydroquinone as an antioxidant which is preferably used in the emulsion layer of the conductive film forming photosensitive material of the invention and the colloidal silica which is preferably used in the emulsion layer of the conductive film forming photosensitive material of the invention; not providing the protective upper layer and the protective lower layer; and adding Cpd-9 and Cpd-10 as a surfactant which is used in the protective upper layer in the same coating amount as in the coated sample 1-1 in the emulsion layer and designated as a coated sample 1-2.

### Preparation of Coated Samples 1-3 to 1-5

A sample was prepared in the same manner as in the coated sample 1-2, except for adding hydroquinone as an antioxidant which is preferably used in the emulsion layer of the conductive film forming photosensitive material of the invention in the same amount as in the coated sample 1-1 in the emulsion layer, and a coated sample 1-3 was thus obtained. Coated samples were prepared in the same manner as in the coated sample 1-3, except for changing the antioxidant to a compound along with its coating amount as shown in the following Table 1, and coated samples 1-4 to 1-5 were thus obtained.

### Preparation of Coated Sample 1-6

A sample was prepared in the same manner as in the coated sample 1-2, except for changing the emulsion to a chemically unsensitized emulsion by not adding the sodium thiosulfate and the chloroauric acid at the preparation of an emulsion, and a coated sample 1-6 was thus obtained.

### Preparation of Coated Samples 1-7 to 1-9

A sample was prepared in the same manner as in the coated sample 1-2, except for adding sodium benzenethiosulfonate as an oxidizing agent which is preferably used in the emulsion layer of the conductive film forming photosensitive material of the invention in the same amount as in the coated sample 1-1 at the same addition time, and a coated sample 1-7 was thus obtained. Also, coated samples were prepared in the same manner as in coated sample 1-7, except for changing the oxidizing agent to a compound along with its coating amount as shown in Table 1, and coated samples 1-8 to 1-9 were thus obtained.

### Preparation of Coated Sample 1-10

A sample was prepared in the same manner as in the coated sample 1-2, except for adding the colloidal silica used in the coated sample 1-1 in the same amount as in the coated sample 1-1, and a coated sample 1-10 was this obtained.

### Preparation of Coated Samples 1-11 to 1-13

A sample was prepared in the same manner as in the coated sample 1-2, except for adding the same amorphous silica matting agent (3.5 μm in average) as used in the protective layer upper layer of the coated sample 1-1 as a matting agent which is preferably used in the emulsion layer of the conductive film forming photosensitive material of the invention in an amount as shown in Table 1 in the emulsion layer, and a coated sample 1-11 was thus obtained. Samples were prepared in the same manner as in the coated sample 1-11, except for changing the matting agent to a compound along with its coating amount as shown in Table 1, and coated samples 1-12 and 1-13 were thus obtained.

### Preparation of Coated Samples 1-14 to 1-15

A sample was prepared in the same manner as in the coated sample 1-2, except for adding the compound (Cpd-9) as a slipping agent which is preferably used in the emulsion layer of the conductive film forming photosensitive material of the invention in an amount as shown in Table 1 in the emulsion layer, and a coated sample 1-14 was thus obtained. Also, a sample was prepared in the same manner as in the coated sample 1-14, except for changing the slipping agent along with its coating amount as shown in Table 1, and a coated sample 1-15 was thus obtained.

### Preparation of Coated Sample 1-16

A sample was prepared in the same manner as in the coated sample 1-1, except for not providing the protective layer upper layer and the protective layer lower layer; adding an amorphous silica matting agent which is preferably used in the conductive film forming photosensitive material of the invention and a slipping agent which is preferably in the conductive film forming photosensitive material of the invention in amounts as shown in Table 1 in the emulsion layer; and adding Cpd-9 and Cpd-10 in the same amounts as in the coated sample 1-1 in the emulsion layer and designated as a coated sample 1-16. Here, as the amorphous silica matting agent, the same material of 3.5 μm in average as used in the protective layer upper layer of the coated sample 1-1 was used.

### Preparation of Coated Sample 1-17

A sample was prepared in the same manner as in the coated sample 1-16, except for changing the addition amount of potassium iodide at the preparation of an emulsion to 9.4 g, and a coated sample 1-17 was thus obtained.

### Preparation of Coated Sample 1-18

A sample was prepared in the same manner as in the coated sample 1-16, except for changing the emulsion to a chemically unsensitized emulsion by not adding the sodium thiosulfate and the chloroauric acid at the preparation of an emulsion, and a coated sample 1-18 was thus obtained.

### Preparation of Coated Samples 1-19 to 1-20

Samples were prepared in the same manner as in the coated sample 1-16, except for changing the silver coating amount of the emulsion layer, and samples 1-19 and 1-20 were thus obtained. The obtained samples each had a silver coating amount as shown in Table 1.

Each of the thus obtained coated samples 1-1 to 1-20 was subjected to the following exposures development and plating treatment.

### (Exposure and Development Treatment)

A lattice-like pattern capable of giving a developed silver image of line/space of 15 μm/285 μm (pitch: 300 μm) was exposed on a dried coating by using an image setter FT-R5055, manufactured by Dainippon Screen Mfg. Co., Ltd. At that time, the exposure amount was adjusted such that it became optimum in conformity with each sample.

Each of the samples was treated with a developing solution (A) and a fixing solution (B) each having the following formulation under a development condition at 35° C. for 30 seconds by using an automatic processor FG-680AG (manufactured by Fuji Photo Film Co., Ltd.).
Formulation of developing solution (A) (composition per one liter of concentrated liquid):

| | | |
|---|---|---|
| Potassium hydroxide | 60.0 | g |
| Diethylenetriaminepentaacetic acid | 3.0 | g |
| Potassium carbonate | 90.0 | g |
| Sodium metabisulfite | 105.0 | g |
| Potassium bromide | 10.5 | g |
| Hydroquinone | 60.0 | g |
| 5-Methylbenzotrizole | 0.53 | g |
| 4-Hydroxymethyl-4-methyl-1-phenyl-3-pyrazolidone | 2.3 | g |
| Sodium 3-(5-mercaprotetrazol-1-yl)benzenesulfonate | 0.15 | g |
| Sodium 2-mercaptobenzimidazole-5-sulfonate | 0.45 | g |
| Sodium erythorbate | 9.0 | g |
| Diethylene glycol | 7.5 | g |

| | |
|---|---|
| pH | 10.79 |

In the use, a mother liquor was prepared by dilution in a proportion of one part of water to two parts of the foregoing concentrated liquid, and the mother liquor had a pH of 10.65; and a replenisher was prepared by dilution in a proportion of three parts of water to four parts of the foregoing concentrated liquid, and the replenisher had a pH of 10.62.
Formulation of fixing solution (B) (composition per one liter of concentrated liquid):

| Ammonium thiosulfate | 360 g |
|---|---|
| Disodium ethylenediaminetetraacetate dihyrate | 0.09 g |
| Sodium thiosulfate pentahydrate | 33.0 g |
| Sodium metasulfite | 57.0 g |
| Sodium hydroxide | 37.2 g |
| Acetic acid (100%) | 90.0 g |
| Tartaric acid | 8.7 g |
| Sodium gluconate | 5.1 g |
| Aluminum sulfate | 25.2 g |
| pH | 4.85 |

In the use, the foregoing concentrated liquid is diluted in a proportion of two parts of water to one part of the concentrated liquid. A used liquid has a pH of 4.8. As a replenisher, a diluted liquid the same as the foregoing used liquid was used in an amount 2.58 mL per m² of the photosensitive material.

### (Plating Treatment)

The film having a silver image for mesh pattern as obtained by the foregoing development treatment was subsequently dipped in an activating liquid and an electroless copper plating liquid each having the following composition, thereby applying electroless copper plating on the mesh pattern silver image. Here, the activation treatment was carried out at 35° C. for 5 minutes. Also, the electroless copper plating was carried out at 35° C. for a period of time until the surface resistivity became not more than 0.3 Ω/□.

### (Composition of Activating Liquid) (Per One Liter):

| | | |
|---|---|---|
| PdCl₂ | 0.2 | g |
| HCl (2N aqueous solution) | 25.6 | mL |

Water is added for dissolving the foregoing therein, thereby making it to one liter.

(Composition of electroless copper plating liquid):

| | | |
|---|---|---|
| Copper sulfate | 0.06 | moles/L |
| Formalin | 0.22 | moles/L |
| Triethanolamine | 0.12 | moles/L |
| Polyethylene glycol | 100 | ppm |
| Yellow prussiate of potash | 50 | ppm |
| Aqueous solution containing 20 ppm | | |
| of α,α′-bipyridine | | |
| pH | 12.5 | |

By applying the foregoing exposure, development and plating treatment to each of the samples, a light transmitting conductive film composed of a metal fine line part and a light transmitting part which is substantially free from a metal was formed. Here, the metal fine line part exhibited a mesh-like pattern corresponding to the exposure pattern; and the line/space width was 15 μm/285 μm in all of the samples. Also, an opening ratio of the light transmitting part was about 90% in all of the samples.

### (Evaluation)

With respect to the resulting conductive thin films plating progress and pressure resistance were evaluated by the following methods.

### (1) Plating Progress:

A surface resistivity after the plating was measured by using a low resistivity meter LORESTA GP/ASP PROBE, manufactured by Mitsubishi Chemical Corporation according to JIS 7194. With respect to each of the samples, a time required for plating until the surface resistivity became not more than 0.3Ω/□ from the relationship between the obtained surface resistivity and the plating time by interpolation.

### (2) Pressure Resistance:

In the case where the surface of each of the samples was scrubbed by a Kikulon scrubbing brush prior to the foregoing exposure, frequency in the generation of a metal formed on a non-exposed area was observed by an optical microscope and rated as follows.

### <Evaluation>

5: Very favorable level on which the formation of a metal in a non-exposed area is not substantially found.
4: Favorable level on which the formation of a metal in a non-exposed area is very scarcely found.
3: Level on which the formation of a metal in a non-exposed area is scarcely found.
2: Level on which the formation of a metal in a non-exposed area is found here and there.
1: Level on which the formation of a metal in a non-exposed area is frequently found.

In the case where the level in the formation of a metal is positioned on an intermediate level of any one of the foregoing evaluation values, an average value of the corresponding evaluation values was employed as the evaluation value.

The obtained evaluation results are shown in Table 1.

TABLE 1

| | Presence or | Coating amount | | | | Content of |
|---|---|---|---|---|---|---|
| Sample | absence of | of silver | | Oxidizing | Chemical | silver iodide |
| No. | protective layer | (g/m²) | Antioxidant | agent | sensitization | (mole %/mole-Ag) |
| 1-1 | Yes | 3.4 | A | Aa | Yes | 0.08 |
| 1-2 | — | ″ | — | — | ″ | ″ |
| 1-3 | — | ″ | A | — | ″ | ″ |
| 1-4 | — | ″ | B | — | ″ | ″ |
| 1-5 | — | ″ | C | — | ″ | ″ |
| 1-6 | — | ″ | — | — | No | ″ |
| 1-7 | — | ″ | — | Aa | Yes | ″ |
| 1-8 | — | ″ | — | Bb | ″ | ″ |
| 1-9 | — | ″ | — | Cc | ″ | ″ |
| 1-10 | — | ″ | — | — | ″ | ″ |
| 1-11 | — | ″ | — | — | ″ | ″ |
| 1-12 | — | ″ | — | — | ″ | ″ |
| 1-13 | — | ″ | — | — | ″ | ″ |
| 1-14 | — | ″ | — | — | ″ | ″ |
| 1-15 | — | ″ | — | — | ″ | ″ |
| 1-16 | — | ″ | A | Aa | ″ | ″ |
| 1-17 | — | ″ | A | Aa | ″ | 4.8 |
| 1-18 | — | ″ | A | Aa | No | 0.08 |
| 1-19 | — | 5.1 | A | Aa | Yes | ″ |
| 1-20 | — | 1.7 | A | Aa | ″ | ″ |

| | | | | Time required | | |
|---|---|---|---|---|---|---|
| Sample | Matting | Slipping | Colloidal | for plating | Pressure | Relationship with |
| No. | agent | agent | silica | (min) | resistance | the invention |
| 1-1 | — | — | Yes | 18 | 4 | Comparison |
| 1-2 | — | — | — | 2.3 | 2.5 | Invention |
| 1-3 | — | — | — | 2.1 | 3 | Invention |
| 1-4 | — | — | — | 2.4 | 3 | Invention |
| 1-5 | — | — | — | 2.1 | 3 | Invention |
| 1-6 | — | — | — | 2.4 | 4 | Invention |
| 1-7 | — | — | — | 2.3 | 3 | Invention |
| 1-8 | — | — | — | 2.3 | 3 | Invention |
| 1-9 | — | — | — | 2.7 | 3 | Invention |
| 1-10 | — | — | Yes | 3.0 | 3 | Invention |
| 1-11 | a | — | — | 3.6 | 3 | Invention |
| 1-12 | b | — | — | 3.8 | 3 | Invention |
| 1-13 | c | — | — | 3.9 | 3 | Invention |
| 1-14 | — | x | — | 2.7 | 3 | Invention |
| 1-15 | — | y | — | 2.6 | 3 | Invention |
| 1-16 | a | x | Yes | 3.3 | 4 | Invention |
| 1-17 | a | x | Yes | 3.3 | 2 | Invention |
| 1-18 | a | x | Yes | 2.9 | 5 | Invention |
| 1-19 | a | x | Yes | 2.3 | 3 | Invention |
| 1-20 | a | x | Yes | 3.6 | 4.5 | Invention |

| Classification | Symbol | Compound | Coating amount | Coating amount unit |
|---|---|---|---|---|
| Antioxidant | A | Hydroquinone | 1.2 × 10⁻² moles | Per mole of silver |
| | B | Sodium catechol disulfonate | 1.2 × 10⁻³ moles | ″ |
| | C | L-Ascorbic acid | 1.2 × 10⁻³ moles | ″ |
| Oxidizing agent | Aa | Sodium benzenethiosulfonate | 10 mg | Per 127 g of silver |
| | Bb | Cpd-OX-1 | 1 × 10⁻⁴ moles | Per mole of silver |
| | Cc | Cpd-OX-2 | 1 × 10⁻⁴ moles | ″ |
| Matting agent | a | Amorphous silica (3.5 μm in average) | 25 mg/m² | |
| | b | Strontium barium sulfate (1.2 μm in average) | 50 mg/m² | |
| | c | Polymethyl methacrylate (2.0 μm in average) | 25 mg/m² | |
| Slipping agent | x | Cpd-8 | 50 mg/m² | |
| | y | Liquid paraffin | 25 mg/m² | |
| 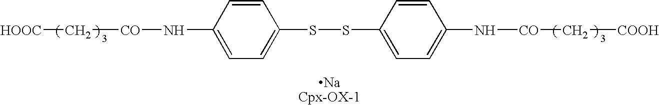 | | | | |
| 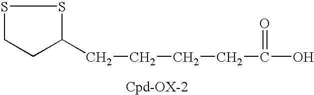 | | | | |

The excellent effects of the invention can be worked out from Table 1. That is, Table 1 reveals that in all of the samples of the invention, the time required for plating is largely shortened as compared with the case of using the coated sample 1-1 as a comparative sample, and it is understood that a conductive film can be rapidly formed by using the sample of the invention. On the other hand, Table 1 reveals simultaneously that when the sample of the invention is used, the pressure resistance is possibly deteriorated. Table 1 reveals that by using the oxidant, oxidizing agent, matting agent, slipping agent and colloidal silica, each of which is preferably used in the photosensitive material of the invention, this deterioration in the pressure resistance can be improved. Also, Table 1 reveals that the use of a chemically unsensitized emulsion, an aspect of which is one of preferred embodiments of the invention, is able to improve the pressure resistance. Also, Table 1 reveals that the use of an emulsion having a restricted silver iodide content, an aspect of which is one of preferred embodiments of the invention, is able to improve the pressure resistance.

### Example 2

### Preparation of Coated Samples 2-1 to 2-7

A sample 2-1 was obtained in the exactly same method as in the sample 1-18 used in Example 1.

Samples were prepared in the same manner as in the coated sample 2-1, except for changing the gelatin amount in the emulsion layer and the coating amount of each of the emulsion layer and the UL layer as shown in Table 2, and samples 2-1 to 2-7 were thus obtained.

Each of the resulting samples was subjected to the same exposure, development treatment, activation and plating treatment in the same manner as in Example 1 and evaluated for plating progress and pressure resistance. The results are shown in Table 2.

TABLE 2

| | Coating amount | | | Time required for | | |
|---|---|---|---|---|---|---|
| | of silver | Emulsion layer | | plating | Pressure | Relationship with |
| Sample No. | (g/m²) | Ag/binder weight | UL layer | (min) | resistance | the invention |
| 2-1 | 3.4 | 1.8 | Yes | 2.9 | 5 | Invention |
| 2-2 | ″ | 0.9 | Yes | 4.2 | 5 | Invention |
| 2-3 | ″ | 2.7 | Yes | 1.8 | 4.5 | Invention |
| 2-4 | ″ | 1.8 | — | 2.9 | 3 | Invention |
| 2-5 | 1.7 | 2.7 | Yes | 3.3 | 5 | Invention |
| 2-6 | ″ | ″ | — | 2.2 | 4 | Invention |
| 2-7 | ″ | 0.9 | Yes | 5.4 | 5 | Invention |

The excellent effects of the invention can be worked out from Table 2. That is, Table 2 reveals that the pressure resistance can be improved within the restricted range of the coating amount of silver, an aspect of which is one of preferred embodiments of the invention. Also, Table 2 reveals that the time required for plating can be further shortened by setting up the restricted Ag/binder ratio of the emulsion layer, an aspect of which is one of preferred embodiments of the invention. Also, Table 2 reveals that the pressure resistance is improved by providing the UL layer located on a side of the support than the emulsion layer, an aspect of which is one of preferred embodiments of the invention. Though a reduction in the coating amount of silver tends to result in an increase of the time required for plating, Table 2 reveals that the increase of the time required for plating following a reduction in the coating amount of silver can be reduced by setting up the restricted Ag/binder ratio of the emulsion layer, an aspect of which is one of preferred embodiments of the invention.

### Example 3

Samples were prepared in the same manner as in the respective samples 1-1 to 1-20 as prepared in Example 1, except for changing the spectral sensitizing coloring matter SD-1 to the following SD-2, changing the Cpd-14 to the following Cpd-YF and not providing the back layer, and samples 3-1 to 3-20 were thus obtained. Here, the coating amounts of SD-2 and Cpd-YF were the same amounts (moles/in²) of SD-1 and Cpd-14, respectively.

Each of the resulting samples was exposed by a contact printer using a high mercury vapor pressure lamp as a light source via a mesh-like photomask having a fine line width of 10 μm and a lattice-to-lattice space of 300 μm, and then subjected to the same development treatment, activation and plating treatment in the same manner as in Example 1 and evaluated for plating progress and pressure resistance. As a result of the evaluation as in Example 1, excellent effects of the invention were confirmed.

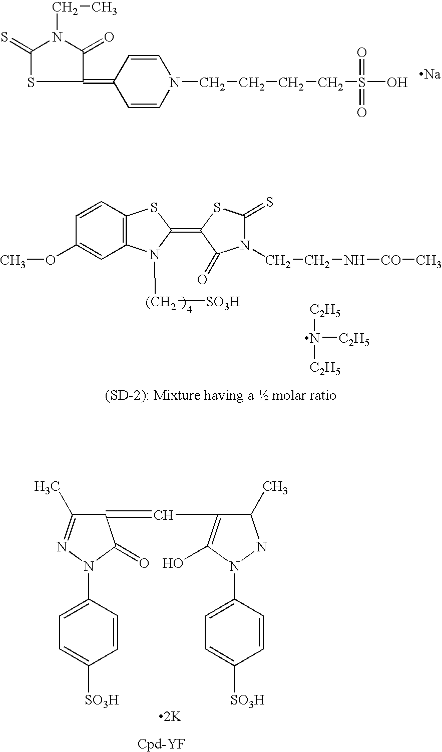

### Example 41

Each of the samples as prepared in Example 3 was exposed in a mesh-like pattern shape having a line width of 15 μm and a pitch of 300 μm by using an image setter (COBALT 8, manufactured by ESCHER-GRAD, laser wavelength: 410 nm) mounted with a blue semiconductor laser. After the exposure, each sample was subjected to the same development treatment, activation and plating treatment in the same manner as in Example 1.

Each of the resulting samples was examined for an electromagnetic wave shielding ability by an Advantest method. As a result, all of the samples had a shielding characteristic of 30 dB or more in the range of form 30 MHz to 1 GHz, and it was confirmed that the photosensitive material of the invention is effective for manufacturing a conductive film having electromagnetic wave shielding properties. Also, all of the samples had an opening ratio of 85% or more, and it was confirmed that the photosensitive material of the invention is effective for preparing a light transmitting electromagnetic wave shielding film for plasma display panel or the like. According to the invention, it is possible to provide a photosensitive material which is favorable for manufacturing a conductive film and/or a light transmitting electromagnetic wave shielding film having improved pressure resistance and a shortened plating time. Also, by using the photosensitive material of the invention, a conductive film and/or a light transmitting electromagnetic wave shielding film can be favorably manufactured.

### Example 5

A sample was prepared in the same manner as in the coated sample 2-1 of Example 2, except for not performing coating of a conductive layer and not providing the antistatic layer, and a coated sample 5-1 was thus obtained.

The resulting coated sample 5-1 and coated sample 2-1 were subjected to the same exposure, development treatment, activation and plating treatment as in Example 2. However, in evaluating the pressure resistance, the front surface and the back surface of the samples were superimposed and abraded without using a Kukulon scrubbing brush, and frequency in the generation of a metal formed on a non-exposed area was evaluated. As a result of observation by an optical microscope in the same manner as in Example 1, the pressure resistance of the sample 2-1 was on the level 5, and the pressure resistance of the sample 5-1 was on the level 3. In the sample 5-1, since the antistatic layer was not provided, foreign matters such as dusts were observed on the sample surface, and it was estimated that the pressure resistance was deteriorated. By providing the antistatic layer, it was revealed that the invention becomes more effective.

### Example 6

An electromagnetic wave shielding film prepared by using the coated sample 2-1 of Example 2 was prepared on a biaxially stretched polyethylene terephthalate (hereinafter “PET”) film (thickness: 100 μm). Next, blackening was carried out by treating with a copper blackening treatment liquid. As the blackening treatment liquid, commercially available COPPER BLACK (manufactured by Isolate Chemical Laboratories Co., Ltd.) was used. A protective film (manufactured by Panac Industries, Inc., a product number: HT-25) having a total thickness of 28 μm was stuck on a side of the PET surface by using a laminator roller.

Also, a protective film (manufactured by Sun A Kaken Co., Ltd., a product name: SUNITECT Y-26F) having a total thickness of 65 μm in which an acrylic adhesive layer is stacked on a polyethylene film was stuck on a side of the electromagnetic wave shielding film (metal mesh) by using a laminator roller.

Next, the stack was stuck on a glass plate having a thickness of 2.5 mm and an external dimension of 950 mm×550 mm, with the PET surface being a sticking surface via a transparent acrylic adhesive material.

Next, an antireflection function-provided near infrared ray absorbing film having a thickness of 100 μm and composed of a PET film, an antireflection layer and a near infrared ray absorber-containing layer (manufactured by Sumitomo Osaka Cement Co., Ltd., a trade name: CLEARAS AR/NIR) was stuck on the internal conductive mesh layer exclusive of its external edge part of 20 mm via an acrylic light transmitting adhesive material having a thickness of 25 μm. Toning coloring matters for adjusting a transmission characteristic of display filter (manufactured by Mitsui Chemicals, Inc., PS-Red-G and PS-Violet-RC) were contained in the acrylic light transmitting adhesive material layer. Furthermore, an antireflection film (manufactured by NOF Corporation, a trade name: ReaLook 8201) was stuck on an opposite major surface of the glass plate via an adhesive material, thereby preparing a display filter.

Since the resulting display filter was prepared by using the electromagnetic wave shielding film having a protective film, it was extremely small in scratches or defects of the metal mesh. Also, the metal mesh was black; the display image was not tinged with a metallic color; and the display filter had an electromagnetic wave shielding ability and a near infrared ray cutting ability (the transmittance of 300˜800 nm is not more than 15%) to an extent that there is no problem in practical use and was excellent in visibility because of the antireflection layer provided on the both surfaces thereof. Also, by containing the coloring matters, a toning function can be imparted, and this display filter can be suitably used as a display filter for plasma display or the like.

### Example 7

A display filter was prepared in the same manner as in Example 6, except for changing the plating method of the coated sample to the following treatment method. The resulting display filter was one which is able to be suitably used as a display filter for plasma display or the like.

### (Plating Method)

A film in which a silver mesh pattern had been formed by the foregoing treatment was subjected to a plating treatment by using an electroplating apparatus provided with an electroplating tank 210 as illustrated in FIG. 1. Incidentally, the foregoing photosensitive material was installed in the electroplating apparatus such that its silver mesh surface was faced downward (the silver mesh surface was brought into contact with an electric power supply roller).

Incidentally, as electric power supply rollers 212a and 212b, a mirror-finished stainless steel-made roller (10 cmφ, length: 70 cm) on a surface of which an electrical copper plating having a thickness of 0.1 mm had been applied was used; and as guide rollers 214 and other carrying rollers, a roller of 5 cmφ and 70 cm in length to which no copper plating had been applied was used. Also, by adjusting a height of the guide rollers 214, even when a line speed varied, it was controlled such that a fixed treatment time in the liquid was ensured.

Also, a distance between a lowermost part of the surface of the electric power supply roller 212a on the inlet side coming into contact with the silver mesh surface and the plating liquid surface (distance La as illustrated in FIG. 1) was set up at 10 cm. A distance between a lowermost part of the surface of the electric power supply roller on the outlet side coming into contact with the silver mesh portion of the photosensitive material and the plating liquid surface (distance Lb as illustrated in FIG. 1) was set up at 20 cm.

FIGS. 2A to 4D each shows a plating apparatus according to an embodiment of the invention.

A composition of the plating treatment liquid, a dipping treatment time (time in the liquid) of each bath and an applied voltage of each plating bath in the plating treatment are as follows. Incidentally, the temperatures of the treatment liquid and water washing were all 25° C.
Composition of copper electroplating liquid (the replenisher had the same composition):

| | | |
|---|---|---|
| Copper sulfate pentahydrate | 75 | g |
| Sulfuric acid | 190 | g |
| Hydrochloric acid (35%) | 0.06 | mL |
| COPPER GLEAM PCM (manufactured by Rohm | 5 | mL |
| and Haas Electronics Materials) | | |

| | |
|---|---|
| Pure water to make | one liter |

a Treatment time and applied voltage of plating bath:

| | | | |
|---|---|---|---|
| Water washing | one minute | | |
| Acid washing | 30 seconds | | |
| Plating 1 | 30 seconds | Voltage | 70 V |
| Plating 2 | 30 seconds | Voltage | 20 V |
| Plating 3 | 30 seconds | Voltage | 10 V |
| Plating 4 | 30 seconds | Voltage | 5 V |
| Water washing | one minute | | |
| Rustproof | 30 seconds | | |
| Water washing | one minute | | |

Every 10-m portion of the film sample was processed and treated at a line speed of 3 m/min.

The resulting conductive film was evaluated in the same manner as in Example 1. As a result, the sample of the invention was excellent in conductivity, namely had an electromagnetic wave shielding ability and brought excellent results in the moiré and degree of blackening.

Also, with respect to the uniformity of the in-plane conductive pattern, in the sample of the invention, unevenness is substantially observed, or even it is observed, it falls within a tolerable range, and the sample of the invention can be suitably utilized as an electromagnetic wave shielding film for display.

While the invention has been described in detail and with reference to specific embodiments thereof, it will be apparent to those skilled in the art that various changes and modifications can be made therein without departing from the spirit and scope thereof.

The present application contains subjects related to a Japanese patent application (No. 2005-038188) filed on Feb. 15, 2005, the entire contents of which being incorporated herein by reference.

1. A conductive film forming photosensitive material, which comprises a support having thereon an emulsion layer containing a silver salt emulsion and is capable of manufacturing a conductive film by exposing the emulsion layer, performing a development treatment and further performing at least one of physical development and plating treatment,
wherein the emulsion layer is disposed substantially in an uppermost layer; and the emulsion layer contains an antioxidant.

2. The conductive film forming photosensitive material according to claim 1,
wherein the emulsion layer further contains an oxidizing agent.

3. The conductive film forming photosensitive material according to claim 1,
wherein the silver salt emulsion is a substantially chemically unsensitized emulsion.

4. The conductive film forming photosensitive material according to claim 1,
wherein the silver salt emulsion is a silver halide emulsion having a silver iodide content of not more than 1.5% by mole.

5. The conductive film forming photosensitive material according to claim 1,
wherein a coating amount of the silver salt emulsion is not more than 4 g/m² as converted to a silver amount.

6. The conductive film forming photosensitive material according to claim 5, wherein a weight ratio of Ag/binder in the emulsion layer is 1.5 or more.

7. The conductive film forming photosensitive material according to claim 5, wherein a binder layer is provided in a lower layer of the emulsion layer.

8. The conductive film forming photosensitive material according to claim 1,
wherein the emulsion layer further contains at least one of a matting agent, a slipping agent, colloidal silica and an antistatic agent.

9. (canceled)

10. A method for manufacturing a conductive film, which comprises:
exposing the conductive film forming photosensitive material according to claim 1; subsequently developing the exposed conductive film forming photosensitive material; and
further performing at least one of physical development and plating treatment.

11. The method for manufacturing a conductive film according to claim 10, wherein the conductive film has electromagnetic wave shielding properties.

12. The method for manufacturing a conductive film according to claim 10, wherein the conductive film forming photosensitive material is partially exposed to form partially a conductive metal part, thereby forming a conductive metal pattern corresponding to an exposure pattern.

13. The method for manufacturing a conductive film according to claim 12,
wherein the conductive metal part is formed only in an exposed area.

14. The method for manufacturing a conductive film according to claim 13,
wherein a portion other than the conductive metal part is light transmitting.

15. A light transmitting electromagnetic wave shielding film, which is manufactured by the method according to claim 14.

16. (canceled)

17. The light transmitting electromagnetic wave shielding film according to claim 15, which has an adhesive layer.

18. The light transmitting electromagnetic wave shielding film according to claim 15, which has a peelable protective film.

19. The light transmitting electromagnetic wave shielding film according to claim 15, wherein 20% or more of a surface of the conductive pattern in terms of a surface area is black.

20. The light transmitting electromagnetic wave shielding film according to claim 15, which has a functional transparent layer having at least one function selected from the group consisting of infrared ray shielding properties, hard coat properties, antireflection properties, antiglare properties, antistatic properties, antifouling properties, ultraviolet ray cutting properties, gas barrier properties and display panel failure-proof properties.

21. The light transmitting electromagnetic wave shielding film according to claim 15, which has infrared ray shielding properties.

22. (canceled)
